(19) United States
(12) Patent Application Publication
(10) Pub. No.: US 2025/0212461 A1
(43) Pub. Date: Jun. 26, 2025

(54) SEMICONDUCTOR DEVICE

(71) Applicant: Semiconductor Energy Laboratory Co., Ltd., Atsugi-shi, Kanagawa-ken (JP)

(72) Inventors: Hiromi SAWAI, Atsugi (JP); Ryota HODO, Atsugi (JP); Yuki OKAMOTO, Ebina (JP); Kazuki TSUDA, Atsugi (JP); Shunpei YAMAZAKI, Setagaya (JP)

(21) Appl. No.: 18/847,289

(22) PCT Filed: Mar. 9, 2023
(86) PCT No.: PCT/IB2023/052225

§ 371 Date: Sep. 16, 2024

(30) Foreign Application Priority Data
Mar. 22, 2022 (JP) 2022-045938
Apr. 28, 2022 (JP) 2022-075018
Jul. 14, 2022 (JP) 2022-113195

(51) Int. Cl. H10D 30/67; H10B 12/00; H10B 41/70; H10D 84/01; H10D 84/03; H10D 84/83

(52) U.S. Cl. CPC H10D 30/6739; H10D 30/6734; H10D 30/6755; H10D 84/83; H10B 12/05; H10B 12/31; H10B 41/70; H10D 84/0126; H10D 84/038

(57) ABSTRACT

A semiconductor device that can be miniaturized or highly integrated is provided. The semiconductor device includes a metal oxide, a first conductor and a second conductor over the metal oxide, a first insulator over the first conductor and the second conductor, a second insulator over the first insulator, a third insulator that is between the first conductor and the second conductor and is over the metal oxide, a third conductor over the third insulator, a fourth conductor that is over the third conductor and is electrically connected to the third conductor, a fourth insulator over the fourth conductor, a fifth insulator over the fourth insulator, and a fifth conductor including a region overlapping with the fourth conductor. The metal oxide includes a first region that overlaps with the first conductor and extends in a first direction. In the first region, an end portion of the metal oxide is aligned with an end portion of the first conductor. The first direction is parallel to a direction in which the fifth conductor extends.

### TECHNICAL FIELD

One embodiment of the present invention relates to a semiconductor device, a memory device, and an electronic device. Another embodiment of the present invention relates to a method for manufacturing a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method of manufacturing any of them.

In this specification and the like, a semiconductor device generally means a device that can function by utilizing semiconductor characteristics. A semiconductor element such as a transistor, a semiconductor circuit, an arithmetic device, and a memory device are each one embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

### BACKGROUND ART

In recent years, semiconductor devices such as LSI (Large Scale Integration), CPUs (Central Processing Units), and memories (memory devices) have been developed. These semiconductor devices have been used in various electronic devices such as computers and portable information terminals. In addition, memories under development employ various storage systems for intended uses such as temporary storage at the time of executing arithmetic processing and long-term storage of data. Examples of memories with typical storage systems include a DRAM (Dynamic Random Access Memory), an SRAM (Static Random Access Memory), and a flash memory.

With an increase in the amount of data dealt with, semiconductor devices having larger memory capacity have been required. Patent Document 1 and Non-Patent Document 1 each disclose a memory cell including stacked transistors.

### REFERENCES

### Patent Document

[Patent Document 1] PCT International Publication No. 2021/053473

### Non-Patent Document

[Non-Patent Document 1] M. Oota, et al., “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a semiconductor device that can be scaled down or highly integrated. Another object of one embodiment of the present invention is to provide a semiconductor device with a high operating speed. Another object of one embodiment of the present invention is to provide a semiconductor device having excellent electrical characteristics. Another object of one embodiment of the present invention is to provide a semiconductor device with a small variation in electrical characteristics of transistors. Another object of one embodiment of the present invention is to provide a highly reliable semiconductor device. Another object of one embodiment of the present invention is to provide a semiconductor device with a high on-state current. Another object of one embodiment of the present invention is to provide a semiconductor device with low power consumption. Another object of one embodiment of the present invention is to provide a novel semiconductor device.

Another object of one embodiment of the present invention is to provide a method for manufacturing a semiconductor device with a small number of processing steps.

Another object of one embodiment of the present invention is to provide a memory device having large memory capacity. Another object of one embodiment of the present invention is to provide a memory device occupying a small area. Another object of one embodiment of the present invention is to provide a highly reliable memory device. Another object of one embodiment of the present invention is to provide a memory device with low power consumption. Another object of one embodiment of the present invention is to provide a novel memory device.

Note that the description of these objects does not preclude the presence of other objects. One embodiment of the present invention does not need to achieve all of these objects. Other objects can be derived from the description of the specification, the drawings, and the claims.

### Means for Solving the Problems

One embodiment of the present invention is a semiconductor device including a metal oxide, a first conductor and a second conductor over the metal oxide, a first insulator over the first conductor and the second conductor, a second insulator over the first insulator, a third insulator that is between the first conductor and the second conductor and is over the metal oxide, a third conductor over the third insulator, a fourth conductor that is over the third conductor and is electrically connected to the third conductor, a fourth insulator over the fourth conductor, a fifth insulator provided in a first opening formed in the fourth insulator, and a fifth conductor including a region overlapping with the fourth conductor with the fifth insulator therebetween. The third insulator and the third conductor are provided in a second opening formed in the first insulator and the second insulator. The metal oxide includes a first region that overlaps with the first conductor and extends in a first direction. In the first region, an end portion of the metal oxide is aligned with an end portion of the first conductor. The first direction is parallel to a direction in which the fifth conductor extends.

Preferably, the above semiconductor device further includes a sixth conductor, a sixth insulator, and a seventh conductor; the metal oxide includes a region overlapping with the sixth conductor; a third opening formed in the first insulator and the second insulator includes a region overlapping with the sixth conductor; the sixth insulator is in contact with a side surface of each of the first insulator and the second insulator in the third opening; the seventh conductor is provided to fill the third opening with the sixth insulator therebetween; and the seventh conductor includes a region in contact with part of a top surface of the sixth conductor and a region in contact with part of a side surface of the sixth conductor.

Preferably, the above semiconductor device further includes a seventh insulator and an eighth insulator; the seventh insulator is between the first conductor and the first insulator; and the eighth insulator is between the second conductor and the first insulator.

In the above semiconductor device, preferably, the first conductor and the second conductor each have a stacked-layer structure; the stacked-layer structure includes a first conductive layer and a second conductive layer over the first conductive layer; and the first conductive layer includes a region with a nitrogen concentration higher than the nitrogen concentration in the second conductive layer.

Another embodiment of the present invention is a semiconductor device including a first transistor and a capacitor, a second transistor, and a fourth insulator over the first transistor. The first transistor includes a first metal oxide, a first conductor and a second conductor over the first metal oxide, a first insulator over the first conductor and the second conductor, a second insulator over the first insulator, a third insulator that is between the first conductor and the second conductor and is over the first metal oxide, and a third conductor over the third insulator. The capacitor includes a fourth conductor, a fifth insulator over the fourth conductor, and a fifth conductor including a region overlapping with the fourth conductor with the fifth insulator therebetween.

The fourth conductor is electrically connected to the third conductor. The second transistor includes an eighth conductor and a second metal oxide that is over the eighth conductor and includes a region overlapping with the eighth conductor. The fifth insulator and the fifth conductor are provided in a first opening formed in the fourth insulator. The eighth conductor is provided in a second opening formed in the fourth insulator. A top surface of the fifth conductor is aligned with a top surface of the eighth conductor.

In the above semiconductor device, preferably, the first metal oxide includes a first region that overlaps with the first conductor and extends in a first direction; in the first region, an end portion of the first metal oxide is aligned with an end portion of the first conductor; and the first direction is parallel to a direction in which the fifth conductor extends.

Preferably, the above semiconductor device further includes a sixth conductor, a sixth insulator, and a seventh conductor; the first metal oxide includes a region overlapping with the sixth conductor; a third opening formed in the first insulator and the second insulator includes a region overlapping with the sixth conductor; the sixth insulator is in contact with a side surface of each of the first insulator and the second insulator in the third opening; the seventh conductor is provided to fill the third opening with the sixth insulator therebetween; and the seventh conductor includes a region in contact with part of a top surface of the sixth conductor and a region in contact with part of a side surface of the sixth conductor.

Preferably, the above semiconductor device further includes a seventh insulator and an eighth insulator; the seventh insulator is between the first conductor and the first insulator; and the eighth insulator is between the second conductor and the first insulator.

In the above semiconductor device, preferably, the first conductor and the second conductor each have a stacked-layer structure; the stacked-layer structure includes a first conductive layer and a second conductive layer over the first conductive layer; and the first conductive layer includes a region with a nitrogen concentration higher than the nitrogen concentration in the second conductive layer.

### Effect of the Invention

According to one embodiment of the present invention, a semiconductor device that can be scaled down or highly integrated can be provided. According to one embodiment of the present invention, a semiconductor device with a high operating speed can be provided. According to one embodiment of the present invention, a semiconductor device with excellent electrical characteristics can be provided. According to one embodiment of the present invention, a semiconductor device with a small variation in electrical characteristics of transistors can be provided. According to one embodiment of the present invention, a highly reliable semiconductor device can be provided. According to one embodiment of the present invention, a semiconductor device with a high on-state current can be provided. According to one embodiment of the present invention, a semiconductor device with low power consumption can be provided. According to one embodiment of the present invention, a novel semiconductor device can be provided.

According to one embodiment of the present invention, a method for manufacturing a semiconductor device with a small number of processing steps can be provided.

According to one embodiment of the present invention, a memory device having large memory capacity can be provided. According to one embodiment of the present invention, a memory device occupying a small area can be provided. According to one embodiment of the present invention, a highly reliable memory device can be provided. According to one embodiment of the present invention, a memory device with low power consumption can be provided. According to one embodiment of the present invention, a novel memory device can be provided.

Note that the description of these effects does not preclude the presence of other effects. One embodiment of the present invention does not necessarily have all the effects. Other effects can be derived from the description of the specification, the drawings, and the claims.

### BRIEF DESCRIPTION OF THE DRAWINGS

FIG. 1 is a cross-sectional view illustrating a structure example of a semiconductor device.

FIG. 2A is a top view illustrating a structure example of a semiconductor device. FIG. 2B is a cross-sectional view illustrating a structure example of a semiconductor device.

FIG. 3A and FIG. 3B are cross-sectional views illustrating structure examples of a semiconductor device.

FIG. 4 is a cross-sectional view illustrating a structure example of a semiconductor device.

FIG. 5A and FIG. 5B are cross-sectional views illustrating structure examples of a semiconductor device.

FIG. 6 is a cross-sectional view illustrating a structure example of a semiconductor device.

FIG. 7A is a top view illustrating a structure example of a semiconductor device. FIG. 7B and FIG. 7C are cross-sectional views illustrating a structure example of a semiconductor device.

FIG. 8A and FIG. 8C are top views illustrating a structure example of a semiconductor device.

FIG. 8B is a cross-sectional view illustrating a structure example of a semiconductor device.

FIG. 9A and FIG. 9B are cross-sectional views illustrating a structure example of a semiconductor device.

FIG. 10A is a top view illustrating a structure example of a semiconductor device. FIG. 10B is a cross-sectional view illustrating a structure example of a semiconductor device.

FIG. 11 is a cross-sectional view illustrating a structure example of a semiconductor device.

FIG. 12 is a cross-sectional view illustrating a structure example of a semiconductor device.

FIG. 13 is a cross-sectional view illustrating a structure example of a semiconductor device.

FIG. 14A and FIG. 14B are top views illustrating a structure example of a semiconductor device.

FIG. 15A to FIG. 15E are cross-sectional views illustrating an example of a method for manufacturing a semiconductor device.

FIG. 16A to FIG. 16C are cross-sectional views illustrating an example of a method for manufacturing a semiconductor device.

FIG. 17A to FIG. 17C are cross-sectional views illustrating an example of a method for manufacturing a semiconductor device.

FIG. 18A to FIG. 18C are cross-sectional views illustrating an example of a method for manufacturing a semiconductor device.

FIG. 19A and FIG. 19B are cross-sectional views illustrating an example of a method for manufacturing a semiconductor device.

FIG. 20A and FIG. 20B are cross-sectional views illustrating an example of a method for manufacturing a semiconductor device.

FIG. 21 is a cross-sectional view illustrating an example of a method for manufacturing a semiconductor device.

FIG. 22A and FIG. 22B are diagrams illustrating an example of a memory device.

FIG. 23A and FIG. 23B are circuit diagrams illustrating examples of a memory layer.

FIG. 24 is a timing chart showing an operation example of a memory cell.

FIG. 25A and FIG. 25B are circuit diagrams illustrating an operation example of a memory cell.

FIG. 26A and FIG. 26B are circuit diagrams illustrating an operation example of a memory cell.

FIG. 27 is a circuit diagram illustrating a structure example of a semiconductor device.

FIG. 28A and FIG. 28B are diagrams illustrating multi-gate transistors. FIG. 28C is a circuit diagram illustrating an example of a memory cell.

FIG. 29A and FIG. 29B are diagrams illustrating an example of a semiconductor device.

FIG. 30A and FIG. 30B are diagrams illustrating examples of electronic components.

FIG. 31A to FIG. 31J are diagrams illustrating examples of electronic devices.

FIG. 32A to FIG. 32E are diagrams illustrating examples of electronic devices.

FIG. 33A to FIG. 33C are diagrams illustrating examples of electronic devices.

FIG. 34 is a diagram illustrating an example of a device for space.

FIG. 35A and FIG. 35B are diagrams illustrating an example of a medical equipment.

FIG. 36 is a diagram illustrating an evaluation environment for an X-ray irradiation test.

FIG. 37A and FIG. 37B are cross-sectional STEM images of a fabricated sample.

FIG. 38 is a flowchart illustrating a method of an X-ray irradiation test.

FIG. 39A is a diagram showing Id-Vg characteristics of a fabricated transistor. FIG. 39B is a diagram showing back gate voltage dependence of SS. FIG. 39C is a diagram showing back gate voltage dependence of Vth.

FIG. 40A is a diagram showing Id-Vg characteristics of a fabricated transistor. FIG. 40B is a diagram showing temperature dependence of SS. FIG. 40C is a diagram showing temperature dependence of Vth.

FIG. 41A is a diagram showing Id-Vg characteristics of an OS transistor. FIG. 41B is a diagram illustrating a change in SS due to X-ray irradiation. FIG. 41C is a diagram illustrating a change in UFE due to X-ray irradiation.

FIG. 42A is a diagram showing the amount of change in the threshold voltage of an OS transistor.

FIG. 42B is a diagram showing the amount of change in the SS of an OS transistor. FIG. 42C is a diagram showing the amount of change in the field-effect mobility of an OS transistor.

FIG. 43A and FIG. 43B are diagrams showing the amount of change in the threshold voltage of an OS transistor.

FIG. 44 is a diagram showing the amount of changes in the threshold voltages of OS transistors.

FIG. 45A and FIG. 45B are diagrams showing the amount of change in the threshold voltage of an OS transistor.

FIG. 46A and FIG. 46B are diagrams showing the amount of changes in the threshold voltages of OS transistors.

FIG. 47A to FIG. 47D are diagrams showing gate voltage dependence of components of TID degradation.

FIG. 48 is a diagram showing the amount of changes in the threshold voltages of OS transistors.

FIG. 49 is a diagram showing the amount of changes in the threshold voltages of OS transistors.

FIG. 50 is a diagram showing the amount of changes in the threshold voltages of OS transistors.

FIG. 51 is a diagram showing the amount of changes in the threshold voltages of OS transistors.

FIG. 52 is a diagram showing the amount of changes in the threshold voltages of OS transistors.

FIG. 53 is a diagram showing the amount of changes in the threshold voltages of OS transistors.

FIG. 54A and FIG. 54B are diagrams showing the amount of changes in the threshold voltages of OS transistors.

FIG. 55A and FIG. 55B are diagrams showing gate voltage dependence of the amount of change in the threshold voltage of OS transistors.

FIG. 56A and FIG. 56B are diagrams showing gate voltage dependence of the amount of change in the threshold voltage of OS transistors.

FIG. 57 is a diagram showing the amount of changes in the threshold voltages of OS transistors.

FIG. 58A to FIG. 58C are cross-sectional STEM images of an OS transistor.

FIG. 59A and FIG. 59B are diagrams showing Id-Vg characteristics of OS transistors. FIG. 59C is a diagram showing the amount of change in the threshold voltage of an OS transistor.

FIG. 60A is a circuit diagram illustrating a memory cell. FIG. 60B is a circuit diagram illustrating a read circuit.

FIG. 61A is a flowchart illustrating a method of a TID resistance test. FIG. 61B is a flowchart illustrating a method of an SEU resistance test.

FIG. 62A and FIG. 62B are diagrams showing results of a TID resistance test.

FIG. 63A to FIG. 63C are diagrams illustrating error modes occurring in an OS memory.

FIG. 64A to FIG. 64D are diagrams showing results of a TID resistance test.

FIG. 65A shows results of a SEU resistance test. FIG. 65B is an error map of SEU in an OS memory.

FIG. 66A to FIG. 66C are energy band diagrams of an OS transistor.

FIG. 67A and FIG. 67B are energy band diagrams of an OS transistor.

FIG. 68A to FIG. 68C are diagrams illustrating error modes occurring in an OS memory.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or claims in some cases.

Note that the term “film” and the term “layer” can be used interchangeably depending on the case or the situation. For example, the term “conductive layer” can be replaced with the term “conductive film”. For another example, the term “insulating film” can be replaced with the term “insulating layer”.

In this specification and the like, the term “insulator” can be replaced with an insulating film or an insulating layer. The term “conductor” can be replaced with a conductive film or a conductive layer. The term “semiconductor” can be replaced with a semiconductor film or a semiconductor layer.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

In this specification and the like, terms for describing positioning, such as “over”, “under”, “above”, and “below”, are sometimes used for convenience to describe the positional relationship between components with reference to drawings. The positional relationship between components is changed as appropriate in accordance with a direction in which each component is described. Thus, the positional relationship is not limited to the terms described in this specification and the like, and can be described with another term as appropriate depending on the situation. For example, the expression “an insulator positioned over a conductor” can be replaced with the expression “an insulator positioned under a conductor” when the direction of a drawing illustrating these components is rotated by 180°.

Note that in this specification and the like, the expression “substantially level with” indicates a structure having the same level from a reference surface (e.g., a flat surface such as a substrate surface) in a cross-sectional view. For example, in a manufacturing process of the semiconductor device, planarization treatment (typically, CMP (Chemical Mechanical Polishing) treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the treated surfaces on which the CMP treatment is performed. This case is also regarded as “substantially level with” in this specification and the like. For example, the expression “substantially level with” includes the case where two layers (here, given as a first layer and a second layer) having different two levels with respect to the reference surface are included, and the difference between the top-surface level of the first layer and the top-surface level of the second layer is less than or equal to 20 nm.

Note that in this specification and the like, the expression “end portions are aligned or substantially aligned” means that at least outlines of stacked layers partly overlap with each other in a top view. For example, the case of processing the upper layer and the lower layer with the use of the same mask pattern or mask patterns that are partly the same is included. However, in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned or substantially aligned”.

In general, it is difficult to clearly differentiate “perfectly aligned” from “substantially aligned”. Thus, in this specification and the like, the expression “the same” includes both “completely the same” and “substantially the same”.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

In this specification and the like, “a layer, a wiring, a component, or the like extends in a direction” means that the layer, the wiring, the component, or the like is provided to extend in the direction. When seen from the above, the layer, the wiring, the component, or the like may have a long extending shape in the direction, and may partly have a portion extending in a direction different from the direction.

### Embodiment 1

In this embodiment, a semiconductor device of one embodiment of the present invention will be described with reference to drawings.

One embodiment of the present invention relates to a semiconductor device in which a memory layer is provided over a substrate. The memory layer includes first to third transistors and a capacitor, which can form a memory cell. The semiconductor device of one embodiment of the present invention includes the memory cell and thus has a function of storing data. Hence, the semiconductor device of one embodiment of the present invention can be referred to as a memory device.

The first transistor includes a first metal oxide, first and second conductors over the first metal oxide, a first insulator that is between the first conductor and the second conductor and is over the first metal oxide, and a third conductor over the first insulator. The second transistor includes a second metal oxide, fourth and fifth conductors over the second metal oxide, a second insulator that is between the fourth conductor and the fifth conductor and is over the second metal oxide, and a sixth conductor over the second insulator. The third transistor includes the second metal oxide, the fifth conductor and a seventh conductor over the second metal oxide, a third insulator that is between the fifth conductor and the seventh conductor and is over the second metal oxide, and an eighth conductor over the third insulator. That is, the second transistor and the third transistor share the second metal oxide and the fifth conductor. It can be said that the first metal oxide is electrically connected to each of the first and second conductors. It can also be said that the second metal oxide is electrically connected to each of the fourth and fifth conductors. It can also be said that the second metal oxide is electrically connected to each of the fifth and seventh conductors.

The first metal oxide includes a region functioning as a channel formation region of the first transistor. The first conductor includes a region functioning as one of a source electrode and a drain electrode of the first transistor. The second conductor includes a region functioning as the other of the source electrode and the drain electrode of the first transistor. The third conductor includes a region functioning as a gate electrode of the first transistor. The first insulator includes a region functioning as a gate insulator of the first transistor.

The second metal oxide includes a region functioning as a channel formation region of the second transistor and a region functioning as a channel formation region of the third transistor. The fourth conductor includes a region functioning as one of a source electrode and a drain electrode of the second transistor. The fifth conductor includes a region functioning as the other of the source electrode and the drain electrode of the second transistor and also functioning as one of a source electrode and a drain electrode of the third transistor. The sixth conductor includes a region functioning as a gate electrode of the second transistor. The seventh conductor includes a region functioning as the other of the source electrode and the drain electrode of the third transistor. The eighth conductor includes a region functioning as a gate electrode of the third transistor. The second insulator includes a region functioning as a gate insulator of the second transistor. The third insulator includes a region functioning as a gate insulator of the third transistor.

When the second transistor and the third transistor are adjacent to each other to share the second metal oxide and the fifth conductor, the two transistors can be formed in an area smaller than the area of two transistors (e.g., the area of one and a half transistors). This enables the transistors to be arranged at high density, which leads to high integration in the semiconductor device.

The semiconductor device of one embodiment of the present invention includes a transistor (an OS transistor) including a metal oxide in a region where a channel is formed (also referred to as a channel formation region). When the OS transistor, which has a low off-state current, is used for a semiconductor device that can be a memory device, stored contents can be retained for a long time. That is, a refresh operation is not required or the frequency of the refresh operation is extremely low; thus, the power consumption of the semiconductor device can be adequately reduced. The semiconductor device with low power consumption can be provided accordingly. The OS transistor has high frequency characteristics and thus enables the semiconductor device to perform data reading and writing at high speed. The semiconductor device with high operating speed can be provided accordingly.

In the semiconductor device of one embodiment of the present invention, the fourth conductor included in the second transistor is provided to extend in the channel width direction of the second transistor (the direction perpendicular to the channel length direction) and includes a region functioning as a wiring. Such a structure eliminates the need for additionally providing an electrode (a wiring or a plug) connected to one of the source electrode and the drain electrode of the second transistor. Note that since the second metal oxide and the fourth conductor that are included in the second transistor are processed with the same mask pattern, the second metal oxide is placed below the fourth conductor. Thus, a region of the second metal oxide that overlaps with the fourth conductor is provided to extend in the channel width direction of the second transistor.

In the semiconductor device of one embodiment of the present invention, a plurality of memory layers each having the above structure are stacked. That is, the plurality of memory layers each having the above structure are provided in the direction perpendicular to the substrate surface, for example. Thus, without an increase in the area occupied by memory cells, the semiconductor device can have larger memory capacity than a semiconductor device including one memory layer. Accordingly, the occupation area per bit is reduced, so that the semiconductor device can have a small size and large memory capacity.

In the case where the plurality of memory layers are stacked, a write bit line and a read bit line can each be provided in the direction perpendicular to the substrate surface, for example. In the case where a semiconductor device including n memory layers (n is an integer greater than or equal to 2) is formed, for example, connection electrodes formed by connecting conductors, which are included in the n memory layers, in a vertical direction can be used as the write bit line and the read bit line that extend in the vertical direction. Here, in the semiconductor device of one embodiment of the present invention, a conductor including a region functioning as the write bit line is provided to include a region in contact with the top surface and side surface of the first conductor. In addition, in the semiconductor device of one embodiment of the present invention, a conductor including a region functioning as the read bit line is provided to include a region in contact with the top surface and the side surface of the seventh conductor. Such a structure eliminates the need for additionally providing a connection electrode between the first conductor and the write bit line and the need for additionally providing a connection electrode between the seventh conductor and the read bit line. In this manner, the semiconductor device of one embodiment of the present invention can be a semiconductor device having a high integration degree of memory cells.

Note that the number of the memory layers provided in the semiconductor device of one embodiment of the present invention may be only one.

### <Structure Example of Semiconductor Device>

Structure examples of the semiconductor device of one embodiment of the present invention will be described below.

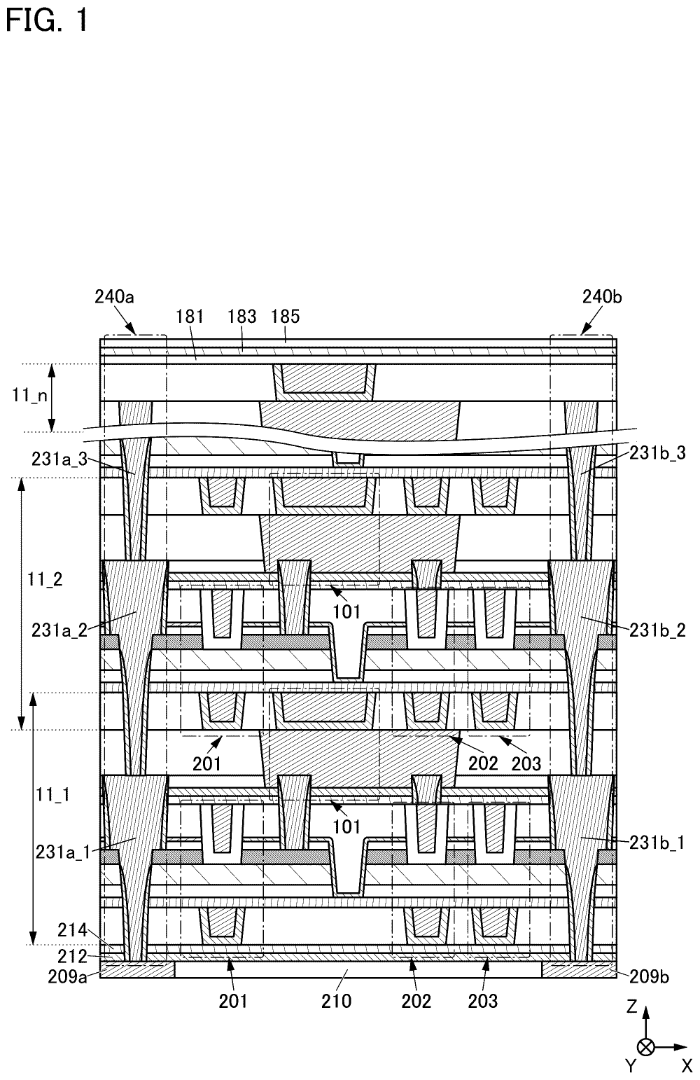

FIG. 1 is a cross-sectional view illustrating a structure example of the semiconductor device of one embodiment of the present invention. The semiconductor device illustrated in FIG. 1 includes an insulator 210 over a substrate (not illustrated), a conductor 209a and a conductor 209b embedded in the insulator 210, an insulator 212 over the insulator 210, an insulator 214 over the insulator 212, n memory layers 11 (a memory layer 11_1 to a memory layer 11_n) over the insulator 214, a connection electrode 240a and a connection electrode 240b, which are electrically connected to the conductor 209a and 209b, respectively, and provided to extend in the Z direction (also referred to as the vertical direction), an insulator 181 over the memory layer 11_n, an insulator 183 over the insulator 181, and an insulator 185 over the insulator 183. Note that components of the semiconductor device of this embodiment may each have either a single-layer structure or a stacked-layer structure.

In the following description of matters common to components distinguished from each other using letters of the alphabet, reference numerals without the letters of the alphabet are sometimes used. For example, in the case where matters common to the conductor 209a and the conductor 209b are described, the term “conductor 209” is used in some cases.

The memory layer 11_1 to the memory layer 11_n are each provided with a memory cell array including a plurality of memory cells. The memory cells each include a transistor 201, a transistor 202, a transistor 203, and a capacitor 101. The connection electrode 240a includes a region functioning as a write bit line, and the connection electrode 240b includes a region functioning as a read bit line.

In this specification and the like, a direction parallel to a channel length direction of a transistor illustrated is referred to as an X direction, and a direction parallel to a channel width direction of a transistor illustrated is referred to as a Y direction. The X direction and the Y direction can be perpendicular to each other. Furthermore, a direction perpendicular to both the X direction and the Y direction, i.e., a direction perpendicular to the XY plane, is referred to as a Z direction. The X direction and the Y direction can each be a direction parallel to the substrate surface, and the Z direction can be a direction perpendicular to the substrate surface, for example.

The connection electrode 240a and the connection electrode 240b are each formed by connecting conductors, which are included in the n memory layers 11, in the Z direction. Specifically, a conductor 231a_1 included in the memory layer 11_1, a conductor 231a_2 included in the memory layer 11_2, a conductor 231a_3 included in the memory layer 11_3, and the like are connected in the Z direction to form the connection electrode 240a. A conductor 231b_1 included in the memory layer 11_1, a conductor 231b_2 included in the memory layer 11_2, a conductor 231b_3 included in the memory layer 11_3, and the like, are connected in the Z direction to form the connection electrode 240b.

The conductor 209a and the conductor 209b each function as a wiring, an electrode, a terminal, or part of a circuit element such as a switch, a transistor, a capacitor, an inductor, a resistor, or a diode.

FIG. 1 illustrates, among the n memory layers 11, the memory layer 11_1 that is the lowest layer, the memory layer 11_2 over the memory layer 11_1, and the memory layer 11_n that is the uppermost layer.

The conductor 209a and the conductor 209b are electrically connected to driver circuits for driving the memory cells provided in the memory layers included in the semiconductor device. The driver circuits are provided below the conductor 209a and the conductor 209b. Increasing the number of stacked memory layers (the value of n) included in the semiconductor device can increase the memory capacity of the memory device without an increase in the area occupied by the memory cells. Accordingly, the occupation area per bit is reduced, so that the semiconductor device can have a small size and large memory capacity.

The transistor 201 to the transistor 203 are provided over the insulator 214. Here, the transistor 202 and the transistor 203 share some layers. The capacitor 101 is provided above the transistor 201 to the transistor 203.

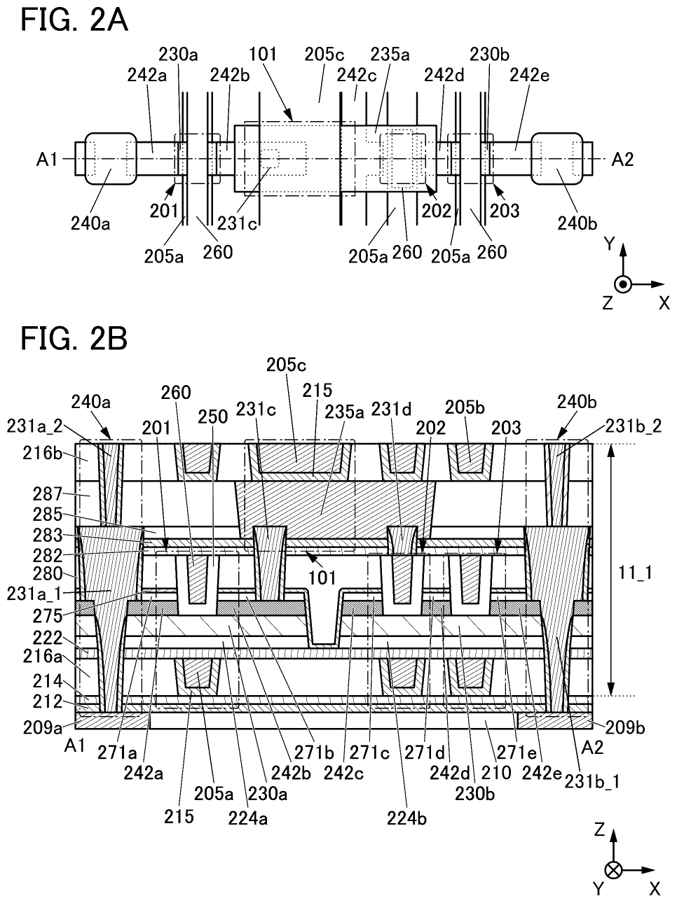

FIG. 2A and FIG. 2B are a top view and a cross-sectional view, respectively, illustrating structure examples of the conductor 209a, the conductor 209b, the insulator 210, the insulator 212, the insulator 214, and the memory layer 11_1. Here, FIG. 2B is a cross-sectional view of a portion indicated by dashed-dotted line A1-A2 in FIG. 2A, and is a cross-sectional view of the transistor 201 to the transistor 203 in the channel length direction. Note that for clarity of the drawing, some components are omitted in the top view of FIG. 2A.

As illustrated in FIG. 2B, an insulator 216a and an insulator 215 are provided over the insulator 214, an insulator 282 is provided over the transistor 201 to the transistor 203, an insulator 283 is provided over the insulator 282, and the capacitor 101 is provided over the insulator 283.

Each of the transistor 201 to the transistor 203 includes a conductor 205a over the insulator 214, an insulator 222 over the conductor 205a, an insulator 224 over the insulator 222, a metal oxide 230 over the insulator 224, a pair of conductors 242 over the metal oxide 230, an insulator 250 that is between the pair of conductors 242 and is over the metal oxide 230, and a conductor 260 over the insulator 250. Here, the transistor 201 includes an insulator 224a as the insulator 224, a metal oxide 230a as the metal oxide 230, and a conductor 242a and a conductor 242b as the pair of conductors 242. The transistor 202 includes an insulator 224b as the insulator 224, a metal oxide 230b as the metal oxide 230, and a conductor 242c and a conductor 242d as the pair of conductors 242. The transistor 203 includes the insulator 224b as the insulator 224, the metal oxide 230b as the metal oxide 230, and the conductor 242d and a conductor 242e as the pair of conductors 242. The transistor 202 and the transistor 203 share the insulator 224b, the metal oxide 230b, and the conductor 242d.

A plurality of openings reaching the insulator 214 are provided in the insulator 216a. The insulator 215 and the conductor 205a are placed in each of the plurality of openings. The insulator 215 is provided in contact with sidewalls of the openings and the top surface of the insulator 214. The conductor 205a is provided to be embedded in a depressed portion formed in the insulator 215. Here, the top surface of the conductor 205a is level with each of the top surface of the insulator 215 and the top surface of the insulator 216a. The conductor 205a includes a region overlapping with the metal oxide 230a or the metal oxide 230b with the insulator 222 and the insulator 224 therebetween.

In this specification and the like, the term “opening” includes a groove, a slit, and the like. A portion where an opening is formed is referred to as an opening portion in some cases.

The insulator 222 is provided over the conductor 205a, the insulator 215, and the insulator 216a. An insulator 275 is provided over the insulator 222 and the conductor 242a to the conductor 242e, and an insulator 280 is provided over the insulator 275.

Each of the transistor 201 to the transistor 203 includes a pair of insulators 271 between the insulator 275 and the pair of conductors 242. Here, the transistor 201 includes an insulator 271a and an insulator 271b as the pair of insulators 271. The transistor 202 includes an insulator 271c and an insulator 271d as the pair of insulators 271. The transistor 203 includes an insulator 271d and an insulator 271e as the pair of insulators 271. The transistor 202 and the transistor 203 share the insulator 271d.

An opening reaching the metal oxide 230a and an opening reaching the metal oxide 230b are provided in the insulator 280 and the insulator 275. That is, the opening provided in the insulator 280 and the insulator 275 includes a region overlapping with the metal oxide 230a or the metal oxide 230b. The insulator 250 and the conductor 260 are provided in the openings. That is, the conductor 260 includes a region overlapping with the metal oxide 230a or the metal oxide 230b with the insulator 250 therebetween. The insulator 250 includes a region in contact with the sidewall of the above opening and a region in contact with the top surface and the side surface of the metal oxide 230a or the metal oxide 230b. The top surface of the conductor 260 is level with each of the top surface of the insulator 250 and the top surface of the insulator 280.

The insulator 282 is provided over the insulator 280, the insulator 250, and the conductor 260. The insulator 283 is provided over the insulator 282. An insulator 285 is provided over the insulator 283

The metal oxide 230a includes a region functioning as a channel formation region of the transistor 201. The metal oxide 230b includes a region functioning as a channel formation region of the transistor 202 and a region functioning as a channel formation region of the transistor 203. Note that for the transistor 201 to the transistor 203, a semiconductor such as single crystal silicon, polycrystalline silicon, or amorphous silicon may be used instead of the metal oxide 230; for example, low-temperature polysilicon (LTPS) may be used.

The conductor 242a includes a region functioning as one of a source electrode and a drain electrode of the transistor 201. The conductor 242b includes a region functioning as the other of the source electrode and the drain electrode of the transistor 201. The conductor 242c includes a region functioning as one of a source electrode and a drain electrode of the transistor 202. The conductor 242d includes a region functioning as the other of the source electrode and the drain electrode of the transistor 202 and a region functioning as one of a source electrode and a drain electrode of the transistor 203. The conductor 242e includes a region functioning as the other of the source electrode and the drain electrode of the transistor 203.

The conductor 260 includes a region functioning as a first gate electrode of the transistor 201, the transistor 202, or the transistor 203. The insulator 250 includes a region functioning as a first gate insulator of the transistor 201, the transistor 202, or the transistor 203.

The conductor 205a includes a region functioning as a second gate electrode of the transistor 201, the transistor 202, or the transistor 203. Each of the insulator 222 and the insulator 224a includes a region functioning as a second gate insulator of the transistor 201. The insulator 222 and the insulator 224b includes a region functioning as a second gate insulator of the transistor 202 and a region functioning as a second gate insulator of the transistor 203.

In this specification and the like, the first gate electrode can be referred to as a top gate electrode or simply as a gate electrode, and the second gate electrode can be referred to as a back gate electrode. Note that the first gate electrode may be referred to as a back gate electrode, and the second gate electrode may be referred to as a top gate electrode or simply as a gate electrode.

The transistor 202 and the transistor 203 are adjacent to each other and share the metal oxide 230b and the conductor 242d. Thus, the two transistors (the transistor 202 and the transistor 203) can be formed in an area (e.g., the area of one and a half transistors) smaller than the area of two transistor. This enables the transistors to be arranged at high density as compared with the case where the transistor 202 and the transistor 203 do not share the metal oxide 230b and the conductor 242d; hence, high integration in the semiconductor device can be achieved.

The conductor 242d is placed in a region between the conductor 260 included in the transistor 202 and the conductor 260 included in the transistor 203. Thus, an n-type region (a low-resistance region) can be formed in a region of the metal oxide 230b that overlaps with the conductor 242d. Moreover, current can flow between the transistor 202 and the transistor 203 through the conductor 242d. Thus, the resistance component between the transistor 202 and the transistor 203 can be significantly reduced as compared with a structure in which two transistors using silicon in their semiconductor layers where channels are formed (also referred to as Si transistors) are connected in series.

The capacitor 101 includes the conductor 235a, the insulator 215 over the conductor 235a, and the conductor 205c over the insulator 215.

The conductor 235a is provided over the insulator 283 and the conductor 260 included in the transistor 202. The conductor 235a is electrically connected to the conductor 260.

An insulator 287 is provided over the insulator 285. An opening reaching the insulator 283 is provided in the insulator 287 and the insulator 285. The conductor 235a is embedded in the opening. The top surface of the conductor 235a is level with the top surface of the insulator 287.

An insulator 216b is provided over the conductor 235a and the insulator 287. In the insulator 216b, a first opening and a plurality of second openings that reach at least one of the insulator 287 and the conductor 235a are provided. The first opening includes a region overlapping with the conductor 235a, and each of the plurality of second openings includes a region overlapping with any one of the transistor 201 to the transistor 203. The insulator 215 and the conductor 205c are provided in the first opening, and the insulator 215 and the conductor 205b are placed in each second opening. The insulator 215 is provided in contact with the side surface and the bottom surface of each of the first opening and the second openings. The conductor 205c is provided to be embedded in the depressed portion formed in the insulator 215 provided in the first opening. In that case, the conductor 205c includes a region overlapping with the conductor 235a with the insulator 215 therebetween. The conductor 205b is provided to be embedded in the depressed portion formed in the insulator 215 provided in the second opening. Here, the top surface of the conductor 205c is level with each of the top surface of the insulator 215, the top surface of the insulator 216b, and the top surface of the conductor 205b.

Note that the insulator 216b of the memory layer 11_1 is also the insulator 216a of the memory layer 11_2. Thus, in this specification and the like, the insulator 216b can be rephrased as the insulator 216a in some cases.

The conductor 205b of the memory layer 11_1 is also the conductor 205a of the memory layer 11_2. Thus, the conductor 205b of the memory layer 11_1 includes a region functioning as a second gate electrode of the transistor 201, the transistor 202, or the transistor 203 of the memory layer 11_2. The conductor 205b of the memory layer 11_1 also includes a region overlapping with the metal oxide 230a or the metal oxide 230b of the memory layer 11_2. Note that in this specification and the like, the conductor 205b can be rephrased as the conductor 205a in some cases.

Hereinafter, in the case where matters common to the conductor 205a to the conductor 205c are described, the term “conductor 205” is used in some cases.

The conductor 235a includes a region functioning as one electrode (also referred to as a lower electrode) of the capacitor 101. The insulator 215 includes a region functioning as a dielectric of the capacitor 101. The conductor 205c includes a region functioning as the other electrode (also referred to as an upper electrode) of the capacitor 101. The capacitor 101 forms a MIM (Metal-Insulator-Metal) capacitor.

An opening reaching the conductor 242b is provided in the insulator 285, the insulator 283, the insulator 282, the insulator 280, the insulator 275, and the insulator 271b, and a conductor 231c is embedded in the opening. An opening reaching the conductor 260 included in the transistor 202 is provided in the insulator 285, the insulator 283, and the insulator 282, and a conductor 231d is provided in the opening. The conductor 242b and the conductor 235a are electrically connected to each other through the conductor 231c. The conductor 260 included in the transistor 202 and the conductor 235a are electrically connected to each other through the conductor 231d. In this manner, the conductor 242b including the region functioning as the other of the source electrode and the drain electrode of the transistor 201 is electrically connected to the conductor 260 including the region functioning as the gate electrode of the transistor 202 through the conductor 231c, the conductor 235a, and the conductor 231d. The conductor 235a includes a region in contact with the top surface of the conductor 231c and a region in contact with the top surface of the conductor 231d.

An opening reaching the conductor 209a is provided in the insulator 285, the insulator 283, the insulator 282, the insulator 280, the insulator 275, the insulator 222, the insulator 216a, the insulator 214, and the insulator 212, and the conductor 231a_1 is embedded in the opening. An opening reaching the conductor 231a_1 is provided in the insulator 285, the insulator 283, the insulator 282, the insulator 280, the insulator 275, the insulator 222, and the insulator 216b and the insulator 287 in the memory layer 11_2 (not illustrated), and the conductor 231a_2 is embedded in the opening.

The top surface of the conductor 209a includes a region in contact with the conductor 231a_1. The top surface of conductor 231a_1 includes a region in contact with the conductor 231a_2. In the area illustrated in FIG. 2B, the connection electrode 240a includes the conductor 231a_1 and the conductor 231a_2.

An opening reaching the conductor 209b is provided in the insulator 285, the insulator 283, the insulator 282, the insulator 280, the insulator 275, the insulator 222, the insulator 216a, the insulator 214, and the insulator 212, and the conductor 231b_1 is embedded in the opening.

An opening reaching the conductor 231b_1 is provided in the insulator 285, the insulator 283, the insulator 282, the insulator 280, the insulator 275, the insulator 222, and the insulator 216b and the insulator 287 in the memory layer 11_2 (not illustrated), and the conductor 231b_2 is embedded in the opening.

The top surface of the conductor 209b includes a region in contact with the conductor 231b_1. The top surface of conductor 231b_1 includes a region in contact with the conductor 231b_2. In the area illustrated in FIG. 2B, the connection electrode 240b includes the conductor 231b_1 and the conductor 231b_2.

As described above and illustrated in FIG. 2B, the top surface of the conductor 231c, the top surface of the conductor 231d, the top surface of the conductor 231a_1, and the top surface of the conductor 231b_1 are level with each other. In addition, the conductor 231c, the conductor 231d, the conductor 231a_1, and the conductor 231b_1 can be formed using the same material in the same step. Thus, the conductor 231c, the conductor 231d, the conductor 231a_1, and the conductor 231b_1 preferably include the same conductive material.

Hereinafter, in the case where matters common to the conductor 231a_1 to the conductor 231a_2 are described, the term “conductor 231a” is used in some cases. In the case where matters common to the conductor 231b_1 to the conductor 231b_2 are described, the term “conductor 231b” is used in some cases.

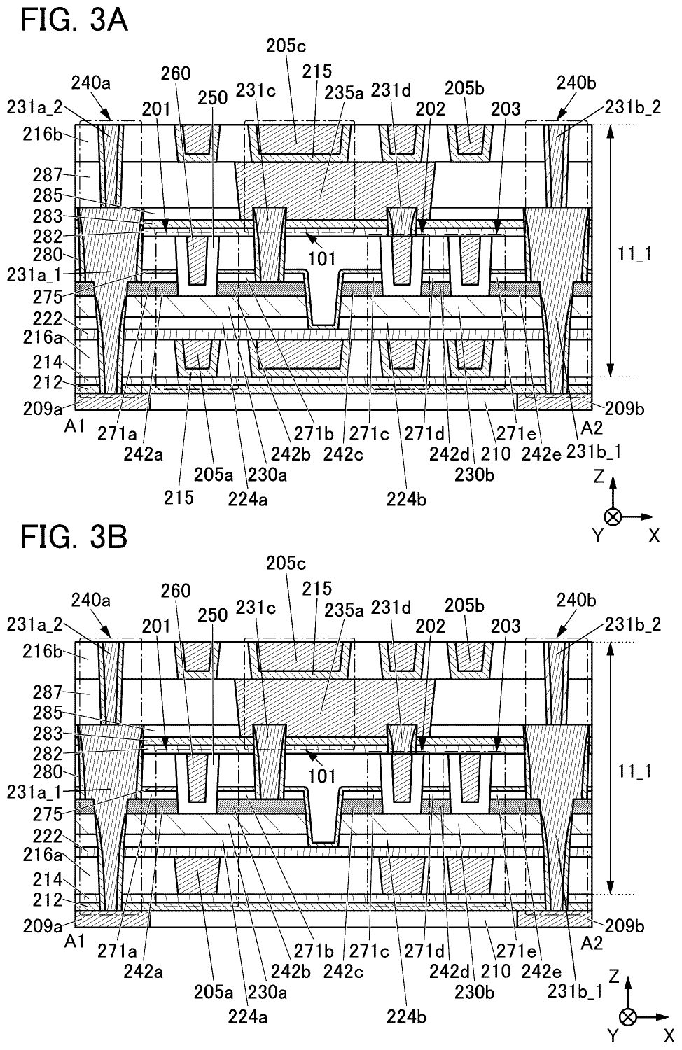

FIG. 2B illustrates a structure in which a conductor corresponding to the conductor 205c provided in the insulator 216b is not provided in the insulator 216a. Note that the present invention is not limited thereto. For example, as illustrated in FIG. 3A, a conductor corresponding to the conductor 205c and the insulator 215 provided in the insulator 216b may be provided in the insulator 216a. With this structure, a mask used in the formation of an opening in the insulator 216a and a mask used in the formation of an opening in the insulator 216b can be used in common, so that the manufacturing cost can be reduced.

FIG. 2B illustrates a structure in which the insulator 215 is provided between the insulator 216a and the conductor 205a. Note that the present invention is not limited thereto. For example, a structure in which the insulator 215 is not provided as illustrated in FIG. 3B may be employed. When the insulator 215 is not provided, the manufacturing cost can be reduced.

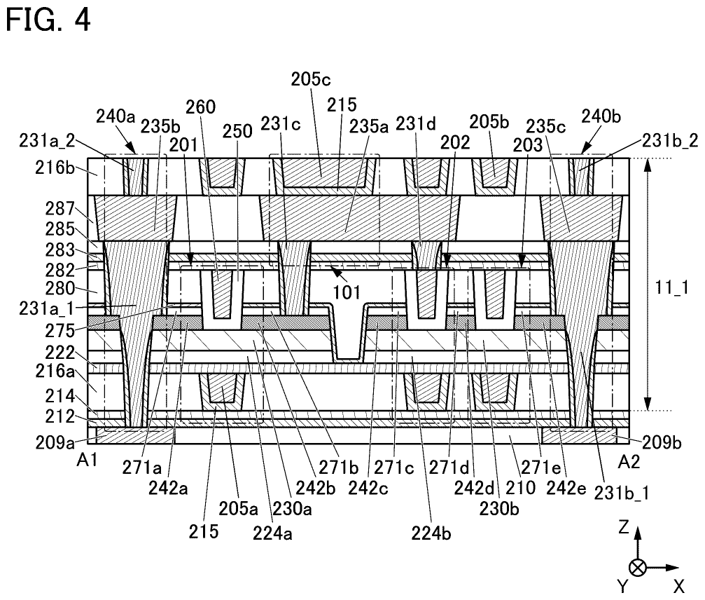

Although FIG. 2B illustrates a structure in which the top surface of the conductor 231a_1 is in contact with the bottom surface of the conductor 231a_2 and the top surface of the conductor 231b_1 is in contact with the bottom surface of the conductor 231b_2, the present invention is not limited thereto. For example, as illustrated in FIG. 4, the conductor 231a_1 and the conductor 231a_2 may be connected to each other with the conductor 235b therebetween, and the conductor 231b_1 and the conductor 231b_2 may be connected to each other with the conductor 235c therebetween.

In the semiconductor device illustrated in FIG. 4, the conductor 235a, the conductor 235b, and the conductor 235c are provided in the openings formed in the insulator 287. The conductor 235b includes a region in contact with the top surface of the conductor 231a_1 and a region in contact with the bottom surface of the conductor 231a_2. The conductor 235c includes a region in contact with the top surface of the conductor 231b_1 and a region in contact with the bottom surface of the conductor 231b_2.

Although FIG. 2B illustrates the structure in which the components included in the semiconductor device have a single-layer structure, the present invention is not limited thereto. Some of the components included in the semiconductor device may have a stacked-layer structure.

Although FIG. 3B illustrates a structure in which the conductor 205b is provided in the insulator 216b in each of the regions overlapping with the transistor 201 to the transistor 203, the present invention is not limited thereto.

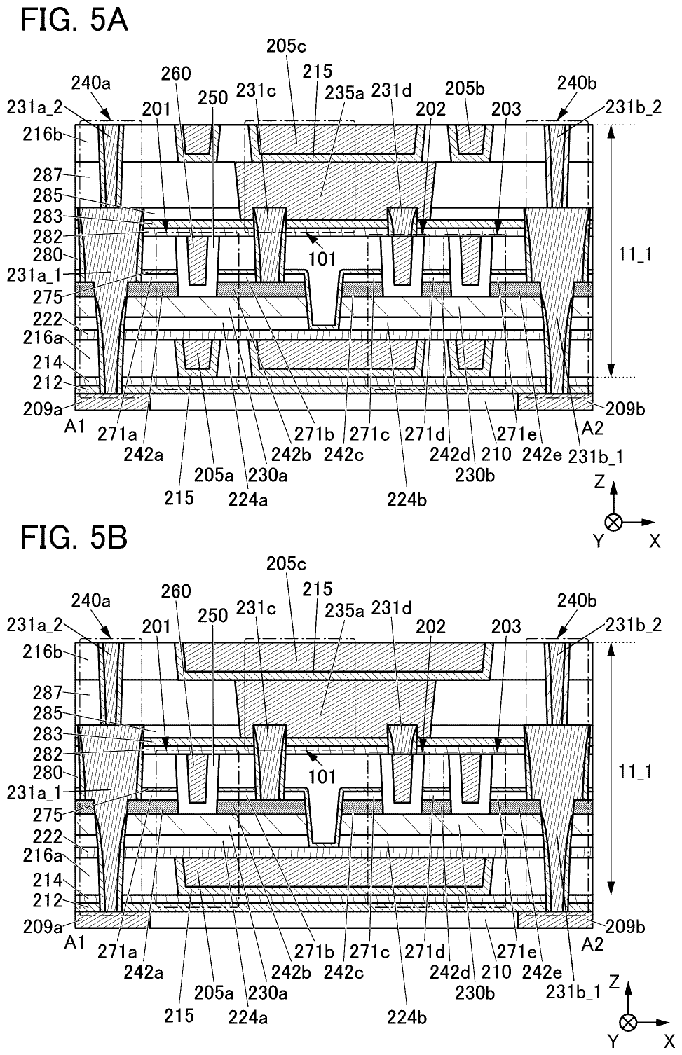

For example, a structure may be employed in which the conductor 205b is not provided in the insulator 216b in the region overlapping with the transistor 202, as illustrated in FIG. 5A. In this case, the conductor 205c includes a region overlapping with the transistor 202. The conductor 205c is shared by the capacitor 101 and the transistor 202. The conductor 205c includes a region functioning as the other electrode of the capacitor 101 and a region functioning as the second gate electrode of the transistor 202. This structure can increase the area of a region where the conductor 205c and the conductor 235a overlap with each other and the area of a region where the conductor 205c and the metal oxide 230b overlap with each other. Accordingly, the capacitance of the capacitor 101 can be increased. In addition, in the structure, the channel formation region of the transistor 202 is interposed between two gate electrodes, so that the metal oxide 230b can be prevented from being affected by an electric field generated outside the transistor 202, such as static electricity. With this structure, a variation in the electrical characteristics of the transistors due to the influence of an external electric field such as static electricity can be inhibited. Consequently, the reliability of the semiconductor device can be increased.

For example, a structure in which the conductor 205b is not provided in the insulator 216b as illustrated in FIG. 5B may be employed. In this case, the conductor 205c includes regions overlapping with the transistor 201 to the transistor 203. The conductor 205c is shared by the capacitor 101 and the transistor 201 to the transistor 203. The conductor 205c includes a region functioning as the other electrode of the capacitor 101 and a region functioning as the second gate electrode of each of the transistor 201 to the transistor 203. This structure can increase the area of a region where the conductor 205c and the conductor 235a overlap with each other, the area of a region where the conductor 205c and the metal oxide 230a overlap with each other, and the area of a region where the conductor 205c and the metal oxide 230b overlap with each other. For example, the metal oxides as a whole can overlap with the conductor 205 in a plan view. In that case, the capacitance of the capacitor 101 can be increased, and variations in the electrical characteristics of the transistor 201 to the transistor 203 due to the influence of an external electric field can be suitably inhibited.

Meanwhile, in the semiconductor device illustrated in FIG. 2B, the potentials of the second gate electrodes of the transistor 201 to the transistor 203 can be changed not in synchronization with but independently of the potential of the other electrode of the capacitor 101. Hence, the threshold voltages (Vth) of the transistor 201 to the transistor 203 can be controlled.

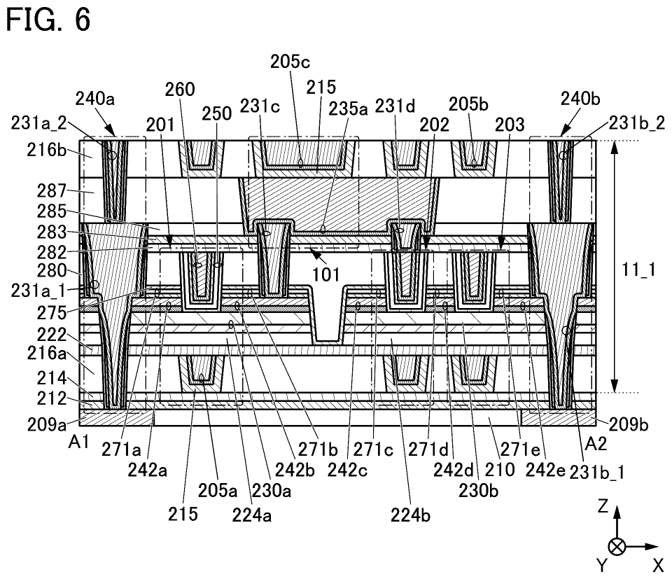

In the semiconductor device illustrated in FIG. 6, the conductor 205, the metal oxide 230, the conductor 242, the insulator 271, the insulator 250, the conductor 260, the conductor 231a to the conductor 231d, and the conductor 235a each have a stacked-layer structure. Note that a preferable stacked-layer structure of the components is described later.

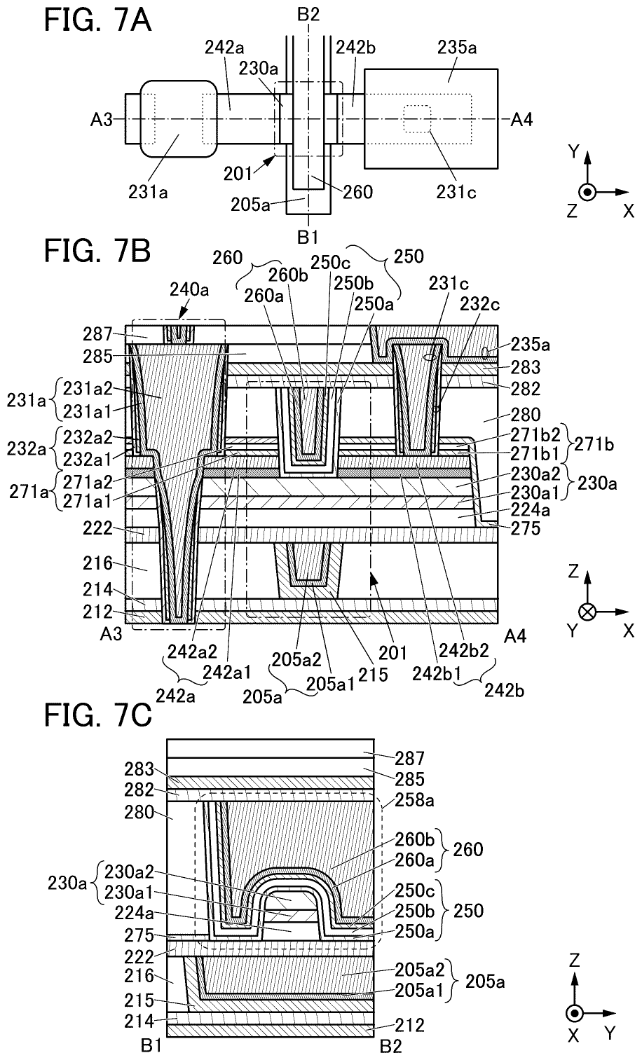

An enlarged view of the transistor 201, the connection electrode 240a, and the vicinity thereof in FIG. 6 are shown in FIG. 7B. FIG. 7B is a cross-sectional view illustrating a structure example of the semiconductor device. FIG. 7A is a top view corresponding to the cross-sectional view of FIG. 7B. Here, FIG. 7B is a cross-sectional view of a portion indicated by the dashed-dotted line A3-A4 in FIG. 7A, and is a cross-sectional view of the transistor 201 in the channel length direction. FIG. 7C is a cross-sectional view of a portion indicated by dashed-dotted line B1-B2 in FIG. 7A, and is a cross-sectional view of the transistor 201 in the channel width direction. Note that for clarity of the drawing, some components are omitted in the top view of FIG. 7A.

As illustrated in FIG. 7C, the top surface and the side surface of the metal oxide 230a and the side surface of the insulator 224a are covered with the insulator 250 and the conductor 260. The insulator 250 and the conductor 260 are provided in an opening 258a included in the insulator 280 and the insulator 275. Furthermore, a curved surface may be provided between a side surface of the metal oxide 230a and the top surface of the metal oxide 230a in a cross-sectional view of the transistor 201 in the channel width direction. In other words, an end portion of the side surface and an end portion of the top surface may be curved (hereinafter referred to as rounded). Here, the conductor 260 including the region functioning as the first gate electrode covers not only the top surface but also the side surface of the metal oxide 230a.

As illustrated in FIG. 7A, the conductor 205a is preferably provided to be larger than a region of the metal oxide 230a that does not overlap with the conductor 242a and the conductor 242b. As illustrated in FIG. 7C, it is particularly preferable that the conductor 205a extend to a region outside the end portion of the metal oxide 230a in the channel width direction. That is, the conductor 205a and the conductor 260 preferably overlap with each other with the insulators therebetween on the outer side of the side surface of the metal oxide 230a in the channel width direction. With this structure, the channel formation region of the metal oxide 230a can be electrically surrounded by the electric field of the conductor 260 functioning as a first gate electrode and the electric field of the conductor 205a functioning as the second gate electrode.

In this specification and the like, a transistor structure in which a channel formation region is electrically surrounded by at least the electric field of the first gate electrode is referred to as a surrounded channel (S-channel) structure. The S-channel structure disclosed in this specification and the like has a structure that is different from a Fin-type structure and a planar structure. The S-channel structure disclosed in this specification and the like can be regarded as a kind of the Fin-type structure. Note that in this specification and the like, the Fin-type structure refers to a structure in which a gate electrode is placed to cover at least two or more surfaces (specifically, two surfaces, three surfaces, or four surfaces) of a channel. With the use of the Fin-type structure and the S-channel structure, a transistor with high resistance to a short-channel effect, i.e., a transistor in which a short-channel effect is unlikely to occur, can be obtained.

When the transistor included in the semiconductor device of this embodiment has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or an LGAA (Lateral Gate All Around) structure. In the transistor having the s-channel structure, the GAA structure, or the LGAA structure, the channel formation region that is formed at the interface between an oxide and a gate insulator or in the vicinity of the interface can be the entire bulk of the oxide. Accordingly, the density of current flowing through the transistor can be improved, which can be expected to improve the on-state current of the transistor or increase the field-effect mobility of the transistor.

Although FIG. 7B illustrates a transistor with the S-channel structure as the transistor, the semiconductor device of one embodiment of the present invention is not limited thereto. For example, a transistor structure that can be used in one embodiment of the present invention may be one or more selected from the planar structure, the Fin-type structure, and the GAA structure.

The connection electrode 240a includes a region in contact with part of the top surface of the conductor 242a and a region in contact with part of the side surface of the conductor 242a. The connection electrode 240b includes a region in contact with part of the top surface of the conductor 242e and a region in contact with part of the side surface of the conductor 242e. Specifically, the conductor 231a includes a region in contact with part of the top surface of the conductor 242a and a region in contact with part of the side surface of the conductor 242a. The conductor 231b includes a region in contact with part of the top surface of the conductor 242e and a region in contact with part of the side surface of the conductor 242e. Such a structure eliminates the need for additionally providing electrodes for connection between the connection electrode 240a and the conductor 242a and between the connection electrode 240b and the conductor 242e, so that the area occupied by the memory cell array can be reduced. In addition, the integration degree of the memory cells can be increased and the memory capacity can be increased. When the connection electrode 240a is in contact with a plurality of surfaces of the conductor 242a, the contact resistance between the connection electrode 240a and the conductor 242a can be reduced. In addition, when the connection electrode 240b is in contact with a plurality of surfaces of the conductor 242e, the contact resistance between the connection electrode 240b and the conductor 242e can be reduced. Furthermore, since the need for additionally providing the electrode for connection is eliminated, the number of steps in the manufacturing process of the semiconductor device can be reduced.

Although FIG. 7A illustrates the structure in which the top surface of the conductor 231a has a quadrilateral shape with rounded corners, the present invention is not limited thereto. For example, the top surface of the conductor 231a may have a circular shape, an elliptical shape, a polygonal shape, or a polygonal shape with rounded corners. The polygonal shape here means a triangle, a quadrangle, a pentagon, a hexagon, and the like.

Note that in this specification and the like, the top surface shape of a component means the outline of the component in a plan view. A plan view means a view to observe the component from a normal direction of a surface where the component is formed or from a normal direction of a surface of a support (e.g., a substrate) where the component is formed.

As illustrated in FIG. 7B, an insulator 232a is provided in contact with the side surface of the conductor 231a. Specifically, the insulator 232a is provided in contact with the inner wall of the opening in the insulator 285, the insulator 283, the insulator 282, the insulator 280, the insulator 275, the insulator 222, the insulator 216, the insulator 214, and the insulator 212; and the conductor 231a is provided in contact with part of the top surface of the conductor 242a and part of the side surface thereof and the side surface of the insulator 232a. In other words, the conductor 231a is provided to fill the opening with the insulator 232a therebetween. In the opening, the insulator 232a includes a region in contact with the side surface of one or more of the insulator 285, the insulator 283, the insulator 282, the insulator 280, the insulator 275, the insulator 271a, the metal oxide 230a, the insulator 224a, the insulator 222, the insulator 216, the insulator 214, and the insulator 212.

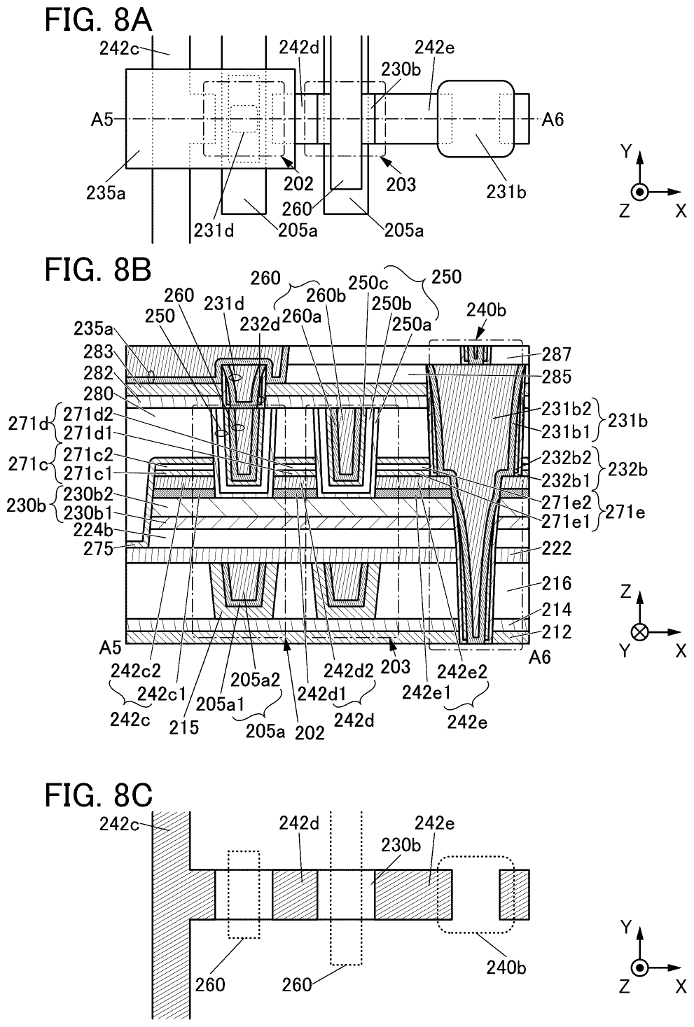

An enlarged view of the transistor 202, the transistor 203, the connection electrode 240b, and the vicinity thereof in FIG. 6 are shown in FIG. 8B. FIG. 8B is a cross-sectional view showing a structure example of the semiconductor device. FIG. 8A is a top view corresponding to the cross-sectional view of FIG. 8B. FIG. 8B is a cross-sectional view of a portion indicated by the dashed-dotted line A5-A6 in FIG. 8A, which corresponds to a cross-sectional view in the channel length direction of the transistor 203. Note that for clarity of the drawing, some components are not illustrated in the top view of FIG. 8A. Note that FIG. 7C can be referred to for a cross-sectional view of the transistor 203 in the channel width direction. Furthermore, the cross-sectional view in FIG. 7C can be referred to for a cross-sectional view of the transistor 202 in the channel width direction, except that the conductor 260 does not extend in the channel width direction.

As illustrated in FIG. 8B, an insulator 232b is provided in contact with the side surface of the conductor 231b. Specifically, the insulator 232b is provided in contact with the inner wall of the opening in the insulator 285, the insulator 283, the insulator 282, the insulator 280, the insulator 275, the insulator 222, the insulator 216, the insulator 214, and the insulator 212; and the conductor 231b is provided in contact with part of the top surface of the conductor 242e and part of the side surface thereof and the side surface of the insulator 232b. In other words, the conductor 231b is provided to fill the opening with the insulator 232b therebetween. In the opening, the insulator 232b includes a region in contact with the side surface of one or more of the insulator 285, the insulator 283, the insulator 282, the insulator 280, the insulator 275, the insulator 271e, the metal oxide 230b, the insulator 224b, the insulator 222, the insulator 216, the insulator 214, and the insulator 212.

FIG. 8C is a top view including the conductor 242c, the conductor 242d, the conductor 242e, and the metal oxide 230b in the top view in FIG. 8A. Note that in FIG. 8C, the outlines of the conductor 260 and the connection electrode 240b are each indicated by a dotted line.

As illustrated in FIG. 8C, the metal oxide 230b includes a first region that overlaps with the conductor 242c and extends in a first direction, a second region that overlaps with the conductor 260 included in the transistor 202, a third region that overlaps with the conductor 242d, and a fourth region that overlaps with the conductor 242e. In other words, the conductor 242c includes a region overlapping with the metal oxide 230b, the conductor 242d includes a region overlapping with the metal oxide 230b, and the conductor 242e includes a region overlapping with the metal oxide 230b.

In the first region, an end portion of the metal oxide 230b is aligned with an end portion of the conductor 242c. In addition, the first region includes a region extending in the channel width direction (Y direction) of the transistor 202. That is, the first direction is the Y direction. The conductor 242c includes a region extending in the Y direction. The conductor 242c can thus also function as a wiring. The metal oxide 230b is provided below a region of the conductor 242c that functions as a wiring.

In the third region, the end portion of the metal oxide 230b is aligned with an end portion of the conductor 242d. In the fourth region, the end portion of the metal oxide 230b is aligned with an end portion of the conductor 242e.

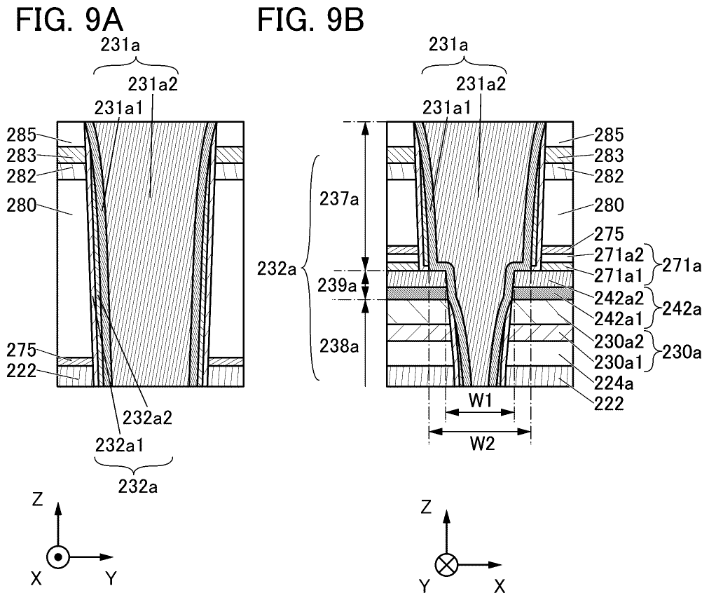

FIG. 9A and FIG. 9B are enlarged views of part of the connection electrode 240a and the vicinity thereof. FIG. 9A is an enlarged view of the part of the connection electrode 240a and the vicinity thereof in the channel width direction. FIG. 9B is an enlarged view of the part of the connection electrode 240a and the vicinity thereof in the channel length direction, and is also an enlarged view of the part of the connection electrode 240a and the vicinity thereof in FIG. 7B.

As illustrated in FIG. 9B, the insulator 232a includes a region 237a, a region 238a, and a region 239a. The region 237a is a region in contact with one or more of the insulator 285, the insulator 283, the insulator 282, the insulator 280, the insulator 275, and the insulator 271a. The region 238a is a region in contact with the side surface of one or more of the metal oxide 230a, the insulator 224a, the insulator 222, the insulator 216, the insulator 214, and the insulator 212. The region 239a is a region between the region 237a and the region 238a. In FIG. 9B, the insulator 232a is in contact with the side surfaces of the insulator 280 and the insulator 275 in the opening where the conductor 231a is provided.

In the conductor 231a included in the connection electrode 240a in FIG. 9B, the width of a region in contact with the side surface of the conductor 242a is referred to as a width W1. In other words, the width W1 is the distance between the conductors 242a. In the conductor 231a included in the connection electrode 240a, the width of a region in contact with the side surface of the insulator 232a in the region 237a is referred to as a width W2. In other words, the width W2 is the distance between the side surfaces of the insulator 232a in the region 237a.

The width W2 is preferably larger than the width W1 in the cross-sectional view of the transistor 201 in the channel length direction, as illustrated in FIG. 9B. With this structure, the connection electrode 240a is in contact with at least part of the top surface of the conductor 242a. Accordingly, the area of the region where the connection electrode 240a and the conductor 242a are in contact with each other can be increased. The connection electrode 240b preferably has a similar structure. Note that in this specification and the like, contact between the connection electrode 240 and the conductor 242 is referred to as top-side contact in some cases.

In other words, preferably, the opening where the connection electrode 240a is provided includes a region overlapping with the conductor 242a in the top view. With this structure, the connection electrode 240a is in contact with at least part of the top surface of the conductor 242a. Similarly, preferably, the opening where the connection electrode 240b is provided includes a region overlapping with the conductor 242e in the top view. With this structure, the connection electrode 240b is in contact with at least part of the top surface of the conductor 242e.

The uppermost portion of the insulator 232a in the region 238a is preferably positioned below the top surface of the conductor 242a. With this structure, the conductor 231a can be in contact with at least part of the side surface of the conductor 242a. Note that the insulator 232a in the region 238a preferably includes a region in contact with the side surface of the metal oxide 230a. This structure can inhibit impurities contained in the insulator 280 and the like, such as water and hydrogen, from entering the metal oxide 230a through the conductor 231a.

The above-described positional relationship between the conductor 231a, the conductor 242a, and the insulator 232a is also applied to the relationship between the conductor 231b, the conductor 242e, and the insulator 232b. Thus, the conductor 231a, the conductor 242a, and the insulator 232a can be replaced with the conductor 231b, the conductor 242e, and the insulator 232b, respectively. The insulator 232b includes a region corresponding to the region 237a, a region corresponding to the region 238a, and a region corresponding to the region 239a. For example, the insulator 232b is in contact with the side surfaces of the insulator 280 and the insulator 275 in the opening where the conductor 231b is provided.

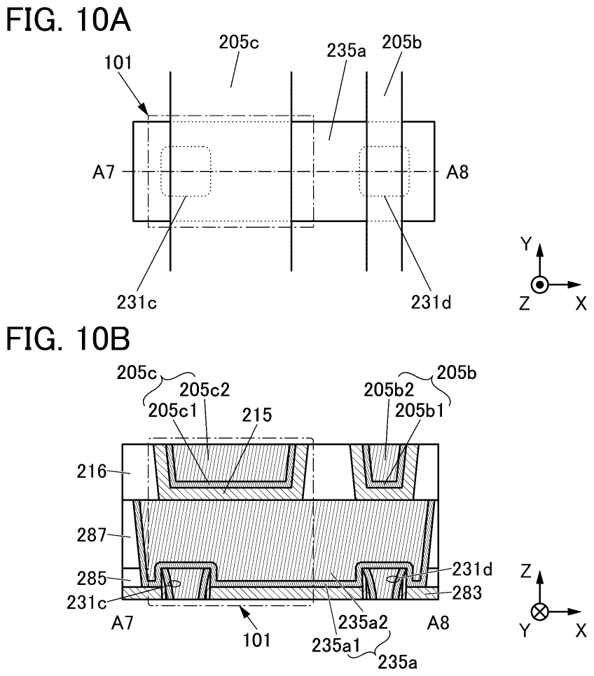

FIG. 10B is an enlarged view of the capacitor 101 and the vicinity thereof in FIG. 6. FIG. 10B is a cross-sectional view illustrating a structure example of the semiconductor device. FIG. 10A is a top view corresponding to the cross-sectional view of FIG. 10B. Here, FIG. 10B is a cross-sectional view of a portion indicated by dashed-dotted line A7-A8 in FIG. 10A, and is a cross-sectional view of the transistor 201 in the channel length direction. Note that for clarity of the drawing, some components are not illustrated in the top view of FIG. 10A.

As illustrated in FIG. 10A, the conductor 205c includes a region overlapping with the conductor 235a. In addition, the conductor 205c is provided to extend in the Y direction. That is, the first direction in which the first region of the metal oxide 230b extends is parallel to the direction in which the conductor 205c extends. The conductor 205c may have a two-layer stacked structure of a conductor 205cl and a conductor 205c2 over the conductor 205c1, as illustrated in FIG. 10B. Note that the conductor 205c can be formed using the same material in the same step as the conductor 205b. Thus, the conductor 205cl preferably includes the same conductive material as the conductor 205b1. The conductor 205c2 preferably includes the same conductive material as the conductor 205b2.

Next, the transistors, the capacitor, and the connection electrodes included in the semiconductor device of this embodiment will be described in detail.

A metal oxide functioning as a semiconductor (hereinafter, also referred to as an oxide semiconductor) is preferably used as the metal oxide 230. Note that the metal oxide functioning as a semiconductor preferably has a band gap of 2.0 eV or more, further preferably 2.5 eV or more. With the use of a metal oxide having a wide band gap, the off-state current of the transistor can be reduced.

As the metal oxide 230, a metal oxide such as indium oxide, gallium oxide, or zinc oxide is preferably used, for example. Alternatively, as the metal oxide 230, a metal oxide containing two or three selected from indium, an element M, and zinc is preferably used, for example. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin. Note that a metal oxide containing indium, the element M, and zinc is referred to as In-M-Zn oxide in some cases.

Although the metal oxide 230 is a single layer in the structure illustrated in FIG. 2B, the present invention is not limited to this. The metal oxide 230 may have a stacked-layer structure of two or more layers. For example, as illustrated in FIG. 7B and FIG. 8B, the metal oxide 230 may have a two-layer stacked structure of a first metal oxide and a second metal oxide over the first metal oxide. Here, the metal oxide 230a includes a metal oxide 230al as the first metal oxide and a metal oxide 230a2 as the second metal oxide. The metal oxide 230b includes a metal oxide 230b1 as the first metal oxide and a metal oxide 230b2 as the second metal oxide.

In the case where the metal oxide 230 has a stacked-layer structure of two or more layers, the metal oxide 230 preferably has a stacked-layer structure of a plurality of oxide layers with different chemical compositions. For example, in the case where the metal oxide 230 has a stacked-layer structure of two layers as illustrated in FIG. 7B and FIG. 8B, the atomic ratio of the element M to a metal element that is a main component in the metal oxide used as the first metal oxide is preferably higher than the atomic ratio of the element M to a metal element that is a main component in the metal oxide used as the second metal oxide. Moreover, the atomic ratio of the element M to In in the metal oxide used as the first metal oxide is preferably higher than the atomic ratio of the element M to In in the metal oxide used as the second metal oxide. With this structure, at least either of impurities or oxygen can be inhibited from diffusing into the second metal oxide from the components formed below the first metal oxide.

Furthermore, the atomic ratio of In to the element M in the metal oxide used as the second metal oxide is preferably higher than the atomic ratio of In to the element M in the metal oxide used as the first metal oxide. With this structure, the transistor can have a high on-state current and high frequency characteristics.

When the first metal oxide and the second metal oxide contain a common element as the main component besides oxygen, the density of defect states at an interface between the first metal oxide and the second metal oxide can be decreased. Thus, the influence of interface scattering on carrier conduction is small, and the transistor can have a high on-state current and high frequency characteristics.

Specifically, as the first metal oxide, a metal oxide with a composition of In:M:Zn=1:3:4 [atomic ratio] or in the neighborhood thereof, a composition of In:M:Zn=1:3:2 [atomic ratio] or in the neighborhood thereof, or a composition of In:M:Zn=1:1:0.5 [atomic ratio] or in the neighborhood thereof can be used. As the second metal oxide, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of +30% of an intended atomic ratio. Gallium is preferably used as the element M. The compositions of the metal oxides that can be used as the first metal oxide and the second metal oxide are not limited to the above. For example, the composition of the metal oxide that can be used as the first metal oxide may be applied to the second metal oxide. Similarly, the composition of the metal oxide that can be used as the second metal oxide may be applied to the first metal oxide. In the case where the metal oxide 230 is a single layer, a metal oxide that can be used as the first metal oxide or the second metal oxide may be used as the metal oxide 230.

When the metal oxide is deposited by a sputtering method, the above atomic ratio is not limited to the atomic ratio of the deposited metal oxide and may be the atomic ratio of a sputtering target used for depositing the metal oxide.

The second metal oxide of the metal oxide 230 includes a channel formation region of each transistor and a source region and a drain region provided to sandwich the channel formation region. At least part of the channel formation region overlaps with the conductor 260. The source region overlaps with one of a pair of conductors 242, and the drain region overlaps with the other of the pair of conductors 242. Note that the channel formation region, the source region, and the drain region may each be formed not only in the second metal oxide of the metal oxide 230 but also in the first metal oxide of the metal oxide 230.

A transistor using an oxide semiconductor is likely to have its electrical characteristics changed by impurities and oxygen vacancies in a channel formation region in the oxide semiconductor, which might reduce the reliability. In some cases, a defect that is an oxygen vacancy into which hydrogen in the vicinity of the oxygen vacancy has entered (hereinafter, sometimes referred to as VoH) is formed, which generates an electron serving as a carrier. Therefore, when the channel formation region in the oxide semiconductor includes oxygen vacancies, the transistor is likely to have normally-on characteristics (characteristics with which, even when no voltage is applied to the gate electrode, the channel exists and current flows through the transistor). Therefore, impurities, oxygen vacancies, and VoH are preferably reduced as much as possible in the channel formation region in the oxide semiconductor.

As a countermeasure against the above, an insulator containing oxygen that is released by heating (hereinafter, sometimes referred to as excess oxygen) is provided in the vicinity of the oxide semiconductor and heat treatment is performed, so that oxygen can be supplied from the insulator to the oxide semiconductor to reduce oxygen vacancies and VoH. However, supply of an excess amount of oxygen to the source region or the drain region might cause a decrease in the on-state current or field-effect mobility of the transistor. Furthermore, a variation in the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and VoH in the channel formation region of the oxide semiconductor are preferably reduced. Supply of an excess amount of oxygen to the source region and the drain region and excessive reduction in the amount of VoH in the source region and the drain region are preferably inhibited. Furthermore, a structure is preferable in which a reduction in the conductivity of the conductor 260, the conductor 242, and the like is inhibited. For example, a structure is preferable in which oxidation of the conductor 260, the conductor 242, and the like is inhibited. Note that hydrogen in the oxide semiconductor can form VoH; thus, the hydrogen concentration needs to be reduced in order to reduce the amount of VoH.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

Note that the carrier concentration of the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1× 1011 cm⁻³, or lower than 1×10¹⁰ cm⁻³. The lower limit of the carrier concentration of the channel formation region is not particularly limited and can be, for example, 1× 10⁻⁹ cm⁻³.

In order to reduce the carrier concentration in the metal oxide 230, the impurity concentration in the metal oxide 230 is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration may be referred to as a highly purified intrinsic or substantially highly purified intrinsic oxide semiconductor (or metal oxide).

An impurity in the metal oxide 230 refers to, for example, an element other than the main components of the metal oxide. For example, an element with a concentration lower than 0.1 atomic % can be regarded as an impurity. In the case where an oxide semiconductor is used as the metal oxide 230, examples of an impurity in the metal oxide 230 include hydrogen, nitrogen, an alkali metal, an alkaline earth metal, iron, nickel, and silicon.

The source region and the drain region have a large amount of oxygen vacancies or a high impurity concentration and thus are each a low-resistance region with a high carrier concentration. In other words, the source region and the drain region are each an n-type region (low-resistance region) having a higher carrier concentration than the channel formation region.

In the metal oxide 230, the boundary of each region is difficult to detect clearly in some cases. The concentrations of a metal element and impurity elements, which are detected in each region, may be not only gradually changed between the regions but also continuously changed in each region. That is, the region closer to the channel formation region may have lower concentrations of a metal element and impurity elements.

In order to obtain stable electrical characteristics of the transistor, reducing the impurity concentration in the metal oxide 230 is effective. In order to reduce the impurity concentration in the metal oxide 230, it is preferable that the impurity concentration in an adjacent film be also reduced.

An oxide semiconductor having crystallinity is preferably used for the second metal oxide of the metal oxide 230. Examples of an oxide semiconductor having crystallinity include a CAAC-OS (c-axis aligned crystalline oxide semiconductor), a nanocrystalline oxide semiconductor (nc-OS), a polycrystalline oxide semiconductor, and a single-crystal oxide semiconductor. For the second metal oxide of the metal oxide 230, a CAAC-OS or an nc-OS is preferably used, and the CAAC-OS is particularly preferably used.

The CAAC-OS is a metal oxide having a dense structure with high crystallinity and small amounts of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as the CAAC-OS, is used as the second metal oxide of the metal oxide 230, oxygen extraction from the second metal oxide by the source electrode or the drain electrode can be inhibited. This can inhibit oxygen extraction from the second metal oxide even when heat treatment is performed; thus, the transistor is stable with respect to high temperatures in a manufacturing process (what is called thermal budget). Furthermore, it is possible to inhibit a reduction in the conductivity of the conductor 242.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal (also referred as nanocrystal). Further, there is no regularity of crystal orientation between different nanocrystal parts in the nc-OS film; thus, the orientation of the whole film is not observed. That is, in the case where the nc-OS is used as the metal oxide 230, the metal oxide 230 has uniform film characteristics regardless of the direction of carriers flowing in the metal oxide 230; thus, the transistor has stable electrical characteristics.

Note that an oxide semiconductor has various structures with different properties. The metal oxide 230 may include two or more of the CAAC-OS, the nc-OS, an amorphous-like oxide semiconductor (a-like OS), an amorphous oxide semiconductor, a polycrystalline oxide semiconductor, and a cloud-aligned composite oxide semiconductor (CAC-OS).

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS. For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

In some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter equivalent to or less than the diameter of a nanocrystal (e.g., greater than or equal to 1 nm and less than or equal to 30 nm).

The metal oxide 230 can be rephrased as a semiconductor layer including a channel formation region of the transistor 201. Note that a material that can be used for the semiconductor layer is not limited to a metal oxide functioning as a semiconductor (an oxide semiconductor). For example, for the semiconductor layer, a semiconductor such as single crystal silicon, polycrystalline silicon, or amorphous silicon may be used; for example, LTPS may be used.

As the semiconductor layer, the transition metal chalcogenide functioning as a semiconductor may be used; for example, molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), or zirconium selenide (typically ZrSe₂) may be used.

An insulator containing excess oxygen is preferably used as the insulator 280 to supply oxygen to the channel formation region. With such a structure, oxygen included in the insulator 280 can be supplied to the channel formation region of the metal oxide 230 through the insulator 280.

For the insulator 280, for example, an oxide containing silicon such as silicon oxide, silicon oxynitride, silicon oxide to which fluorine is added, silicon oxide to which carbon is added, silicon oxide to which carbon and nitrogen are added, or porous silicon oxide is preferably used. In particular, silicon oxide and silicon oxynitride, which are thermally stable, are preferable. A material such as silicon oxide, silicon oxynitride, or porous silicon oxide is particularly preferably used, in which case a region containing oxygen released by heating can be easily formed.

The insulator 280 functions as an interlayer film and thus preferably has a low permittivity. When a material with a low dielectric constant is used for an interlayer film, parasitic capacitance generated between wirings can be reduced. The above-described oxide containing silicon is preferable because it is a material with a low permittivity.

The concentration of impurities such as water and hydrogen in the insulator 280 is preferably reduced. For example, the insulator 280 preferably contains an oxide containing silicon, such as silicon oxide or silicon oxynitride.

Note that in the opening portion of the insulator 280, the sidewall of the insulator 280 may be substantially perpendicular to the top surface of the insulator 222 or may have a tapered shape. The tapered sidewall can improve the coverage with the insulator 250 provided in the opening portion of the insulator 280, for example; as a result, the number of defects such as voids can be reduced. Alternatively, when the sidewall is substantially perpendicular to the top surface of the insulator 222, miniaturization or high integration of the semiconductor device can be achieved.

Note that in this specification and the like, a tapered shape refers to a shape such that at least part of the side surface of a component is inclined with respect to a substrate surface or a formation surface. For example, a tapered shape includes a region where the angle between the inclined side surface and the substrate surface or the formation surface (hereinafter, sometimes referred to as a taper angle) is less than 90°. Note that the side surface of the component and the substrate surface are not necessarily completely flat and may be substantially flat with a slight curvature or substantially flat with slight unevenness.

The insulator 250 includes a region functioning as a first gate insulator. Although FIG. 2B illustrates a single-layer structure of the insulator 250, the present invention is not limited to this structure, and a stacked-layer structure of two or more layers may be employed. For example, as illustrated in FIG. 7B and FIG. 8B, the insulator 250 may have a stacked-layer structure including three layers of an insulator 250a, an insulator 250b over the insulator 250a, and an insulator 250c over the insulator 250b.

An insulator that easily transmits oxygen is preferably used as the insulator 250b to supply oxygen to the channel formation region. With such a structure, oxygen included in the insulator 280 can be supplied to the channel formation region of the metal oxide 230 through the insulator 250b.

As the insulator 250b, for example, silicon oxide, silicon oxynitride, silicon oxide to which fluorine is added, silicon oxide to which carbon is added, silicon oxide to which carbon and nitrogen are added, porous silicon oxide, or the like can be used. In particular, silicon oxide and silicon oxynitride, which are thermally stable, are preferable. The insulator 250b in this case is an insulator containing at least oxygen and silicon.

The concentration of impurities such as water and hydrogen in the insulator 250b is preferably reduced.

The thickness of the insulator 250b is preferably greater than or equal to 0.5 nm and less than or equal to 20 nm, further preferably greater than or equal to 1 nm and less than or equal to 15 nm. In particular, in order to manufacture a minute transistor (e.g., a transistor with a gate length less than or equal to 10 nm), the thickness of the insulator 250b is preferably greater than or equal to 0.5 nm and less than or equal to 10 nm, further preferably greater than or equal to 0.5 nm and less than or equal to 5 nm. In this case, at least part of the insulator 250b may include a region having the above-described thickness.

The insulator 250a is provided in contact with the bottom surface of the insulator 250b, the top surface of the metal oxide 230, and the side surface of the metal oxide 230. The insulator 250a preferably has a barrier property against oxygen. Since the insulator 250a has a barrier property against oxygen, oxygen included in the insulator 250b can be supplied to the channel formation region, while oxygen included in the insulator 250b can be inhibited from being excessively supplied to the channel formation region. Thus, it is possible to inhibit excessive supply of oxygen to the source region and the drain region through the channel formation region and a decrease in the on-state current or field-effect mobility of the transistor. In addition, it is possible to inhibit release of oxygen from the metal oxide 230 when heat treatment or the like is performed and inhibit formation of oxygen vacancies in the metal oxide 230. Accordingly, the transistor can have favorable electrical characteristics and higher reliability.

The insulator 250a is provided between the insulator 280 and the insulator 250b and includes a region in contact with a sidewall of the opening included in the insulator 280. With such a structure, oxygen included in the insulator 280 can be supplied to the insulator 250b, while oxygen included in the insulator 280 can be inhibited from being excessively supplied to the insulator 250b.

An insulator containing an oxide of one or both of aluminum and hafnium is preferably used as the insulator 250a. As the insulator, aluminum oxide, hafnium oxide, an oxide containing aluminum and hafnium (hafnium aluminate), an oxide containing hafnium and silicon (hafnium silicate), or the like can be used. For the insulator 250a, magnesium oxide, gallium oxide, gallium zinc oxide, indium gallium zinc oxide, or the like may be used, for example. For the insulator 250a, a material that is less permeable to oxygen than the insulator 250b is used, for example.

In this embodiment, aluminum oxide is used for the insulator 250a. In this case, the insulator 250a contains at least oxygen and aluminum.

Aluminum oxide, which can be suitably used for the insulator 250a, has a function of inhibiting diffusion of hydrogen (e.g., at least one of a hydrogen atom, a hydrogen molecule, and the like). Thus, diffusion of impurities included in the insulator 250b, such as hydrogen, into the metal oxide 230 can be inhibited. The insulator 250a is a material that is less permeable to hydrogen than the insulator 250b, for example.

Note that the thickness of the insulator 250a is preferably small. When the thickness of the insulator 250a is reduced to form a minute transistor, a semiconductor device that can be miniaturized or highly integrated can be provided. When the thickness of the insulator 250a is reduced, a reduction in the amount of oxygen supplied to the metal oxide 230 through the insulator 250b can be inhibited. The thickness of the insulator 250a is specifically greater than or equal to 0.1 nm and less than or equal to 5.0 nm, preferably greater than or equal to 0.5 nm and less than or equal to 3.0 nm, further preferably greater than or equal to 1.0 nm and less than 3.0 nm. In this case, at least part of the insulator 250a may include a region with a thickness like the above-described thickness. For example, the thickness of the insulator 250a preferably includes a region having a smaller thickness than the thickness of the insulator 250b. In this case, at least part of the insulator 250a may include a region having a thickness that is smaller than that of the insulator 250b.

To form the insulator 250a having a small thickness as described above, an atomic layer deposition (ALD) method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because deposition at a lower temperature is possible.

An ALD method, which enables atomic layers to be deposited one by one, has advantages such as formation of an extremely thin film, film formation on a component with a high aspect ratio, formation of a film with a small number of defects such as pinholes, film formation with excellent coverage, and low-temperature film formation. Therefore, the insulator 250a can be formed on the side surface of the opening formed in the insulator 280 and the like with a small thickness like the above-described thickness and good coverage.

Note that some of precursors usable in an ALD method contain carbon or the like. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

The insulator 250a is provided between the insulator 250b and the conductor 242. When the thickness of the insulator 250a is reduced, the side surface of the conductor 242 is oxidized to form an insulator between the conductor 242 and the insulator 250a in some cases. In other words, the transistor sometimes includes an insulator between the conductor 242 and the insulator 250a.

The insulator is formed in a self-aligned manner in the formation of the conductor 242 or in the process after the formation of the conductor 242. Thus, the parasitic capacitance of the conductor 242 and the conductor 260 can be reduced in a self-aligned manner.

The above insulator includes an element included in the conductor 242 and oxygen. For example, in the case where a material including a metal element is used for the conductor 242, the insulator includes the metal element and oxygen. For example, in the case where a conductive material including a metal element and nitrogen is used for the conductor 242, the insulator includes the metal element, oxygen, and nitrogen.

The insulator 250c preferably has a barrier property against hydrogen. Accordingly, diffusion of impurities contained in the conductor 260, such as hydrogen, into the insulator 250b and the metal oxide 230 can be inhibited. For example, silicon nitride deposited by a PEALD method is used for the insulator 250c. In this case, the insulator 250c contains at least nitrogen and silicon. As the insulator 250c, aluminum oxide, magnesium oxide, hafnium oxide, gallium oxide, indium gallium zinc oxide, silicon nitride oxide, or the like may be used, for example. For the insulator 250c, a material that is less permeable to hydrogen than the insulator 250b is used, for example.

The insulator 250c may further have a barrier property against oxygen. The insulator 250c is provided between the insulator 250b and the conductor 260. Thus, diffusion of oxygen included in the insulator 250b into the conductor 260 can be prevented, so that oxidation of the conductor 260 can be inhibited. A reduction in the amount of oxygen supplied to the metal oxide 230 can be inhibited. For the insulator 250c, a material that is less permeable to oxygen than the insulator 250b is used, for example.

The insulator 250c needs to be provided together with the insulator 250a, the insulator 250b, and the conductor 260 in the opening formed in the insulator 280 and the like. The thickness of the insulator 250c is preferably small for miniaturization of the transistor. The thickness of the insulator 250c is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of each of the insulator 250c includes a region having the above-described thickness. The thickness of the insulator 250c is preferably smaller than the thickness of the insulator 250b. In this case, at least part of the insulator 250c may include a region having a thickness that is smaller than that of the insulator 250b.

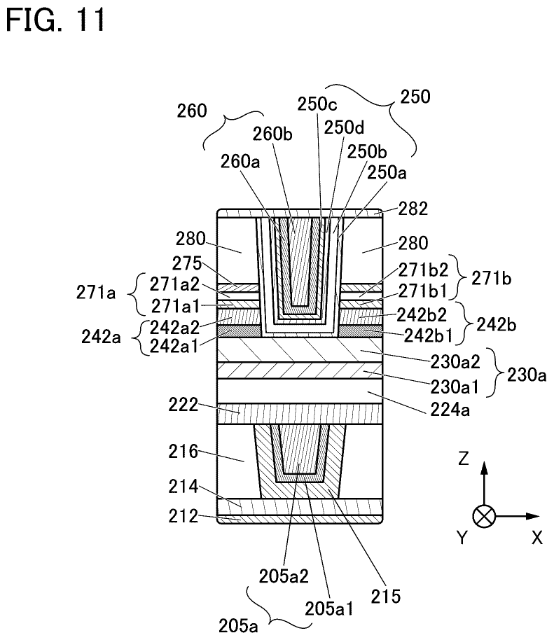

The insulator 250 may have a four-layer stacked structure of the insulator 250a to an insulator 250d, as illustrated in FIG. 11. In this case, the insulator 250d is provided between the insulator 250b and the insulator 250c. The insulator 250d is preferably formed using an insulator having a function of inhibiting diffusion of oxygen. With such a structure, oxygen included in the insulator 250b can be inhibited from diffusing into the conductor 260. That is, a reduction in the amount of oxygen supplied to the metal oxide 230 can be inhibited. In addition, oxidation of the conductor 260 due to oxygen included in the insulator 250b can be inhibited. An insulator including an oxide of one or both of aluminum and hafnium may be used as the insulator 250d. As the insulator, aluminum oxide, hafnium oxide, an oxide including aluminum and hafnium (hafnium aluminate), an oxide including hafnium and silicon (hafnium silicate), or the like can be used. In this embodiment, hafnium oxide is used for the insulator 250d. In that case, the insulator 250d contains at least oxygen and hafnium. The thickness of the insulator 250d is greater than or equal to 0.5 nm and less than or equal to 5.0 nm, preferably greater than or equal to 1.0 nm and less than or equal to 5.0 nm, further preferably greater than or equal to 1.0 nm and less than or equal to 3.0 nm. In this case, it is acceptable that at least part of the insulator 250d has a region with the above-described thickness.

In the case where silicon oxide, silicon oxynitride, or the like is used for the insulator 250b, the insulator 250d may be formed using an insulating material that is a high-k material having a high relative permittivity. With such a structure, a stacked-layer structure that is thermally stable and has a high relative dielectric constant can be obtained. Accordingly, a gate potential applied during the operation of the transistor can be reduced while the physical thickness of the gate insulator is maintained. In addition, the equivalent oxide thickness (EOT) of the insulator functioning as the gate insulator can be reduced. Therefore, the withstand voltage of the insulator 250 can be increased.

Note that when an insulator having a function of inhibiting passage of oxygen and impurities such as hydrogen, e.g., hafnium oxide, is used as the insulator 250d, the insulator 250d can also have the function of the insulator 250c. In such a case, the structure without the insulator 250c enables simplification of the manufacturing process and the improvement in productivity of the semiconductor device.

Note that in this specification and the like, a barrier insulator refers to an insulator having a barrier property. A barrier property in this specification and the like means a function of inhibiting diffusion of a targeted substance (also referred to as having low permeability). Alternatively, the barrier property means a function of capturing and fixing (also referred to as gettering) a targeted substance.

Examples of the barrier insulator against oxygen include an oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

Examples of the barrier insulator against hydrogen include oxides such as aluminum oxide, hafnium oxide, and tantalum oxide and nitrides such as silicon nitride.

The insulator 275 preferably has a barrier property against oxygen. The insulator 275 is provided between the insulator 280 and the conductor 242. With this structure, oxygen contained in the insulator 280 can be inhibited from diffusing into the conductor 242. Thus, the conductor 242 can be inhibited from being oxidized by oxygen contained in the insulator 280, so that an increase in resistivity and a reduction in on-state current can be inhibited. It is preferable that oxygen be less likely to pass through the insulator 275 than at least the insulator 280. For example, silicon nitride is preferably used for the insulator 275. In that case, the insulator 275 contains at least nitrogen and silicon. In this case, the insulator 275 includes at least nitrogen and silicon.

When the insulator included in the transistor has the above structure, the channel formation region can be an i-type or substantially i-type region, and the source region and the drain region can be n-type regions; thus, a semiconductor device with excellent electrical characteristics can be provided. The semiconductor device with the above structure can have excellent electrical characteristics even when scaled down or highly integrated. Scaling down of the transistor can improve the high-frequency characteristics. Specifically, the cutoff frequency can be improved.

The conductor 205a is placed to overlap with the metal oxide 230 and the conductor 260. Here, the conductor 205a is preferably provided to be embedded in an opening portion formed in the insulator 216. Part of the conductor 205a is embedded in the insulator 214 in some cases.

Although the conductor 205a in FIG. 2B is a single layer, the present invention is not limited to this. For example, the conductor 205a may have a stacked-layer structure of two or more layers. For example, as illustrated in FIG. 7B and FIG. 8B, the conductor 205a may have a stacked-layer structure of a conductor 205al and a conductor 205a2 over the conductor 205a1.

In the case where the conductor 205a has a two-layer stacked structure of the conductor 205al and the conductor 205a2, the conductor 205al is provided in contact with the bottom surface and sidewall of the opening portion formed in the insulator 216. The conductor 205a2 is provided to be embedded in a depressed portion formed in the conductor 205a1. Here, the top surface of the conductor 205a2 is level with each of the top surface of the conductor 205al and the top surface of the insulator 216.

Here, for the conductor 205a1, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to contain a conductive material having a function of inhibiting diffusion of oxygen (e.g., at least one of an oxygen atom, an oxygen molecule, and the like).

When a conductive material having a function of inhibiting diffusion of hydrogen is used for the conductor 205a1, impurities such as hydrogen contained in the conductor 205a2 can be inhibited from diffusing into the metal oxide 230 through the insulator 216, the insulator 224, and the like. When a conductive material having a function of inhibiting diffusion of oxygen is used for the conductor 205a1, the conductivity of the conductor 205a2 can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 205al can have a single-layer structure or a stacked-layer structure of the above conductive material. For example, the conductor 205al preferably contains titanium nitride.

A conductive material containing tungsten, copper, or aluminum as its main component is preferably used for the conductor 205a2. For example, the conductor 205a2 preferably contains tungsten.

The conductor 205a can function as the second gate electrode. In that case, by changing a potential applied to the conductor 205a not in conjunction with but independently of a potential applied to the conductor 260, the threshold voltage (Vth) of the transistor can be controlled. In particular, by applying a negative potential to the conductor 205a, Vth of the transistor can be higher, and its off-state current can be reduced. Thus, a drain current at the time when a potential applied to the conductor 260 is 0 V can be lower in the case where a negative potential is applied to the conductor 205a than in the case where the negative potential is not applied to the conductor 205a.

The electrical resistivity of the conductor 205a is designed in consideration of the potential applied to the conductor 205a, and the thickness of the conductor 205a is set in accordance with the electrical resistivity. The thickness of the insulator 216 is substantially equal to the thickness of the conductor 205a. Here, the conductor 205a and the insulator 216 are preferably as thin as possible in the allowable range of the design of the conductor 205a. When the thickness of the insulator 216 is reduced, the absolute amount of impurities such as hydrogen contained in the insulator 216 can be reduced, so that diffusion of the impurities into the metal oxide 230 can be reduced.

The insulator 222 and the insulator 224 function as a second gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

The insulator 222 preferably includes an insulator containing an oxide of one or both of aluminum and hafnium, which is an insulating material. For the insulator, aluminum oxide, hafnium oxide, or an oxide containing aluminum and hafnium (hafnium aluminate) is preferably used. Alternatively, an oxide containing hafnium and zirconium is preferably used. In the case where the insulator 222 is formed using such a material, the insulator 222 functions as a layer that inhibits release of oxygen from the metal oxide 230 to the substrate side and diffusion of impurities such as hydrogen from the periphery of the transistor into the metal oxide 230. Thus, providing the insulator 222 can inhibit diffusion of impurities such as hydrogen to the inside of the transistor and inhibit generation of oxygen vacancies in the metal oxide 230. Moreover, the conductor 205a2 can be inhibited from reacting with oxygen contained in the insulator 224 and the metal oxide 230.

Alternatively, aluminum oxide, bismuth oxide, germanium oxide, niobium oxide, silicon oxide, titanium oxide, tungsten oxide, yttrium oxide, or zirconium oxide may be added to the above insulators, for example. Alternatively, these insulators may be subjected to nitriding treatment. A stack of silicon oxide, silicon oxynitride, silicon nitride, silicon nitride oxide, or silicon nitride over the above insulators may be used for the insulator 222.

For example, the insulator 222 may have a single-layer structure or a stacked-layer structure of an insulator(s) containing what is called a high-k material such as aluminum oxide, hafnium oxide, tantalum oxide, zirconium oxide, or hafnium zirconium oxide. As scaling down and high integration of transistors progress, a problem such as leakage current may arise because of a thinner gate insulator. When a high-k material is used for the insulator functioning as a gate insulator, a gate potential at the time of the operation of the transistor can be reduced while the physical thickness is maintained. Furthermore, a substance with a high dielectric constant such as lead zirconate titanate (PZT), strontium titanate (SrTiO₃), or (Ba,Sr)TiO₃ (BST) can be used for the insulator 222 in some cases.

The insulator 224 that is in contact with the metal oxide 230 preferably contains silicon oxide or silicon oxynitride, for example.

Note that the insulator 222 and the insulator 224 may each have a stacked-layer structure of two or more layers. In that case, without limitation to a stacked-layer structure formed of the same material, a stacked-layer structure formed of different materials may be employed.

A conductive material that is not easily oxidized or a conductive material having a function of inhibiting oxygen diffusion is preferably used for each of the conductor 242 and the conductor 260. Examples of the conductive material include a conductive material containing nitrogen and a conductive material containing oxygen. This can inhibit a reduction in the conductivity of the conductor 242 and the conductor 260. In the case where a conductive material containing metal and nitrogen is used for the conductor 242 and the conductor 260, the conductor 242 and the conductor 260 contain at least metal and nitrogen.

Although the conductor 242 in FIG. 2B is a single layer, the present invention is not limited to this. The conductor 242 may have a stacked-layer structure of two or more layers.

For example, the conductor 242 illustrated in FIG. 7B and FIG. 8B has a two-layer structure of a first conductor and a second conductor over the first conductor. In the conductor 242a, the first conductor corresponds to a conductor 242a1, and the second conductor corresponds to a conductor 242a2. In the conductor 242b, the first conductor corresponds to a conductor 242b1, and the second conductor corresponds to a conductor 242b2. In the conductor 242c, the first conductor corresponds to a conductor 242c1, and the second conductor corresponds to a conductor 242c2. In the conductor 242d, the first conductor corresponds to a conductor 242d1, and the second conductor corresponds to a conductor 242d2. In the conductor 242e, the first conductor corresponds to a conductor 242e1, and the second conductor corresponds to a conductor 242e2.

In the case where the conductor 242 has a two-layer stacked structure, a conductive material that is not easily oxidized or a conductive material having a function of inhibiting oxygen diffusion is preferably used for the first conductor of the conductor 242 in contact with the metal oxide 230. In that case, the conductivity of the conductor 242 can be inhibited from being reduced. For the first conductor of the conductor 242, a material that is likely to absorb (extract) hydrogen is preferably used, in which case the hydrogen concentration in the metal oxide 230 can be reduced.

The second conductor of the conductor 242 preferably has higher conductivity than the first conductor of the conductor 242. For example, the thickness of the second conductor of the conductor 242 is preferably larger than the thickness of the first conductor of the conductor 242.

For example, it is preferable to use a conductive material containing nitrogen for the first conductor of the conductor 242 and use tungsten, copper, or aluminum for the second conductor of the conductor 242. In that case, the first conductor of the conductor 242 includes a region having a higher nitrogen concentration than that of the second conductor of the conductor 242. Specifically, tantalum nitride or titanium nitride can be used for the first conductor of the conductor 242, and tungsten can be used for the second conductor of the conductor 242.

To inhibit a reduction in the conductivity of the conductor 242, an oxide having crystallinity, such as a CAAC-OS, is preferably used as the metal oxide 230. Specifically, a metal oxide containing indium, zinc, and one or more selected from gallium, aluminum, and tin is preferably used. When a CAAC-OS is used, oxygen extraction from the metal oxide 230 by the conductor 242 can be inhibited. Furthermore, it is possible to inhibit a reduction in the conductivity of the conductor 242.

As the conductor 242, for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. For another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that, for example, hydrogen contained in the metal oxide 230 diffuses into the conductor 242 in some cases. In particular, when a nitride containing tantalum is used for the conductor 242, for example, hydrogen contained in the metal oxide 230 is likely to diffuse into the conductor 242, and the diffused hydrogen is bonded to nitrogen contained in the conductor 242 in some cases. That is, hydrogen contained in the metal oxide 230 or the like is sometimes absorbed by the conductor 242, for example.

The conductor 260 is placed such that its top surface is substantially level with the top surface of the insulator 250 and the top surface of the insulator 280.

The conductor 260 functions as the first gate electrode of the transistor.

Although the conductor 260 in FIG. 2B is a single layer, the present invention is not limited to this. The conductor 260 may have a stacked structure of two or more layers. For example, as illustrated in FIG. 7B and FIG. 8B, the conductor 260 may have a stacked-layer structure of a conductor 260a and a conductor 260b over the conductor 260a. In this case, the conductor 260a is preferably placed to cover the bottom surface and the side surface of the conductor 260b.

In the case where the conductor 260 has a two-layer stacked structure, a conductive material that is not easily oxidized or a conductive material having a function of inhibiting oxygen diffusion is preferably used for the conductor 260a.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the conductor 260a has a function of inhibiting oxygen diffusion, for example, the conductivity of the conductor 260b can be inhibited from being lowered because of oxidation due to oxygen contained in the insulator 280. As the conductive material having a function of inhibiting oxygen diffusion, for example, titanium, titanium nitride, tantalum, tantalum nitride, ruthenium, or ruthenium oxide is preferably used.

As the conductor 260, a conductor having high conductivity is preferably used. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

In the transistor, the conductor 260 is formed in a self-aligned manner to fill the opening formed in the insulator 280, for example. The formation of the conductor 260 in this manner allows the conductor 260 to be placed properly in a region between the pair of conductors 242 without alignment.

One or more of the insulator 212, the insulator 214, the insulator 282, and the insulator 283 preferably function as a barrier insulating film, which inhibits diffusion of impurities such as water and hydrogen into the transistor from the substrate side or from above the transistor. Thus, one or more of the insulator 212, the insulator 214, the insulator 282, and the insulator 283 preferably contain an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), or a copper atom (an insulating material through which the impurities are less likely to pass). Alternatively, it is preferable to contain an insulating material having a function of inhibiting diffusion of oxygen (e.g., at least one of an oxygen atom, an oxygen molecule, and the like) (an insulating material through which the oxygen is less likely to pass).

The insulator 212, the insulator 214, the insulator 282, and the insulator 283 each preferably include an insulator having a function of inhibiting diffusion of oxygen and impurities such as water and hydrogen; for example, aluminum oxide, magnesium oxide, hafnium oxide, gallium oxide, indium gallium zinc oxide, silicon nitride, silicon nitride oxide, or the like can be used. For example, silicon nitride, which has a higher hydrogen barrier property, is preferably used for the insulator 212 and the insulator 283. For example, the insulator 214 and the insulator 282 preferably contain aluminum oxide, magnesium oxide, or the like, which has an excellent function of capturing and fixing hydrogen. The above structure can inhibit impurities such as water and hydrogen from diffusing from the substrate side to the transistor side through the insulator 212 and the insulator 214. Furthermore, impurities such as water and hydrogen can be inhibited from diffusing to the transistor side from an interlayer insulating film and the like placed outside the insulator 282 and the insulator 283. In addition, oxygen contained in the insulator 280 and the like can be inhibited from diffusing to the components over the transistor through the insulator 282 and the insulator 283. In this manner, it is preferable that the transistor be surrounded by the insulators having a function of inhibiting diffusion of oxygen and impurities such as water and hydrogen.

The dielectric constant of each of the insulator 216, the insulator 280, the insulator 285, the insulator 287, the insulator 181, and the insulator 185 is preferably lower than that of the insulator 214. When a material with a low dielectric constant is used for an interlayer film, parasitic capacitance generated between wirings can be reduced.

For example, the insulator 216, the insulator 280, the insulator 285, the insulator 287, the insulator 181, and the insulator 185 each preferably contain one or more of silicon oxide, silicon oxynitride, silicon oxide to which fluorine is added, silicon oxide to which carbon is added, silicon oxide to which carbon and nitrogen are added, and porous silicon oxide.

In particular, silicon oxide and silicon oxynitride, which are thermally stable, are preferable. A material such as silicon oxide, silicon oxynitride, or porous silicon oxide is particularly preferably used, in which case a region containing oxygen released by heating can be easily formed.

The top surfaces of the insulator 216, the insulator 280, the insulator 285, the insulator 287, the insulator 181, and the insulator 185 may be planarized.

For the conductor 235a included in the capacitor 101, any of the materials that can be used for the conductor 205a, the conductor 242, and the conductor 260 can be used. The conductor 235a is preferably formed by a deposition method that offers good coverage, such as an ALD method or a chemical vapor deposition (CVD) method.

Although the conductor 235a in FIG. 2B is a single layer, the present invention is not limited to this. For example, the conductor 235a may have a stacked-layer structure of two or more layers. For example, as illustrated in FIG. 10B, the conductor 235a preferably includes a conductor 235al and a conductor 235a2 over the conductor 235a1. For example, titanium nitride deposited by an ALD method can be used for the conductor 235al, and tungsten deposited by a CVD method can be used for the conductor 235a2. Note that in the case where the adhesion of tungsten to the insulator 283 is sufficiently high, a single-layer structure of tungsten deposited by a CVD method may be used for the conductor 235a.

For the insulator 215 included in the capacitor 101, a high dielectric constant (high-k) material (a material with a high relative permittivity) is preferably used. The insulator 215 is preferably formed by a deposition method that offers good coverage, such as an ALD method or a CVD method.

Examples of insulators of the high dielectric constant (high-k) material include an oxide, an oxynitride, a nitride oxide, and a nitride containing one or more kinds of metal elements selected from aluminum, hafnium, zirconium, gallium, and the like. The above-described oxide, oxynitride, nitride oxide, and nitride may contain silicon. Stacked insulators formed of any of the above-described materials can also be used.

Examples of the insulators of the high dielectric constant (high-k) material include aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, and an oxynitride containing hafnium and zirconium. Using such a high-k material allows the insulator 215 to be thick enough to inhibit leakage current and the capacitor 101 to have a sufficiently high capacitance.

It is preferable to use stacked insulators formed of any of the above-described materials, and it is preferable to use a stacked-layer structure of a high dielectric constant (high-k) material and a material having a higher dielectric strength than the high dielectric constant (high-k) material. As the insulator 215, an insulator in which zirconium oxide, aluminum oxide, and zirconium oxide are stacked in this order can be used, for example. For another example, an insulator in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. Using such stacked insulators with relatively high dielectric strength, such as aluminum oxide, can increase the dielectric strength and inhibit electrostatic breakdown of the capacitor 101. In the case where stacked insulators are used, the layers are preferably formed without exposure to the air (also referred to as “successively formed”). For example, the insulators may be deposited successively by a thermal ALD method.

The conductor 205c can be formed with the same material in the same step as the conductor 205b. The conductor 205b can be formed with the same material in the same step as the conductor 205a. Thus, the conductor 205c preferably includes the same conductive material as the conductor 205a or the conductor 205b.

Although the conductor 231 in FIG. 2B is a single layer, the present invention is not limited to this. The semiconductor layer 231 may have a stacked-layer structure of two or more layers. For example, as illustrated in FIG. 7B and FIG. 8B, the conductor 231 preferably has a stacked-layer structure of a first conductor and a second conductor over the first conductor. In the conductor 231a, the first conductor corresponds to a conductor 231a1, and the second conductor corresponds to a conductor 231a2. In the conductor 231b, the first conductor corresponds to a conductor 231b1, and the second conductor corresponds to a conductor 231b2.

For example, as illustrated in FIG. 7B and FIG. 8B, the second conductor of the conductor 231 can be provided in the opening formed in the insulator 285, the insulator 283, the insulator 282, the insulator 280, the insulator 275, the insulator 222, the insulator 216, the insulator 214, and the insulator 212, and the first conductor of the conductor 231 can be provided between the opening and the second conductor. The first conductor of the conductor 231 includes a region in contact with at least part of the top surface and side surface of the conductor 242.

A conductive material having a function of inhibiting passage of impurities such as water and hydrogen is preferably used for the first conductor of the conductor 231. The first conductor of the conductor 231 can have a single-layer structure or a stacked-layer structure including one or more of tantalum, tantalum nitride, titanium, titanium nitride, ruthenium, and ruthenium oxide, for example. Thus, impurities such as water and hydrogen can be inhibited from entering the metal oxide 230 through the conductor 231.

The conductor 231 also functions as a wiring and thus is preferably formed using a conductor having high conductivity. For example, a conductive material containing tungsten, copper, or aluminum as its main component can be used for the second conductor of the conductor 231.

For example, it is preferable to use titanium nitride for the first conductor of the conductor 231 and tungsten for the second conductor of the conductor 231. In that case, the first conductor of the conductor 231 contains titanium and nitrogen, and the second conductor of the conductor 231 contains tungsten.

The insulator 232 is provided in contact with the insulator 285, the insulator 283, the insulator 282, the insulator 280, the insulator 275, the insulator 271, the metal oxide 230, the insulator 222, the insulator 216, the insulator 214, and the insulator 212. For the insulator 232, a barrier insulating film that can be used for the insulator 275 or the like may be used. For the insulator 232, for example, an insulator such as silicon nitride, aluminum oxide, or silicon nitride oxide may be used. This structure can inhibit impurities contained in the insulator 280 and the like, such as water, from entering the metal oxide 230 through the conductor 231. In particular, silicon nitride is suitable because of having a high barrier property against hydrogen. Furthermore, oxygen contained in the insulator 280 can be inhibited from being absorbed by the conductor 231.

Although the insulator 232 in FIG. 2B is a single layer, the present invention is not limited to this. The insulator 232 may have a stacked-layer structure of two or more layers.

For example, in FIG. 7B and FIG. 8B, the insulator 232 has a two-layer structure of a first insulator and a second insulator over the first insulator. In the insulator 232a, the first insulator corresponds to an insulator 232a1, and the second insulator corresponds to an insulator 232a2. In the insulator 232b, the first insulator corresponds to an insulator 232b1, and the second insulator corresponds to an insulator 232b2.

When the insulator 232 has a stacked-layer structure illustrated in FIG. 7B and FIG. 8B, a first insulator in contact with an inner wall of the opening formed in the insulator 280 and the like and a second insulator on the inner side of the first insulator are preferably formed using a combination of a barrier insulating film against oxygen and a barrier insulating film against hydrogen. For example, aluminum oxide deposited by an ALD method is used for the first insulator and silicon nitride deposited by a PEALD method is used for the second insulator. With this structure, oxidation of the conductor 231 can be inhibited, and hydrogen can be prevented from entering the conductor 231.

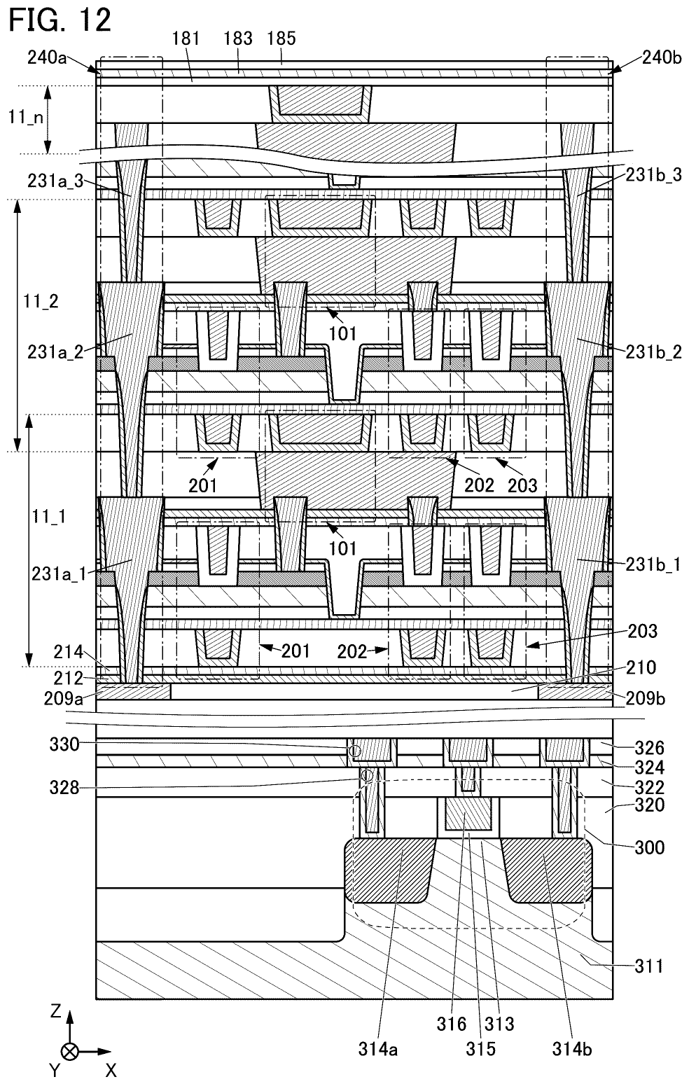

FIG. 12 is a cross-sectional view illustrating a structure example of the semiconductor device of one embodiment of the present invention. The semiconductor device illustrated in FIG. 12 is an example in which a layer including a transistor 300 is provided under the structure illustrated in FIG. 1, for example. The transistor 300 can be provided in a driver circuit of a memory cell formed above the insulator 210, for example. Note that the structure above the insulator 210 in FIG. 12 is similar to that in FIG. 1, thus, the detailed description thereof is omitted.

FIG. 12 illustrates an example of the transistor 300. The transistor 300 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 300 may be either a p-channel transistor or an n-channel transistor. As the substrate 311, a single crystal silicon substrate can be used, for example.

Here, in the transistor 300 illustrated in FIG. 12, the semiconductor region 313 (part of the substrate 311) in which a channel is formed has a protruding shape. The conductor 316 is provided to cover the side surface and top surface of the semiconductor region 313 with the insulator 315 therebetween. Note that a material adjusting the work function may be used for the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI (Silicon on Insulator) substrate.

Note that the transistor 300 illustrated in FIG. 12 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are stacked in this order over the transistor 300 as an interlayer film. A conductor 328 or the like is embedded in the insulator 320 and the insulator 322. A conductor 330 or the like is embedded in the insulator 324 and the insulator 326. Note that the conductor 328 and the conductor 330 function as a contact plug or a wiring.

The insulators functioning as the interlayer film may also function as a planarization film that covers an uneven shape thereunder. For example, the top surface of the insulator 322 may be planarized by planarization treatment using a chemical mechanical polishing (CMP) method or the like to have improved planarity.

The OS transistor can be formed in a BEOL (Back end of line) process forming a wiring of a semiconductor device. Thus, the OS transistor can be formed directly above the transistor 300.

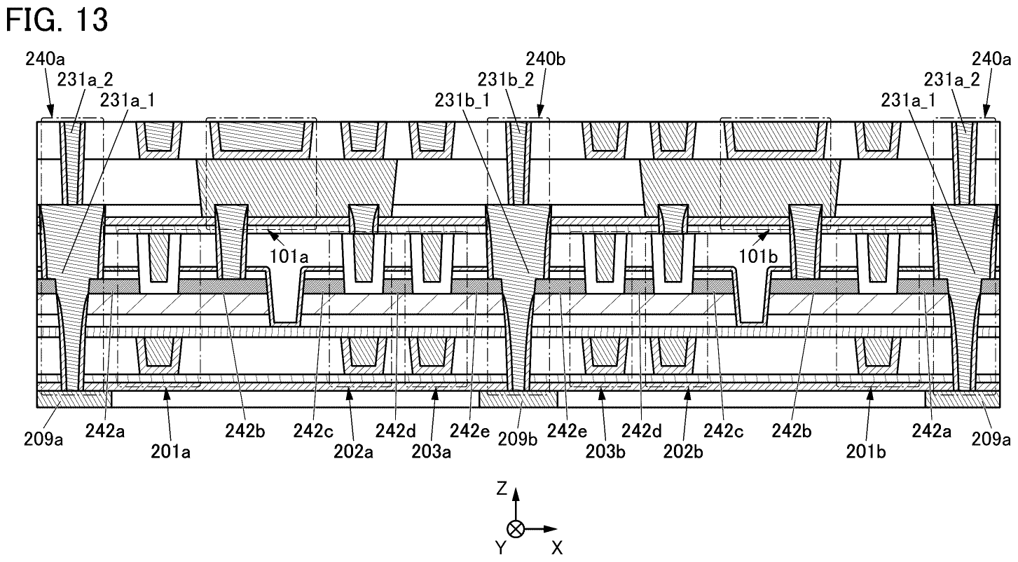

FIG. 13 is a cross-sectional view illustrating an example in which two memory cells are arranged in the X direction. FIG. 13 illustrates a memory cell including a transistor 201a, a transistor 202a, a transistor 203a, and a capacitor 101a and a memory cell including a transistor 201b, a transistor 202b, a transistor 203b, and a capacitor 101b, as the memory cells each including the transistor 201, the transistor 202, the transistor 203, and the capacitor 101.

As illustrated in FIG. 13, the connection electrode 240b can be electrically connected to the conductor 242e included in the transistor 203a and the conductor 242e included in the transistor 203b. Thus, the connection electrode 240b can be shared by two memory cells adjacent to each other in the X direction, for example. The connection electrode 240a can be electrically connected to two conductors 242a adjacent to each other in the X direction, for example. Thus, the connection electrode 240a can also be shared by two memory cells adjacent to each other in the X direction, for example.

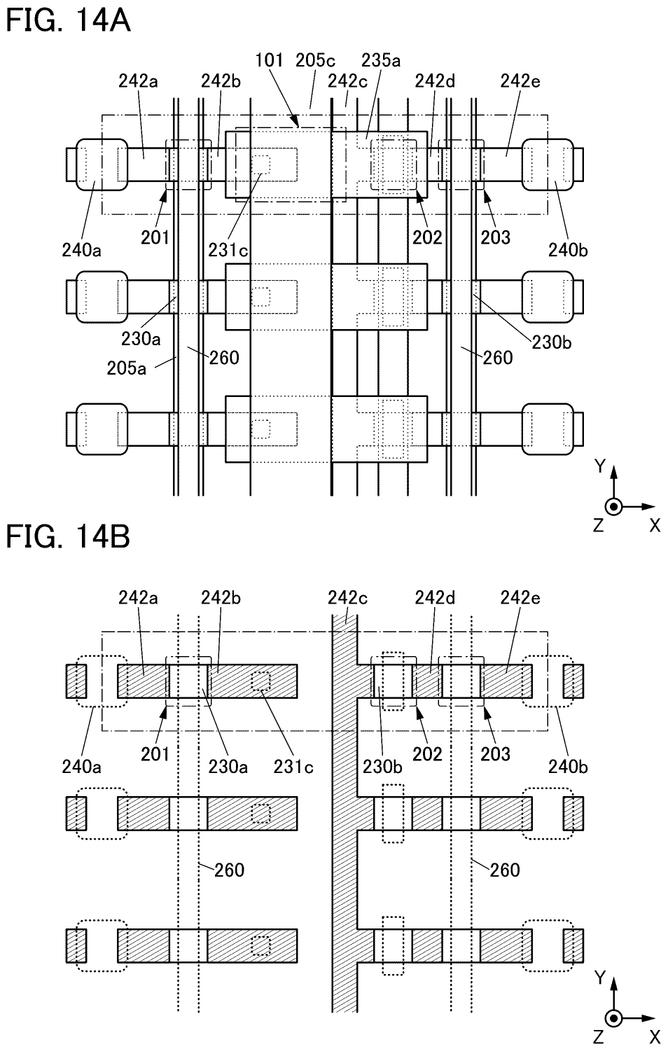

FIG. 14A and FIG. 14B are plan views illustrating examples of the semiconductor device having the structure illustrated in FIG. 2A, for example, and illustrate structure examples of the XY plane.

FIG. 14A illustrates some of the conductors and the metal oxide 230 included in the semiconductor device illustrated in FIG. 2A. FIG. 14B illustrates the conductor 242a to the conductor 242e, the metal oxide 230, the connection electrode 240a, the connection electrode 240b, the conductor 231c, and the conductor 260 in FIG. 14A. In FIG. 14A and FIG. 14B, a memory cell composed of the transistor 201, the transistor 202, the transistor 203, and the capacitor 101 is indicated by a dashed double-dotted line. That is, FIG. 14A and FIG. 14B are top views each illustrating an example in which three memory cells are arranged in the Y direction. Note that at least an insulator is omitted in FIG. 14A and FIG. 14B.

As illustrated in FIG. 14A and FIG. 14B, the metal oxide 230b of the transistor 202 and the transistor 203 included in a first memory cell and the metal oxide 230b of the transistor 202 and the transistor 203 included in a second memory cell adjacent to the first memory cell in the Y direction are not separated from each other. In other words, in a plurality of memory cells adjacent to each other in the Y direction, the metal oxide 230b included in the transistor 202 and the transistor 203 is provided as a continuous layer.

In the above manner, the plurality of memory cells are arranged in at least one of the X direction and the Y direction, whereby the memory cell array can be formed.

### <Example of Method for Manufacturing Semiconductor Device>

An example of a method for manufacturing the semiconductor device of one embodiment of the present invention will be described below. Here, the case of manufacturing the semiconductor device illustrated in FIG. 6 will be described as an example.

Hereinafter, an insulating material for forming an insulator, a conductive material for forming a conductor, or a semiconductor material for forming a semiconductor can be deposited by a sputtering method, a CVD method, an MBE method, a PLD method, an ALD method, or the like as appropriate.

Examples of the sputtering method include an RF sputtering method in which a high-frequency power source is used as a sputtering power source, a DC sputtering method in which a DC power source is used, and a pulsed DC sputtering method in which voltage applied to an electrode is changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, such plasma damage is not caused in the case of the thermal CVD method, which does not use plasma, and thus the yield of the semiconductor device can be increased. In addition, the thermal CVD method does not cause plasma damage during deposition, so that a film with few defects can be obtained.

As the ALD method, a thermal ALD method, in which a precursor and a reactant react with each other only by a thermal energy, a PEALD method, in which a reactant excited by plasma is used, and the like can be used.

The CVD method and the ALD method are different from the sputtering method in which particles ejected from a target or the like are deposited. Thus, the CVD method and the ALD method are deposition methods that enable good step coverage almost regardless of the shape of an object to be processed. In particular, the ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as the CVD method, in some cases.

By the CVD method, a film with a certain composition can be formed depending on the flow rate ratio of the source gases. For example, by the CVD method, a film whose composition is continuously changed can be formed by changing the flow rate ratio of the source gases during film formation. In the case where the film is formed while the flow rate ratio of the source gases is changed, as compared with the case where the film is formed using a plurality of deposition chambers, the time taken for the film formation can be shortened because the time taken for transfer or pressure adjustment is not required. Thus, the productivity of the semiconductor device can be increased in some cases.

By the ALD method, a film with a certain composition can be formed by concurrently introducing different kinds of precursors. In the case where different kinds of precursors are introduced, a film with a certain composition can be formed by controlling the number of cycles for each of the precursors.

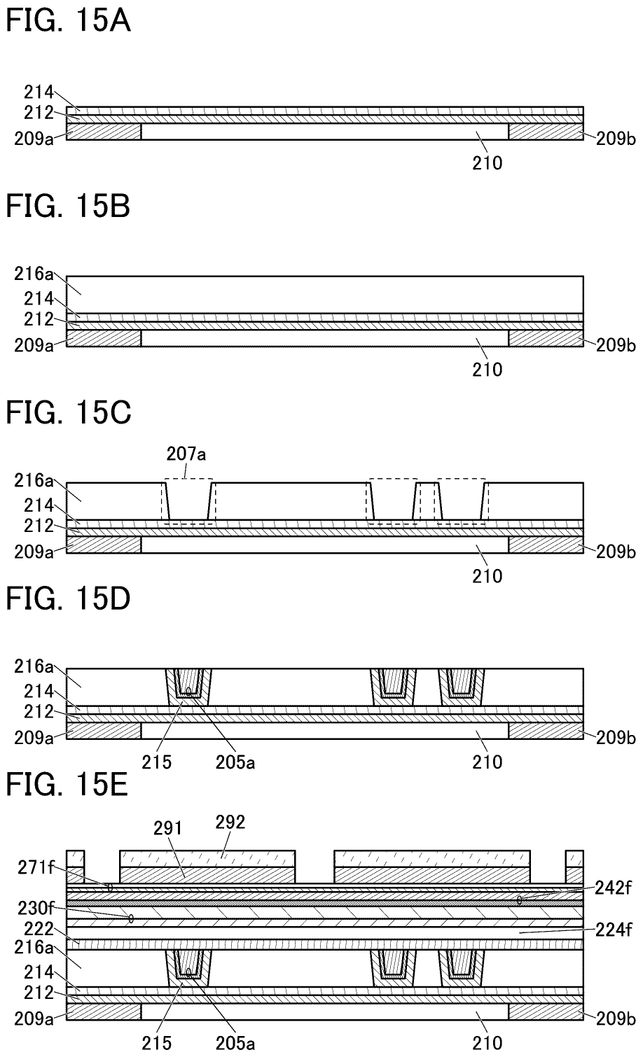

First, a substrate (not illustrated) is prepared, and the conductor 209a, the conductor 209b, and the insulator 210 are formed over the substrate. Next, the insulator 212 and the insulator 214 are formed in this order over the conductor 209a, the conductor 209b, and the insulator 210 (FIG. 15A). The insulator 212 and the insulator 214 are preferably deposited by a sputtering method. In this embodiment, for the insulator 212, silicon nitride is deposited by a pulsed DC sputtering method. As the insulator 214, aluminum oxide is deposited by a pulsed DC sputtering method.

The use of an insulator through which impurities such as water and hydrogen are unlikely to pass, such as silicon nitride or hafnium oxide, can inhibit diffusion of impurities such as water and hydrogen contained in a layer below the insulator 212. Even when a metal that is likely to diffuse, such as copper, is used for the conductor (the conductor 209a, the conductor 209b, or the like) in a layer below the insulator 212, the use of an insulator through which copper is unlikely to pass, such as silicon nitride, as the insulator 212 can inhibit upward diffusion of the metal through the insulator 212.

The use of an insulator such as aluminum oxide, which has high capability of capturing and fixing hydrogen, allows capturing or fixing hydrogen contained in the insulator 216 and the like and inhibits diffusion of hydrogen into the metal oxide 230. It is particularly preferable to use aluminum oxide having an amorphous structure or amorphous aluminum oxide for the insulator 214 because hydrogen can be captured or fixed more effectively in some cases. In that case, the transistor and the semiconductor device which have favorable characteristics and high reliability can be manufactured.

Then, the insulator 216a is formed over the insulator 214 (FIG. 15B). In this embodiment, as the insulator 216a, silicon oxide is deposited by a pulsed DC sputtering method. The use of the pulsed DC sputtering method can achieve more uniform film thickness and improve the sputtering rate, deposition rate, and film quality.

The insulator 212, the insulator 214, and the insulator 216a are preferably successively formed without exposure to the air. For example, a multi-chamber deposition apparatus can be used. As a result, the amounts of hydrogen in the formed insulator 212, insulator 214, and insulator 216a can be reduced, and furthermore, entry of hydrogen into the films in intervals between deposition steps can be inhibited.

Next, an opening 207a reaching the insulator 214 is formed in the insulator 216a (FIG. 15C). Wet etching may be used for forming the opening 207a; however, dry etching is preferably used for fine processing. Note that part of the insulator 214 is sometimes removed by the formation of the opening 207a. This leads to formation of a depressed portion in a region of the insulator 214 that overlaps with the opening 207a.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

Next, an insulating film to be the insulator 215 and a conductive film to be the conductor 205a are formed in this order.

An insulating film to be insulator 215 is preferably formed by a film formation method that offers good coverage. The insulating film is preferably formed using a high-k material, and further preferably has a stacked-layer structure including a high-k material and a material having higher dielectric strength than the high-k material. In this embodiment, as the insulating film, zirconium oxide, aluminum oxide, and zirconium oxide are deposited in this order by an ALD method. Alternatively, as the insulating film, zirconium oxide, aluminum oxide, zirconium oxide, and aluminum oxide may be deposited in this order by an ALD method.

A conductive film to be the conductor 205a preferably has a stacked-layer structure of a conductive film having a function of inhibiting passage of oxygen and a conductive film having lower electrical resistivity than the conductive film to be the conductor 205a. As the conductive film having a function of inhibiting passage of oxygen, one or more of tantalum nitride, tungsten nitride, and titanium nitride are preferably included, for example. Alternatively, the conductive film can have a stacked-layer structure of the conductive film having a function of inhibiting passage of oxygen and tantalum, tungsten, titanium, molybdenum, aluminum, copper, or a molybdenum-tungsten alloy. As the conductive film having low electrical resistivity, one or more of tantalum, tungsten, titanium, molybdenum, aluminum, copper, and a molybdenum-tungsten alloy are preferably included.

In this embodiment, a titanium nitride film is formed as the lower layer of the conductive film to be the conductor 205a and a tungsten is film is formed as the upper layer thereof. The use of a metal nitride as the lower layer of the conductor 205a can inhibit oxygen contained in the insulator 216a from oxidizing the conductor 205a, for example. Furthermore, even when a metal that is likely to diffuse is used as the upper layer of the conductor 205a, the metal can be inhibited from diffusing to the outside from the conductor 205a.

Next, CMP treatment is performed to remove part of the insulating film to be insulator 215 and part of the conductive film to be the conductor 205a, so that the insulator 216a is exposed. As a result, the insulator 215 and the conductor 205a are formed to fill the opening 207a (FIG. 15D). Note that the insulator 216a is partly removed by the CMP treatment in some cases. This enables the insulator 216a to be planarized.

The semiconductor device having the structure illustrated in FIG. 3B can be manufactured by forming the conductive film to be the conductor 205a and performing CMP treatment, without forming the insulating film to be the insulator 215.

Next, the insulator 222 is formed over the insulator 216a, the insulator 215, and the conductor 205a (FIG. 15E). In this embodiment, for the insulator 222, hafnium oxide is deposited by an ALD method.

Subsequently, heat treatment is preferably performed. The temperature of the heat treatment is preferably higher than or equal to 250° C. and lower than or equal to 650° C., further preferably higher than or equal to 300° C. and lower than or equal to 500° C., still further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is preferably 1 ppb or less, further preferably 0.1 ppb or less, still further preferably 0.05 ppb or less. The heat treatment using a highly purified gas can prevent entry of moisture into the insulator 222 as much as possible, for example.

In this embodiment, as the heat treatment, treatment is performed at 400° C. for one hour with a flow rate ratio of a nitrogen gas to an oxygen gas of 4:1 after the formation of the insulator 222. Through the heat treatment, impurities such as water and hydrogen contained in the insulator 222 can be removed, for example. In the case where an oxide containing hafnium is used for the insulator 222, the insulator 222 is partly crystallized by the heat treatment in some cases. The heat treatment can also be performed after formation of an insulating film 224f, for example.

Next, the insulating film 224f is formed over the insulator 222 (FIG. 15E). In this embodiment, as the insulating film 224f, a silicon oxide film is formed by a sputtering method. By using a sputtering method that does not need to use a molecule containing hydrogen for a deposition gas, the hydrogen concentration in the insulating film 224f can be reduced. The hydrogen concentration in the insulating film 224f is preferably reduced in this manner because the insulating film 224f is in contact with the metal oxide 230 in a later step.

Next, a metal oxide film 230f is formed over the insulating film 224f (FIG. 15E). In this embodiment, as the metal oxide film 230f, a first metal oxide film is formed in a lower layer and a second metal oxide film is formed in an upper layer. Note that it is preferable to form the first and second metal oxide films successively without exposure to the atmospheric environment. By the formation without exposure to the air, impurities or moisture from the atmospheric environment can be prevented from being attached onto the first and second metal oxide films, so that the vicinity of an interface between the first and second metal oxide films can be kept clean. In this embodiment, the first and second metal oxide films are formed by a sputtering method.

In the case where the first and second metal oxide films are formed by a sputtering method, oxygen or a mixed gas of oxygen and a noble gas is used as a sputtering gas. Increasing the proportion of oxygen contained in the sputtering gas can increase the amount of excess oxygen in the oxide films. In the case where the first and second metal oxide films are formed by a sputtering method, an In-M-Zn oxide target can be used, for example.

In particular, when the first metal oxide film is formed, part of oxygen contained in the sputtering gas is supplied to the insulating film 224f in some cases. Thus, the proportion of oxygen contained in the sputtering gas is preferably higher than or equal to 70%, further preferably higher than or equal to 80%, still further preferably 100%.

In the case where the second metal oxide film is formed by a sputtering method and the proportion of oxygen contained in the sputtering gas for film formation is higher than 30% and lower than or equal to 100%, preferably higher than or equal to 70% and lower than or equal to 100%, an oxygen-excess oxide semiconductor is formed. In a transistor using an oxygen-excess oxide semiconductor for its channel formation region, relatively high reliability can be obtained. Note that one embodiment of the present invention is not limited thereto. In the case where the second metal oxide film is formed by a sputtering method and the proportion of oxygen contained in the sputtering gas for film formation is higher than or equal to 1% and lower than or equal to 30%, preferably higher than or equal to 5% and lower than or equal to 20%, an oxygen-deficient oxide semiconductor is formed. In a transistor using an oxygen-deficient oxide semiconductor for its channel formation region, relatively high field-effect mobility can be obtained. Furthermore, when the film formation is performed while the substrate is being heated, the crystallinity of the oxide film can be improved.

In this embodiment, the first metal oxide film is formed by a sputtering method using an oxide target with In:Ga:Zn=1:3:4 [atomic ratio]. In addition, the second metal oxide film is formed by a sputtering method using an oxide target with In:Ga:Zn=1:1:1 [atomic ratio] or an oxide target with In:Ga:Zn=1:1:1.2 [atomic ratio]. Note that each of the oxide films is preferably formed to have characteristics required for the first and second metal oxides of the metal oxide 230 by selecting the film formation conditions and the atomic ratios as appropriate.

Note that the insulating film 224f and the first and second metal oxide films of the metal oxide film 230f are preferably formed by a sputtering method without exposure to the air. For example, a multi-chamber deposition apparatus is preferably used. As a result, entry of hydrogen into the insulating film 224f and the first and second metal oxide films of the metal oxide film 230f in intervals between film formation steps can be inhibited.

Next, heat treatment is preferably performed. The heat treatment is performed in a temperature range where the metal oxide film 230f does not become polycrystal. The temperature of the heat treatment is preferably higher than or equal to 250° C. and lower than or equal to 650° C., further preferably higher than or equal to 400° C. and lower than or equal to 600° C.

Note that an example of an atmosphere of the heat treatment is an atmosphere similar to the atmosphere applicable to the heat treatment performed after the formation of the insulator 222.

As in the heat treatment performed after the formation of the insulator 222, a gas used in the heat treatment is preferably highly purified. The heat treatment performed using a highly purified gas can prevent entry of moisture or the like into the metal oxide film 230f and the like as much as possible.

In this embodiment, the heat treatment is performed at 400° C. for one hour with a flow rate ratio of a nitrogen gas to an oxygen gas being 4:1. Through such heat treatment using the oxygen gas, impurities such as carbon, water, and hydrogen in the metal oxide film 230f can be reduced. The reduction of impurities in the films in this manner improves the crystallinity of the metal oxide film 230f, thereby offering a dense structure with a higher density. Thus, the crystalline region in the metal oxide film 230f can be expanded, and an in-plane variation of the crystallinity in the metal oxide film 230f can be reduced. Accordingly, an in-plane variation of electrical characteristics of transistors can be reduced. Thus, a semiconductor device with a small variation in electrical characteristics of transistors can be provided.

By performing the heat treatment, hydrogen in the insulator 216a, the insulating film 224f, and the metal oxide film 230f moves into the insulator 222 and is absorbed by the insulator 222. In other words, hydrogen in the insulator 216a, the insulating film 224f, and the metal oxide film 230f diffuses into the insulator 222. Accordingly, the hydrogen concentration in the insulator 222 increases, while the hydrogen concentrations in the insulator 216a, the insulating film 224f, and the metal oxide film 230f decrease.

Specifically, the insulator 224 formed by processing the insulating film 224f functions as the gate insulator of each of the transistor 201 to the transistor 203, and the metal oxide 230a and the metal oxide 230b formed by processing the metal oxide film 230f function as the channel formation region of each of the transistor 201 to the transistor 203. The transistor 201 to the transistor 203 formed using the insulating film 224f and the metal oxide film 230f with reduced hydrogen concentrations are preferable because of their high reliability.

Next, a conductive film 242f is formed over the metal oxide film 230f (FIG. 15E). For example, as the conductive film 242f, a tantalum nitride film is deposited by a sputtering method, and a tungsten film is deposited thereover by a sputtering method. Note that heat treatment may be performed before the formation of the conductive film 242f. The heat treatment may be performed under reduced pressure, and the conductive film 242f may be successively formed without exposure to the air. Such treatment can remove moisture and hydrogen adsorbed on the surface of the metal oxide film 230f and can reduce the moisture concentration and the hydrogen concentration in the metal oxide film 230f. The heat treatment temperature is preferably higher than or equal to 100° C. and lower than or equal to 400° C. In this embodiment, the heat treatment temperature is 200° C.

Next, an insulating film 271f is formed over the conductive film 242f (see FIG. 15E). For example, as the insulating film 271f, a silicon nitride film is formed by a sputtering method, and a silicon oxide film is formed thereover by a sputtering method.

Note that the conductive film 242f and the insulating film 271f are preferably formed by a sputtering method without exposure to the air. For example, a multi-chamber deposition apparatus is preferably used. In that case, the amount of hydrogen in each of the conductive film 242f and the insulating film 271f can be reduced in deposition, so that the amount of hydrogen mixing into the films in intervals between deposition steps can be further reduced.

Next, a film to be a hard mask 291 is formed over the insulating film 271f, a resist mask 292 is formed over the film, and the film is etched, so that the hard mask 291 with a desired shape is formed (FIG. 15E).

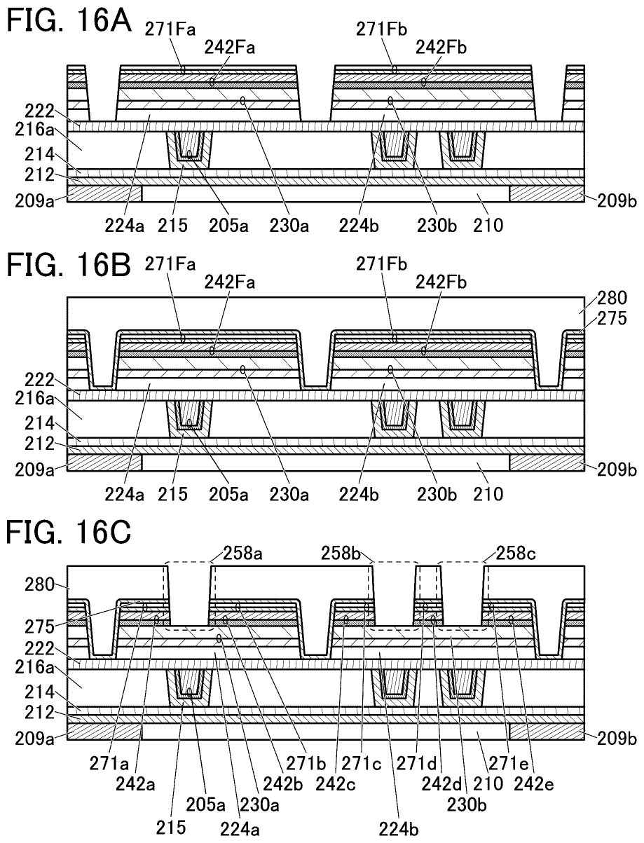

Next, the insulating film 224f, the metal oxide film 230f, the conductive film 242f, and the insulating film 271f are processed into island shapes by, for example, a lithography method and an etching method, so that the insulator 224 (the insulator 224a and the insulator 224b), the metal oxide 230 (the metal oxide 230a and the metal oxide 230b), the conductive layer 242F (the conductive layer 242Fa and the conductive layer 242Fb), and the insulating layer 271F (the insulating layer 271Fa and the insulating layer 271Fb) are formed (FIG. 16A). Here, the insulator 224a, the metal oxide 230a, the conductive layer 242Fa, and the insulating layer 271Fa are formed to at least partly overlap with the conductor 205a. Similarly, the insulator 224b, the metal oxide 230b, the conductive layer 242Fb, and the insulating layer 271Fb are formed to at least partly overlap with the conductor 205a. As described above, the metal oxide 230b is layer shared by the transistor 202 and the transistor 203.

In the lithography method, first, a resist is exposed to light through a mask. Next, a region exposed to light is removed or left using a developing solution, so that a resist mask is formed. The resist mask can be formed through, for example, exposure of the resist to KrF excimer laser light, ArF excimer laser light, EUV (Extreme Ultraviolet) light, or the like. Alternatively, a liquid immersion technique may be employed in which a gap between a substrate and a projection lens is filled with a liquid (e.g., water) in light exposure. Note that the resist mask can be removed by dry etching treatment such as ashing, wet etching treatment, wet etching treatment after dry etching treatment, or dry etching treatment after wet etching treatment. After the resist mask is formed by a lithography method, etching treatment through the resist mask is conducted, whereby a conductive film, a semiconductor film, an insulating film, or the like can be processed into a desired shape. In this manner, a conductor, a semiconductor, an insulator, or the like can be formed by a lithography method and an etching method. Note that an electron beam or an ion beam may be used instead of the light. A mask is unnecessary in the case of using an electron beam or an ion beam.

A dry etching method or a wet etching method can be employed for the processing. A dry etching method is suitable for fine processing. The insulating film 224f, the metal oxide film 230f, the conductive film 242f, and the insulating film 271f may be processed under different conditions.

For example, the etching of the metal oxide film 230f may be performed after removal of the resist mask 292 or with the resist mask 292 remaining. In the latter case, the resist mask 292 sometimes disappears during the etching. The hard mask 291 may be removed by etching after the etching of the metal oxide film 230f, for example.

After the processing, the resist mask 292 and the hard mask 291 are removed if the resist mask 292 and the hard mask 291 are left (FIG. 16A).

Since the insulating layer 271Fa and the insulating layer 271Fb function as masks for the conductive layer 242Fa and the conductive layer 242Fb, respectively, there is no curved surface between the side surface and top surface of each of the conductive layer 242Fa and the conductive layer 242Fb, as illustrated in FIG. 16A. Thus, end portions at the intersection of the side surface and the top surface of the conductor 242 illustrated in FIG. 6 is angular. The cross-sectional area of the conductor 242 in the case where the end portion at the intersection of the side surface and the top surface of the conductor 242 is angular is larger than that in the case where the end portion is rounded. Accordingly, the resistance of the conductor 242 is reduced, so that the on-state current of the transistor can be increased.

As illustrated in FIG. 16A, the side surfaces of the insulator 224, the metal oxide 230, the conductive layer 242F, and the insulating layer 271F may have tapered shapes. The taper angles of the side surfaces of the insulator 224, the metal oxide 230, the conductive layer 242F, and the insulating layer 271F may be greater than or equal to 60° and less than 90°, for example. Such tapered side surfaces can improve the coverage with the insulator 275 in a later step, for example; as a result, the number of defects such as voids can be reduced.

Not being limited to the above, the insulator 224, the metal oxide 230, the conductive layer 242F, and the insulating layer 271F may have side surfaces that are substantially perpendicular to the top surface of the insulator 222. With such a structure, a plurality of transistors can be provided at high density in a small area.

Next, the insulator 275 is formed over the insulating layer 271F, and the insulator 280 is formed over the insulator 275 (FIG. 16B). As the insulator 280, an insulator having a flat top surface is preferably formed in the following manner: an insulating film to be the insulator 280 is formed and then the insulating film is subjected to CMP treatment. Note that, for example, silicon nitride may be deposited over the insulator 280 by a sputtering method and CMP treatment may be performed on the silicon nitride film until the insulator 280 is reached.

As the insulator 275, an insulator having a function of inhibiting passage of oxygen is preferably used. For example, silicon nitride is preferably deposited for the insulator 275 by an ALD method, specifically a PEALD method. Alternatively, for the insulator 275, it is preferable that aluminum oxide be deposited by a sputtering method and silicon nitride be deposited thereover by a PEALD method. When the insulator 275 has such a stacked-layer structure, the function of inhibiting diffusion of oxygen and impurities such as water and hydrogen can be improved.

In this manner, the insulator 224, the metal oxide 230, and the conductive layer 242F can be covered with the insulator 275, which has a function of inhibiting diffusion of oxygen. This can inhibit direct diffusion of oxygen from the insulator 280 or the like into the insulator 224, the metal oxide 230, and the conductive layer 242F in a later step.

The insulator 280 is preferably silicon oxide deposited by a sputtering method, for example. When the insulator 280 is formed by a sputtering method in an oxygen-containing atmosphere, the insulator 280 containing excess oxygen can be formed. By using a sputtering method that does not need to use a molecule containing hydrogen as a deposition gas, the hydrogen concentration in the insulator 280 can be reduced. For example, the hydrocarbon concentration in the insulator 280 is preferably lower than or equal to 1×10²⁰ atoms/cm³, further preferably lower than or equal to 1×10¹⁹ atoms/cm³, still further preferably lower than or equal to 1×10¹⁸ atoms/cm³. Note that heat treatment may be performed before the formation of the insulating film. The heat treatment may be performed under reduced pressure, and the insulating film may be successively formed without exposure to the air. Such treatment can remove moisture and hydrogen adsorbed onto the surface of the insulator 275 and the like, and further can reduce the moisture concentration and the hydrogen concentration in each of the metal oxide 230 and the insulator 224. For the heat treatment, the above heat treatment conditions can be used.

Then, the conductive layer 242F, the insulating layer 271F, the insulator 275, and the insulator 280 are processed by a lithography method and an etching method to form the opening 258a that reaches the metal oxide 230a and the opening 258b and the opening 258c that reach the metal oxide 230b. The conductor 242a, the conductor 242b, the insulator 271a, and the insulator 271b are formed by the formation of the opening 258a. The conductor 242c, the conductor 242d, the conductor 242e, the insulator 271c, the insulator 271d, and the insulator 271e are formed by the formation of the opening 258b and the opening 258c (FIG. 16C). The opening 258a, the opening 258b, and the opening 258c each include a region overlapping with the conductor 205a. Note that the processing of the conductive layer 242F, the processing of the insulating layer 271F, the processing of the insulator 275, and the processing of the insulator 280 may be performed under different conditions. Alternatively, the processing of the insulator 275 and the processing of the insulator 280 may be performed under the same conditions, which may be different from the conditions for the processing of the conductive layer 242F. The processing of these forms a groove portion in a region of the metal oxide 230a that overlaps with the opening 258a in some cases. Similarly, a groove portion is formed in each of a region of the metal oxide 230b that overlaps with the opening 258b and a region of the metal oxide 230b that overlaps with the opening 258c in some cases.

Through the etching treatment, impurities might be attached to the top surface and side surface of the metal oxide 230, the side surface of the conductor 242, the side surface of the insulator 271, the side surface of the insulator 275, the side surface of the insulator 280, and the like or the impurities might diffuse into these components. A step of removing the impurities may be performed. Particularly in the case where the opening 258a, the opening 258b, and the opening 258c are formed by a dry etching method, a damaged region is sometimes formed on the surface of the metal oxide 230. Such a damaged region may be removed. The impurities result from components contained in the insulator 280, the insulator 275, the insulator 271, and the conductor 242, components contained in a member of an apparatus used to form the opening 258a to the opening 258c, and components contained in a gas or a liquid used for etching, for example. Examples of the impurities include hafnium, aluminum, silicon, tantalum, fluorine, and chlorine.

In particular, silicon might reduce the crystallinity of the metal oxide 230. Thus, silicon is preferably removed from the surface of the metal oxide 230 and the vicinity thereof. In addition, the concentration of silicon is preferably reduced. For example, the concentration of silicon at the surface of the metal oxide 230 and the vicinity thereof is preferably lower than or equal to 5.0 atomic %, further preferably lower than or equal to 2.0 atomic %, still further preferably lower than or equal to 1.5 atomic %, yet further preferably lower than or equal to 1.0 atomic %, yet still further preferably lower than 0.3 atomic %.

Note that since the density of a crystal structure is reduced in a low-crystallinity region of the metal oxide 230 because of silicon, a large amount of VoH is formed; thus, the transistor is likely to be normally on. Hence, the low-crystallinity region of the metal oxide 230 is preferably reduced or removed.

By contrast, the metal oxide 230 preferably has a layered CAAC structure. In particular, the CAAC structure preferably reaches a lower edge portion of a drain in the metal oxide 230. Here, in the transistor 201 to the transistor 203, at least part of the conductor 242a to the conductor 242e and their vicinities function as drains. Thus, the metal oxides 230 in the vicinities of the lower edge portions of the conductor 242a to the conductor 242e preferably have a CAAC structure. In this manner, the low-crystallinity region of the metal oxide 230 is removed and the CAAC structure is formed also in the drain edge portion, which significantly affects the drain breakdown voltage, so that variations in the electrical characteristics of the transistor 201 to the transistor 203 can be further inhibited. In addition, the reliability of the transistor 201 to the transistor 203 can be improved.

In order to remove impurities attached to the surface of the metal oxide 230 in the above etching step, for example, cleaning treatment is performed. Examples of the cleaning method include wet cleaning using a cleaning solution (which can also be referred to as wet etching treatment), plasma treatment using plasma, and cleaning by heat treatment, and any of these cleanings may be performed in appropriate combination. Note that the cleaning treatment sometimes makes the groove portion deeper.

The wet cleaning may be performed using an aqueous solution in which one or more of ammonia water, oxalic acid, phosphoric acid, and hydrofluoric acid is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. For example, damage to the metal oxide 230b can be reduced with this frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

The cleaning treatment can remove impurities that are attached onto the surfaces of the metal oxide 230 and the like or diffused into the metal oxide 230 and the like. Furthermore, the crystallinity of the metal oxide 230 can be increased.

After the etching or the cleaning, heat treatment may be performed. The temperature of the heat treatment is preferably higher than or equal to 100° C. and lower than or equal to 450° C., further preferably higher than or equal to 350° C. and lower than or equal to 400° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. This can supply oxygen to the metal oxide 230 to reduce oxygen vacancies. In addition, the crystallinity of the metal oxide 230 can be improved by such heat treatment. The heat treatment may be performed under reduced pressure. Alternatively, heat treatment may be performed in an oxygen atmosphere, and then heat treatment may be successively performed in a nitrogen atmosphere without exposure to the air.

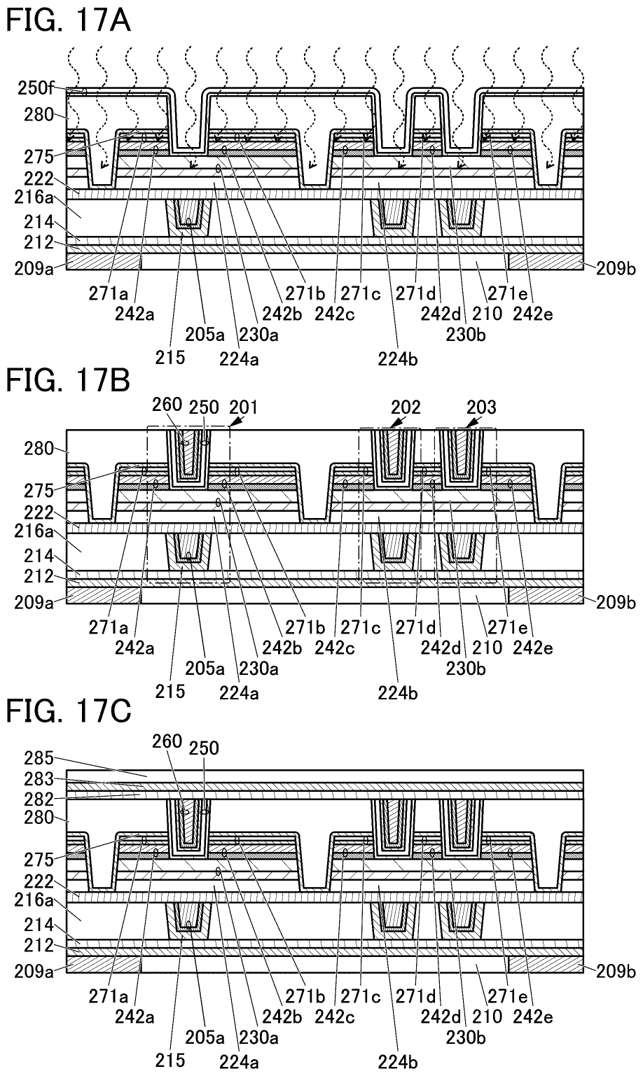

Next, the insulating film 250f is formed. The insulating film 250f is preferably formed by an ALD method. It is preferable that the thickness of the insulator 250 be small and hardly vary. An ALD method is a film formation method in which a precursor and a reactant (e.g., an oxidizer) are alternately introduced, and the thickness can be adjusted with the number of repetition times of the cycle; thus, accurate control of the thickness is possible. As illustrated in FIG. 17A, the insulating film 250f is preferably formed with good coverage on the bottom surfaces and the side surfaces of the opening 258a to the opening 258c. With the use of an ALD method, an atomic layer can be deposited one by one on the bottom surfaces and the side surfaces of the opening 258a to the opening 258c. Thus, the insulator 250 can be formed with good coverage in the opening 258a to the opening 258c.

When the insulating film 250f is formed by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffusing into the metal oxide 230b can be reduced.

The insulating film 250f may be an insulating film to be the insulator 250a or may have a stacked-layer structure of the insulating film to be the insulator 250a and an insulating film to be the insulator 250b. In this embodiment, as the insulating film 250f, an aluminum oxide film is deposited by a thermal ALD method, and a silicon oxide film is deposited thereover by a PEALD method. Note that the aluminum oxide film is the insulating film to be the insulator 250a, and the silicon oxide film is the insulating film to be the insulator 250b.

Next, it is preferable to perform microwave treatment in an atmosphere containing oxygen. Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHz.

The microwave treatment is preferably performed with a microwave treatment apparatus including a power source for generating high-density plasma using microwaves, for example. Here, the frequency of the microwave treatment apparatus is preferably set to greater than or equal to 300 MHz and less than or equal to 300 GHz, further preferably greater than or equal to 2.4 GHz and less than or equal to 2.5 GHZ, and can be set to 2.45 GHz, for example. Oxygen radicals at a high density can be generated with high-density plasma. The electric power of the power source that applies microwaves of the microwave treatment apparatus is preferably set to higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the metal oxide 230 efficiently.

The microwave treatment is preferably performed under reduced pressure, and the pressure is preferably set to higher than or equal to 10 Pa and lower than or equal to 1000 Pa, further preferably higher than or equal to 300 Pa and lower than or equal to 700 Pa. The treatment temperature is preferably set to lower than or equal to 750° C., further preferably lower than or equal to 500° C., and can be approximately 250° C., for example. The oxygen plasma treatment may be followed successively by heat treatment without exposure to air. The temperature of the heat treatment is preferably higher than or equal to 100° C. and lower than or equal to 750° C., further preferably higher than or equal to 300° C. and lower than or equal to 500° C., for example.

Furthermore, the microwave treatment can be performed using an oxygen gas and an argon gas, for example. Here, the oxygen flow rate ratio (O₂/(O₂+Ar)) is higher than 0% and lower than or equal to 100%, preferably higher than 0% and lower than or equal to 50%, further preferably higher than or equal to 10% and lower than or equal to 40%, or still further preferably higher than or equal to 10% and lower than or equal to 30%. The carrier concentration in the metal oxide 230 can be reduced by thus performing the microwave treatment in an atmosphere containing oxygen. In addition, preventing introduction of an excess amount of oxygen into the chamber in the microwave treatment can prevent an excessive reduction in the carrier concentration in the metal oxide 230.

As illustrated in FIG. 17A, the microwave treatment in an atmosphere containing oxygen can convert an oxygen gas into plasma using a high-frequency wave such as a microwave or RF, and apply the oxygen plasma to a region of the metal oxide 230 which is between the conductor 242a and the conductor 242b, a region of the metal oxide 230 which is between the conductor 242c and the conductor 242d, and a region of the metal oxide 230 which is between the conductor 242d and the conductor 242e. By the effect of the plasma, the microwave, or the like, VoH in the region can be divided and hydrogen can be removed from the region. That is, VoH contained in the channel formation region can be reduced. Accordingly, oxygen vacancies and VoH in the channel formation region can be reduced to lower the carrier concentration. In addition, oxygen radicals generated by the oxygen plasma can be supplied to oxygen vacancies in the channel formation region, thereby further reducing oxygen vacancies in the channel formation region and lowering the carrier concentration.

Meanwhile, the metal oxide 230 includes a region overlapping with any of the conductor 242a to the conductor 242e. The region can function as a source region or a drain region. Here, the conductor 242a to the conductor 242e preferably function as blocking films preventing the effect caused by the high-frequency wave such as a microwave or RF, the oxygen plasma, or the like in the microwave treatment in an atmosphere containing oxygen. Therefore, the conductor 242a to the conductor 242e preferably have a function of blocking an electromagnetic wave greater than or equal to 300 MHz and less than or equal to 300 GHz, for example, greater than or equal to 2.4 GHz and less than or equal to 2.5 GHz.

The conductor 242a to the conductor 242e block the effects of the high-frequency wave such as a microwave or RF, the oxygen plasma, and the like. Thus, the effects do not reach the region of the metal oxide 230 that overlaps with any of the conductor 242a to the conductor 242e. Hence, a reduction in VoH and supply of an excess amount of oxygen due to the microwave treatment do not occur in the source region and the drain region, preventing a decrease in carrier concentration.

Furthermore, the insulating film to be the insulator 250a having a barrier property against oxygen is provided in contact with the side surfaces of the conductor 242a to the conductor 242e. This can inhibit formation of oxide films on the side surfaces of the conductor 242a to the conductor 242e by the microwave treatment.

Furthermore, the film quality of the insulating film 250f can be improved, leading to higher reliability of the transistor.

In the above manner, oxygen vacancies and VoH can be selectively removed from the channel formation region in the metal oxide, whereby the channel formation region can be an i-type or substantially i-type region. Furthermore, supply of an excess amount of oxygen to the regions functioning as the source region and the drain region can be inhibited, and the conductivity can be maintained. As a result, a change in the electrical characteristics of the transistor can be inhibited, and thus a variation in the electrical characteristics of transistors in the substrate plane can be inhibited.

In the microwave treatment, thermal energy is directly transmitted to the metal oxide 230 in some cases owing to an electromagnetic interaction between the microwave and a molecule in the metal oxide 230. The metal oxide 230 may be heated by this thermal energy. Such heat treatment is sometimes referred to as microwave annealing. When microwave treatment is performed in an atmosphere containing oxygen, an effect equivalent to that of oxygen annealing is sometimes obtained. In the case where hydrogen is contained in the metal oxide 230, it is probable that the thermal energy is transmitted to the hydrogen in the metal oxide 230 and the hydrogen activated by the energy is released from the metal oxide 230.

Note that the microwave treatment may be performed not after the formation of the insulating film 250f but before the formation of the insulating film 250f.

After the microwave treatment after the formation of the insulating film 250f, heat treatment may be performed with the reduced pressure being maintained. Such treatment enables hydrogen in the insulating film 250f and the metal oxide 230 to be removed efficiently. Part of hydrogen is gettered by the conductor 242 (the conductor 242a to the conductor 242e) in some cases. Alternatively, the step of performing microwave treatment and then performing heat treatment with the reduced pressure being maintained may be repeated a plurality of cycles. The repetition of the heat treatment enables hydrogen in the insulating film 250f and the metal oxide 230 to be removed more efficiently. Note that the temperature of the heat treatment is preferably higher than or equal to 300° C. and lower than or equal to 500° C. The microwave treatment, i.e., the microwave annealing, may also serve as the heat treatment. The heat treatment is not necessarily performed in the case where the metal oxide 230 is adequately heated by the microwave annealing, for example.

Furthermore, the microwave treatment improves the film quality of the insulating film 250f, thereby inhibiting diffusion of hydrogen, water, impurities, or the like. Accordingly, hydrogen, water, impurities, and the like can be inhibited from diffusing into the metal oxide 230 and the like through the insulator 250 in a later step such as formation of a conductive film to be the conductor 260 or later treatment such as heat treatment.

Next, an insulating film to be the insulator 250c is formed over the insulating film 250f. The insulating film is preferably formed by an ALD method, like the insulating film 250f. By an ALD method, the insulating film can be formed to have a small thickness and good coverage. In this embodiment, as the insulating film, a silicon nitride film is formed by a PEALD method.

In the case where the insulating film 250f is the insulating film to be the insulator 250a, the insulating film to be the insulator 250b is preferably formed before the insulating film to be the insulator 250c is formed.

In the case where the insulator 250 has a four-layer stacked structure of the insulator 250a to the insulator 250d, an insulating film to be the insulator 250d is formed before the insulating film to be the insulator 250c is formed. The insulating film is preferably deposited by an ALD method, like the insulating film 250f. By an ALD method, the insulating film can be deposited to have a small thickness and good coverage. In this embodiment, as the insulating film, a hafnium oxide film is deposited by a thermal ALD method.

As described above, an insulating film to be the insulator 250 composed of the insulating film to be the insulator 250a, the insulating film to be the insulator 250b, and the insulating film to be the insulator 250c is formed. Alternatively, an insulating film to be the insulator 250 composed of the insulating film to be the insulator 250a, the insulating film to be the insulator 250b, the insulating film to be the insulator 250d, and the insulating film to be the insulator 250c is formed.

Next, the conductive film to be the conductor 260 is formed over the insulating film to be the insulator 250. The conductive film may be a single layer or have a stacked-layer structure of two or more layers. In this embodiment, the conductive film has a stacked-layer structure of titanium nitride deposited by a CVD method and tungsten deposited by a CVD method.

Then, the insulating film to be the insulator 250 and the conductive film to be the conductor 260 are polished by CMP treatment until the insulator 280 is exposed. That is, portions of the insulating film to be the insulator 250 and the conductive film to be the conductor 260 that are exposed from the opening 258a to the opening 258c are removed. Accordingly, the insulator 250 and the conductor 260 are formed in each of the opening 258a to the opening 258c (FIG. 17B).

Thus, the insulator 250 is provided in contact with the bottom surfaces and the side surfaces of the opening 258a to the opening 258c. The conductor 260 is formed to be embedded in the opening 258a to the opening 258c with the insulator 250 therebetween. Consequently, the transistor 201 to the transistor 203 are formed. In this manner, the transistor 201 to the transistor 203 can be formed in parallel through the same process.

Then, heat treatment may be performed under conditions similar to those for the above heat treatment. In this embodiment, treatment is performed at 400° C. for one hour in a nitrogen atmosphere. The heat treatment can reduce the moisture concentration and the hydrogen concentration in the insulator 280. After the heat treatment, the insulator 282 may be successively formed without exposure to the air.

Next, the insulator 282 is formed over the insulator 250, the conductor 260, and the insulator 280 (FIG. 17C). The insulator 282 is preferably deposited by a sputtering method. Since a molecule containing hydrogen is not needed to be used for a deposition gas in the sputtering method, the hydrogen concentration in the insulator 282 can be reduced.

In this embodiment, as the insulator 282, aluminum oxide is deposited by a pulsed DC sputtering method using an aluminum target in an atmosphere containing an oxygen gas. The use of the pulsed DC sputtering method can achieve more uniform film thickness and improve the sputtering rate, deposition rate, and film quality. Note that the insulator 282 may have a stacked-layer structure of two layers.

When the insulator 282 is deposited by a sputtering method in an atmosphere containing oxygen, oxygen can be added to the insulator 280 during the deposition. Thus, excess oxygen can be contained in the insulator 280. At this time, the insulator 282 is preferably deposited while the substrate is being heated.

Then, the insulator 283 is formed over the insulator 282 (FIG. 17C). The insulator 283 is preferably deposited by a sputtering method. Since a molecule containing hydrogen is not needed to be used for a deposition gas in the sputtering method, the hydrogen concentration in the insulator 283 can be reduced. The insulator 283 may be a multilayer. For example, silicon nitride may be deposited by a sputtering method and silicon nitride may be deposited thereover by an ALD method. Providing the insulator 283 and the insulator 214 that have a high barrier property can prevent entry of moisture and hydrogen from the outside.

Then, the insulator 285 is formed over the insulator 283 (FIG. 17C). In this embodiment, as the insulator 285, silicon oxide is deposited by a pulsed DC sputtering method using a silicon target in an atmosphere containing an oxygen gas.

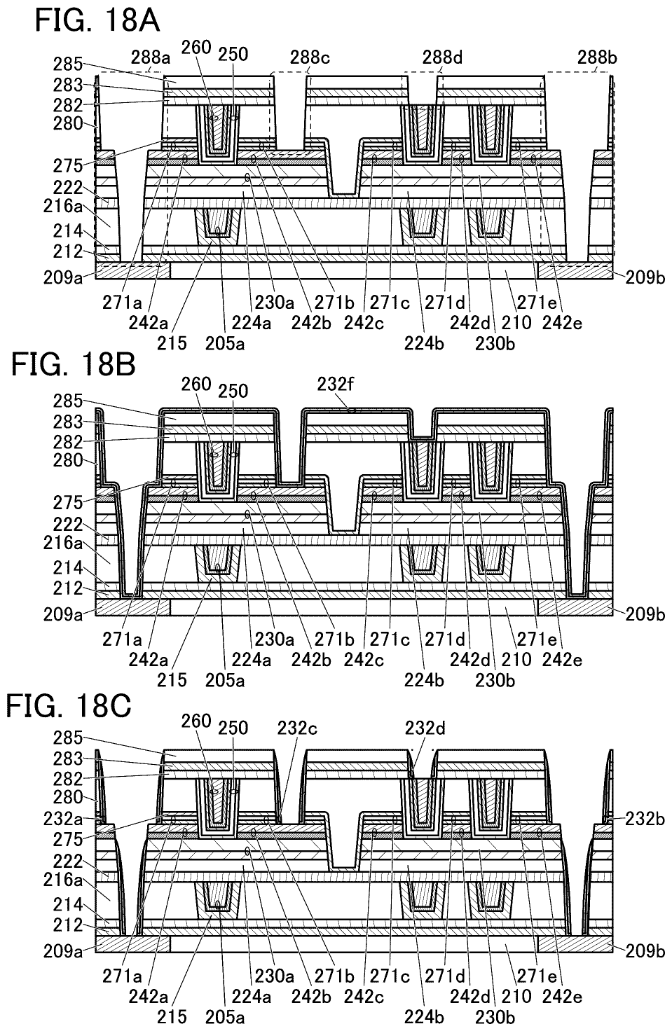

Next, an opening 288c reaching the conductor 242b is formed in the insulator 285, the insulator 283, the insulator 282, the insulator 280, the insulator 275, and the insulator 271b. In addition, an opening 288d reaching the conductor 260 included in the transistor 202 is formed in the insulator 285, the insulator 283, and the insulator 282. An opening 288a reaching the conductor 209a is formed in the insulator 285, the insulator 283, the insulator 282, the insulator 280, the insulator 275, the insulator 271a, the insulator 222, the insulator 216a, the insulator 214, and the insulator 212. An opening 288b reaching the conductor 209b is formed in the insulator 285, the insulator 283, the insulator 282, the insulator 280, the insulator 275, the insulator 271e, the insulator 222, the insulator 216a, the insulator 214, and the insulator 212 (FIG. 18A). Wet etching may be used for forming the openings; however, dry etching is preferably used for fine processing.

Each of the opening 288a and the opening 288b preferably includes a first region having a first width and a second region having a second width larger than the first width. The first region is a region between the conductors 242a in the opening 288a and is a region between the conductors 242e in the opening 288b. The first width corresponds to the width W1 illustrated in FIG. 9B. The second region is a region of each of the opening 288a and the opening 288b that overlaps with the insulator 285, the insulator 283, the insulator 282, the insulator 280, the insulator 275, and the insulator 271. With this structure, the top surfaces and side surfaces of the conductor 242a and the conductor 242e can be partly exposed by anisotropic etching described later.

Next, an insulating film 232f is formed (see FIG. 18B). As the insulating film 232f, an insulating film having a function of inhibiting diffusion of at least one of oxygen and hydrogen is preferably used. For example, a silicon nitride film is preferably deposited by a PEALD method. Silicon nitride is preferably used because silicon nitride has a high barrier property against oxygen and hydrogen. Note that the insulating film 232f may have a stacked-layer structure. For the insulating film 232f, an aluminum oxide film may be deposited by an ALD method and a silicon nitride film may be deposited thereover by a PEALD method, for example. In the case where an ALD method is used to form the insulating film 232f, the aluminum oxide film can be deposited at a lower temperature than a silicon nitride film. Thus, deposition of the aluminum oxide film before deposition of the silicon nitride film can inhibit oxidation of the conductor 260, the conductor 242, and the like.

Next, the insulating film 232f is subjected to anisotropic etching, whereby an insulator 232c is formed in contact with the sidewall of the opening 288c, an insulator 232d is formed in contact with the sidewall of the opening 288d, the insulator 232a is formed in contact with the sidewall of the opening 288a, and the insulator 232b is formed in contact with the sidewall of the opening 288b (FIG. 18C). For the anisotropic etching of the insulating film 232f, a dry etching method or the like is employed, for example. When the insulator 232a is provided on the sidewall portion of the opening 288a, passage of oxygen from the outside can be inhibited and oxidation of the conductor 231a to be formed next can be prevented. Furthermore, impurities such as water and hydrogen contained in the insulator 280 and the like can be prevented from diffusing into the conductor 231a. The same applies to the insulator 232b to the insulator 232d.

Next, a conductive film to be the conductor 231a to the conductor 231d is formed. The conductive film preferably has a stacked-layer structure of a conductive film having a function of inhibiting passage of oxygen and a conductive film having lower electrical resistivity than the conductive film. A material similar to any of the materials that can be used for the conductor 205a can be used for the conductive film, for example.

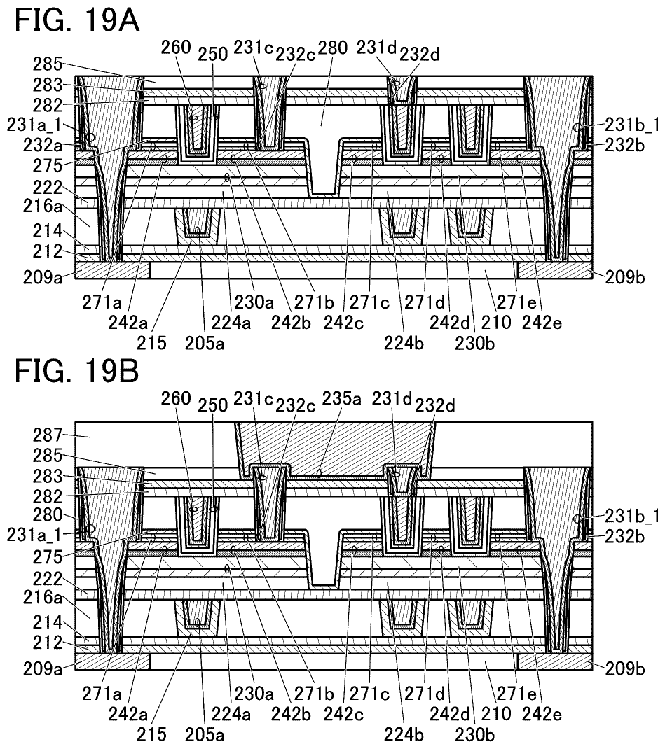

Next, CMP treatment is performed to remove part of the conductive film to be the conductor 231a to the conductor 231d, so that the insulator 285 is exposed. As a result, the conductor 231c is formed to fill the opening 288c. The conductor 231d is formed to fill the opening 288d. The conductor 231a_1 is formed to fill the opening 288a. The conductor 231b_1 is formed to fill the opening 288b (FIG. 19A). Note that the insulator 285 is partly removed by the CMP treatment in some cases. This enables the insulator 285 to be planarized. Accordingly, the top surface of the conductor 231a_1, the top surface of the conductor 231b_1, the top surface of the conductor 231c, and the top surface of the conductor 231d are level with each other.

Next, the insulator 287 is formed over the insulator 285, the conductor 231a_1, and the conductor 231b_1. The insulator 287 can be formed by a method similar to that for forming the insulator 216a or the insulator 280. For the insulator 287, a material similar to any of the materials that can be used for the insulator 216a or the insulator 280 can be used.

Then, the insulator 287 and the insulator 285 are processed by a lithography method and an etching method, so that an opening reaching the conductor 231c and the conductor 231d is formed. The opening is preferably formed to be larger than the top surfaces of the conductor 231c and the conductor 231d.

Next, a conductive film to be the conductor 235a is formed to fill the opening. The conductive film can be formed by a method similar to that can be used to form the conductive film to be the conductor 205a. For the conductive film, a material similar to any of the materials that can be used for the conductive film to be the conductor 205a can be used.

Next, CMP treatment is performed to remove part of the conductive film to be the conductor 235a, so that the insulator 287 is exposed. As a result, the conductor 235a is formed to fill the opening (FIG. 19B). Note that the insulator 287 is partly removed by the CMP treatment in some cases. This enables the insulator 287 to be planarized.

The conductor 235a is formed to be electrically connected to the conductor 231c and the conductor 231d; for example, the conductor 235a is formed to include regions in contact with the conductor 231c and the conductor 231d. In this manner, the conductor 235a is electrically connected to the conductor 242b through the conductor 231c and is electrically connected to the conductor 260 of the transistor 202 through the conductor 231d.

When the etching selectivity of the insulator 287 to the insulator 285 is high, the insulator 285 can function as an etching stop film during the formation of the opening in the insulator 287. In that case, the opening, the opening reaching the conductor 231a_1, and the opening reaching the conductor 231b_1 are formed, the conductive film to be the conductor 235a to the conductor 235c is formed, and CMP treatment is performed, whereby the semiconductor device having the structure illustrated in FIG. 4 can be manufactured.

Next, the insulator 216b is formed over the conductor 235a and the insulator 287. The insulator 216b can be formed by a method similar to that for forming the insulator 216a. For the insulator 216b, a material similar to any of the materials that can be used for the insulator 216a can be used.

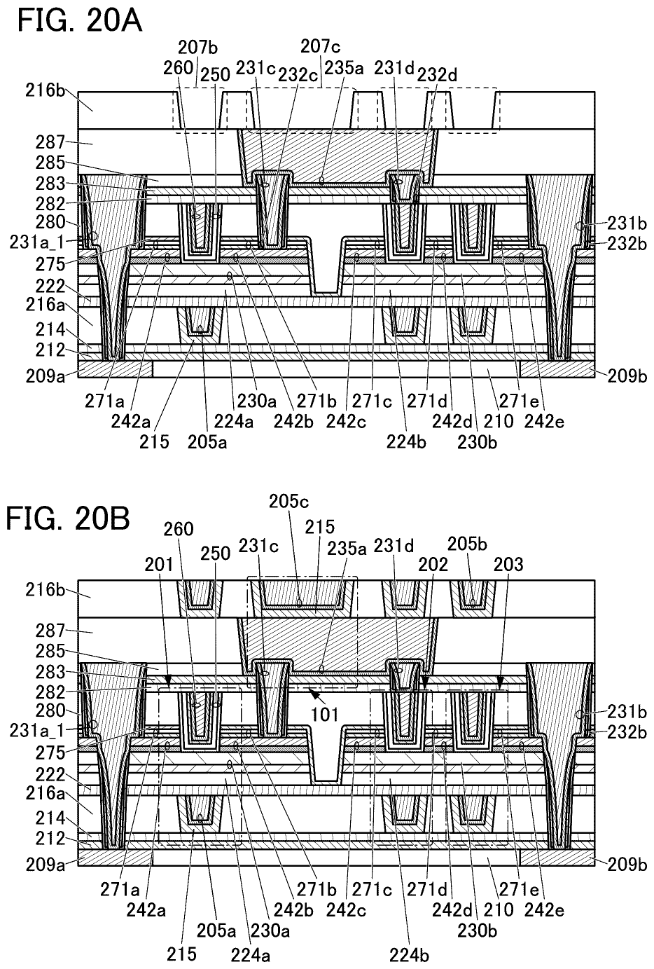

Next, an opening 207b and an opening 207c which reach the insulator 287 are formed in the insulator 216b (FIG. 20A). The opening 207c includes a region overlapping with the conductor 235a. The opening 207b includes a region overlapping with the metal oxide 230 and the conductor 260 that are provided above the opening 207b. Wet etching may be used for forming the opening 207b and the opening 207c; however, dry etching is preferably used for fine processing. Note that part of the insulator 287 is sometimes removed by the formation of the opening 207b and the opening 207c. This sometimes leads to formation of a depressed portion in each of a region of the insulator 287 that overlaps with the opening 207b and a region of the insulator 287 that overlaps with the opening 207c.

Next, an insulating film to be the insulator 215 and a conductive film to be the conductor 205b and the conductor 205c are formed in this order. The conductive film can be formed by a method similar to that can be used to form the conductive film to be the conductor 205a. For the conductive film, a material similar to any of the materials that can be used for the conductive film to be the conductor 205a can be used.

Next, CMP treatment is performed to remove part of the insulating film to be the insulator 215, part of the conductive film to be part of the conductor 205b and the conductor 205c, so that the insulator 216b is exposed. As a result, the insulator 215, the conductor 205b, and the conductor 205c are formed to fill the openings of the insulator 216b (FIG. 20B). At this time, the top surface of the conductor 205c is aligned with the top surface of the conductor 205b. Note that the insulator 216b is partly removed by the CMP treatment in some cases. This enables the insulator 216b to be planarized. In this manner, the capacitor 101 including the conductor 235a, the insulator 215, and the conductor 205c is formed.

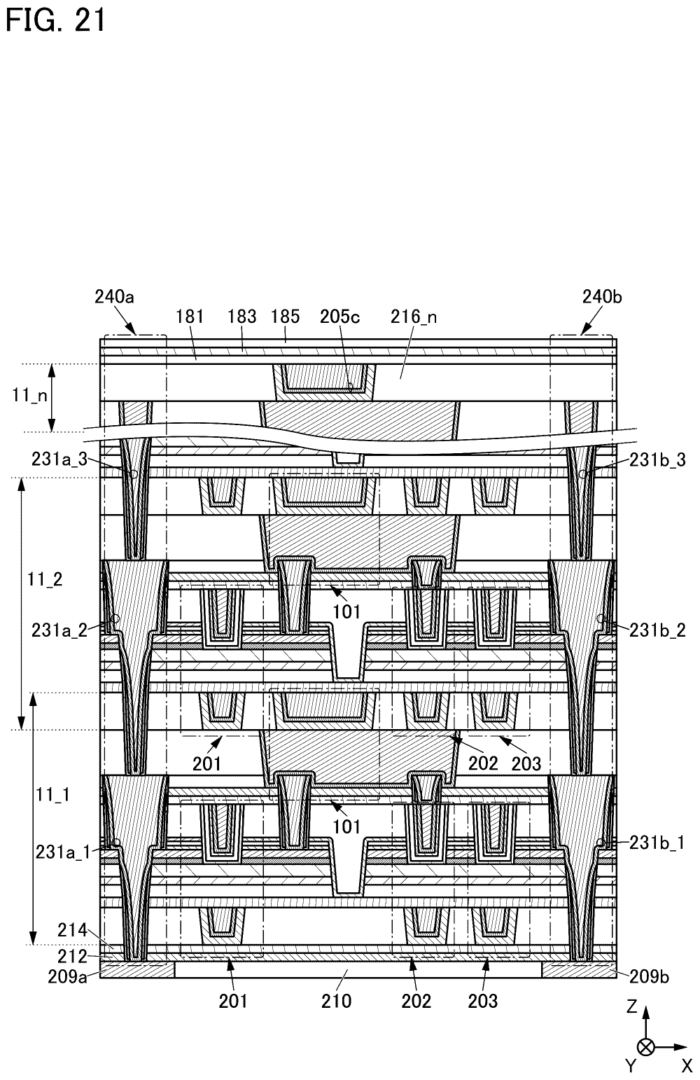

Through the above steps, the memory layer 11_1 can be formed. After that, the formation of the transistor 201, the transistor 202, the transistor 203, and the capacitor 101 is repeated n−1 times, whereby the memory layer 11_2 to the memory layer 11_n are formed (FIG. 21). Since the transistors included in the memory layer are not formed over the insulator 287 included in the memory layer 11_n, the conductor 205b is not formed over the insulator 287 included in the memory layer 11_n.

Furthermore, the memory layer 11_1 to the memory layer 11_n include the connection electrode 240a and the connection electrode 240b, as illustrated in FIG. 21. The connection electrode 240a includes the conductor 231a_1 to a conductor 231a_n (not illustrated), which are electrically connected to each other. The connection electrode 240b includes the conductor 231b_1 to a conductor 231b_n (not illustrated), which are electrically connected to each other.

Next, the insulator 181 is formed over the conductor 205c and the insulator 216_n. The insulator 181 can be formed by a method similar to that for forming the insulator 287, the insulator 285, the insulator 280, the insulator 216a, or the insulator 212. For the insulator 181, a material similar to any of the materials that can be used for the insulator 287, the insulator 285, the insulator 280, the insulator 216a, or the insulator 212 can be used.

Next, the insulator 183 is formed over the insulator 181, and the insulator 185 is formed over the insulator 183. Through the above steps, the semiconductor device illustrated in FIG. 21 can be manufactured.

This embodiment can be combined with the other embodiments as appropriate. In this specification, in the case where a plurality of structure examples are shown in one embodiment, the structure examples can be combined as appropriate.

### Embodiment 2

In this embodiment, a memory device of one embodiment of the present invention will be described with reference to drawings.

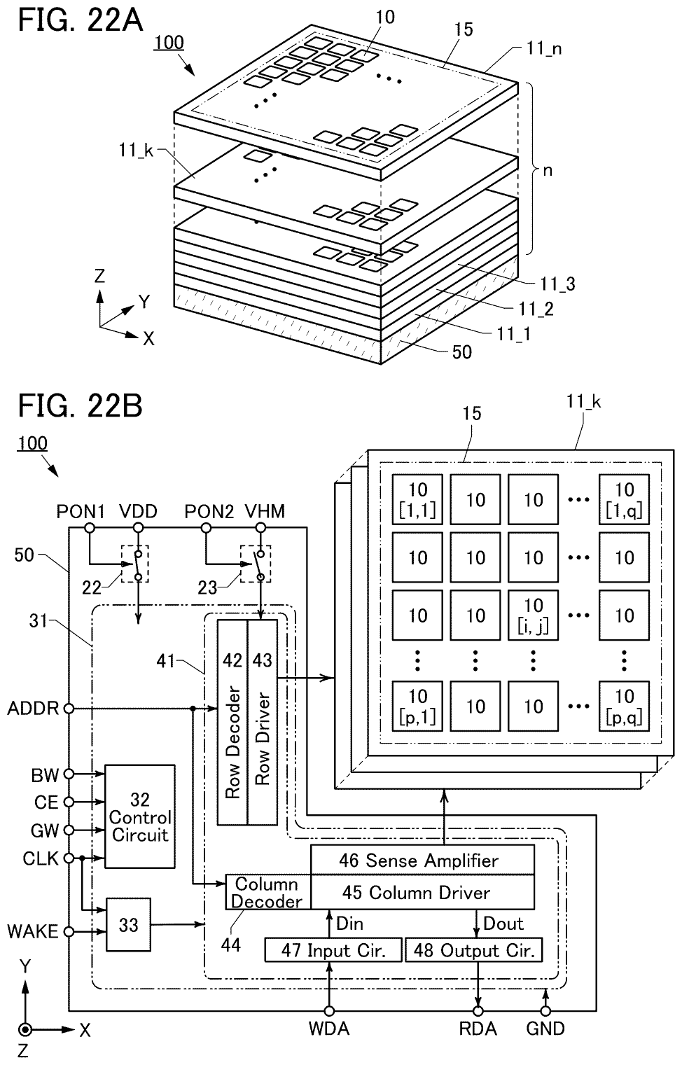

FIG. 22A is a schematic perspective view of a memory device of one embodiment of the present invention. FIG. 22B is a block diagram of the memory device of one embodiment of the present invention.

A memory device 100 illustrated in FIG. 22A and FIG. 22B includes a driver circuit layer 50 and the n memory layers 11 (n is an integer greater than or equal to 1). The n memory layers 11 each include a memory cell array 15. The memory cell array 15 includes the plurality of memory cells 10.

The memory layers 11 are provided over the driver circuit layer 50. Provision of the n memory layers 11 over the driver circuit layer 50 can reduce the area occupied by the memory device 100. Furthermore, memory capacity per unit area can be increased.

In this embodiment, the first memory layer is denoted by the memory layer 11_1, the second memory layer is denoted by the memory layer 11_2, and the third memory layer is denoted by a memory layer 11_3. Furthermore, the k-th (k is an integer greater than or equal to 1 and less than or equal to n) memory layer is denoted by a memory layer 11_k, and the n-th memory layer is denoted by the memory layer 11_n. Note that in this embodiment and the like, the simple term “memory layer 11” is sometimes used in the case of describing matters related to all the n memory layers 11 or matters common to the n memory layers.

### <Structure Example of Driver Circuit Layer 50>

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the memory device 100, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside.

The signal CLK is a clock signal. The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 100. For example, the control circuit performs a logical operation on the signal CE, the signal GW, and the signal BW to determine an operation mode (e.g., a writing operation or a reading operation) of the memory device 100. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33 and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47 (Input Cir.), an output circuit 48 (Output Cir.), and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting a wiring WWL (write word line) or a wiring RWL (read word line) specified by the row decoder 42. The column driver 45 has a function of writing data to the memory cells 10, a function of reading data from the memory cells 10, a function of retaining the read data, and the like. The column driver 45 has a function of selecting a wiring WBL (write bit line) or a wiring RBL (read bit line) specified by the column decoder 44.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 100. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 100, a high power supply voltage is VDD and a low power supply voltage is GND (a ground potential). In addition, VHM is a high power supply voltage used to set a word line at a high level and is higher than VDD. The on/off of the PSW 22 is controlled by the signal PON1, and the on/off of the PSW 23 is controlled by the signal PON2. The number of power domains to which VDD is supplied is one in the peripheral circuit 31 in FIG. 22B but can be more than one. In that case, a power switch is provided for each power domain.

### <Structure Example of Memory Layer 11>

A structure example of the n memory layers 11 is described. The n memory layers 11 each include the memory cell array 15. The memory cell array 15 includes the plurality of memory cells 10. FIG. 22A and FIG. 22B illustrate an example in which the memory cell array 15 includes the plurality of memory cells 10 arranged in a matrix of p rows and q columns (each of p and q is independently an integer greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 22B, the memory cell 10 provided in the first row and the first column is referred to as a memory cell 10[1,1], and the memory cell 10 provided in the p-th row and the q-th column is referred to as a memory cell 10[p,q]. The memory cell 10 provided in the i-th row and the j-th column (i is an integer greater than or equal to 1 and less than or equal to p, and j is an integer greater than or equal to 1 and less than or equal to q) is referred to as a memory cell 10[i,j].

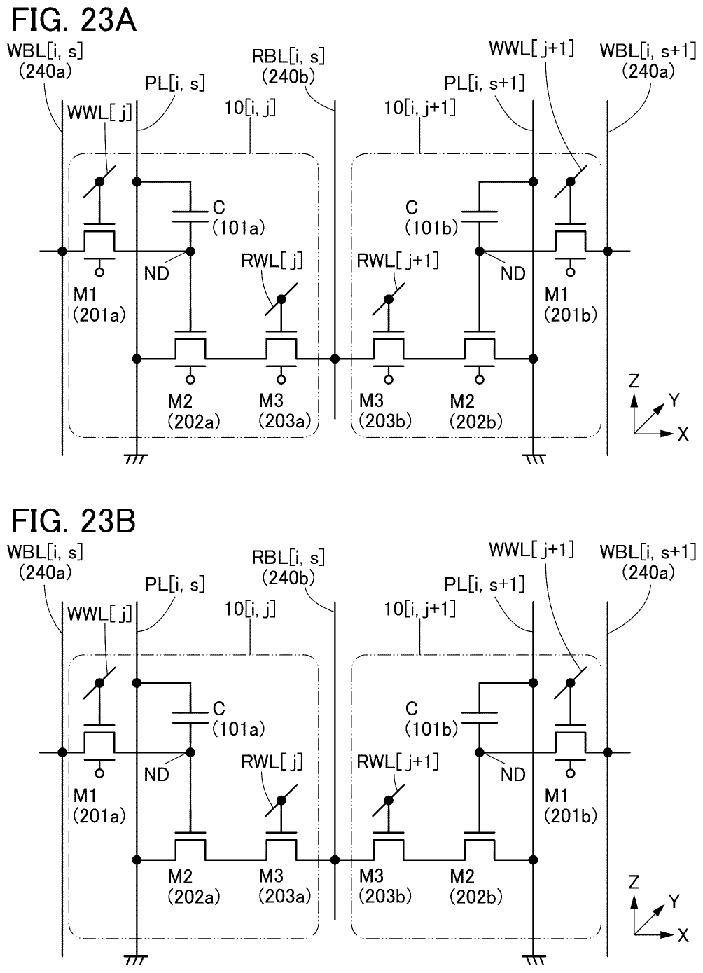

FIG. 23A and FIG. 23B illustrate circuit structure examples of memory cells. Embodiment 1 can be referred to for cross-sectional structure examples of the memory cells 10 corresponding to the circuit structures.

The memory cells 10 each include a transistor M1, a transistor M2, a transistor M3, and a capacitor C. A memory cell composed of three transistors and one capacitor is also referred to as a 3Tr1C memory cell. Thus, the memory cells 10 shown in this embodiment are each a 3Tr1C memory cell.

The transistor M1 corresponds to the transistor 201, the transistor 201a, or the transistor 201b described in Embodiment 1. The transistor M2 corresponds to the transistor 202, the transistor 202a, or the transistor 202b described in Embodiment 1. The transistor M3 corresponds to the transistor 203, the transistor 203a, or the transistor 203b described in Embodiment 1. The capacitor C corresponds to the capacitor 101 described in Embodiment 1. The wiring WBL corresponds to the connection electrode 240a described in Embodiment 1. The wiring RBL corresponds to the connection electrode 240b described in Embodiment 1.

In the memory cell 10[i,j], a gate of the transistor M1 is electrically connected to a wiring WWL[j], and one of a source and a drain of the transistor M1 is electrically connected to a wiring WBL[i,s]. Note that FIG. 23A illustrates a structure example in which part of the wiring WWL[j] functions as the gate of the transistor M1. One electrode of the capacitor C is electrically connected to a wiring PL[i,s], and the other electrode of the capacitor C is electrically connected to the other of the source and the drain of the transistor M1. Note that FIG. 23A illustrates a structure example in which part of the wiring PL[i,s] functions as the one electrode of the capacitor C, for example. A gate of the transistor M2 is electrically connected to the other electrode of the capacitor C, one of a source and a drain of the transistor M2 is electrically connected to one of a source and a drain of the transistor M3, and the other of the source and the drain of the transistor M2 is electrically connected to the wiring PL[i,s]. A gate of the transistor M3 is electrically connected to a wiring RWL[j], and the other of the source and the drain of the transistor M3 is electrically connected to a wiring RBL[i,s].

In the memory cell 10[i,j], a region where the other electrode of the capacitor C, the other of the source and the drain of the transistor M1, and the gate of the transistor M2 are electrically connected to one another and always have the same potential is referred to as a “node ND”.

In a memory cell 10[i,j+1], the gate of the transistor M1 is electrically connected to a wiring WWL[j+1], and one of the source and the drain of the transistor M1 is electrically connected to a wiring WBL[i,s+1]. Note that FIG. 23A illustrates a structure example in which part of the wiring WWL[j+1] functions as the gate of the transistor M1. One electrode of the capacitor C is electrically connected to a wiring PL[i,s+1], and the other electrode of the capacitor C is electrically connected to the other of the source and the drain of the transistor M1. Note that FIG. 23A illustrates a structure example in which part of the wiring PL[i,s+1] functions as the one electrode of the capacitor C, for example. The gate of the transistor M2 is electrically connected to the other electrode of the capacitor C, one of the source and the drain of the transistor M2 is electrically connected to one of the source and the drain of the transistor M3, and the other of the source and the drain of the transistor M2 is electrically connected to the wiring PL[i,s+1]. The gate of the transistor M3 is electrically connected to a wiring RWL[j+1], and the other of the source and the drain of the transistor M3 is electrically connected to the wiring RBL[i,s].

In the memory cell 10[i,j+1], a region where the other electrode of the capacitor C, the other of the source and the drain of the transistor M1, and the gate of the transistor M2 are electrically connected to one another and always have the same potential is referred to as the node ND.

Thus, the wiring RBL[i,s] is electrically connected to the other of the source and the drain of the transistor M3 included in the memory cell 10[i,j] and the other of the source and the drain of the transistor M3 included in the memory cell 10[i,j+1]. Accordingly, the wiring RBL[i,s] is shared by the memory cell 10[i,j] and the memory cell 10[i,j+1]. Although not illustrated, the wiring WBL[i,s] is shared by a memory cell 10[i,j−1] and the memory cell 10[i,j], and the wiring WBL[i,s+1] is shared by the memory cell 10[i,j+1] and a memory cell 10[i,j+2].

Accordingly, there is the following relationships between j and s indicating the positions of the columns. When j is an even number, s is j/2, which is an integer greater than or equal to 1 and less than or equal to q/2. When j is an odd number, s is (j+1)/2, which is an integer greater than or equal to 1 and less than or equal to (q+1)/2.

As illustrated in FIG. 23A, a transistor with a back gate may be used as each of the transistor M1, the transistor M2, and the transistor M3. The gate and the back gate are placed such that a channel formation region of a semiconductor is sandwiched between the gate and the back gate. The gate and the back gate are formed using conductors. The back gate can function like the gate. By changing the potential of the back gate, the threshold voltage of the transistor can be changed. The potential of the back gate may be the same as the potential of the gate or may be a ground potential or a given potential.

Note that each of the transistor M1, the transistor M2, and the transistor M3 does not necessarily include a back gate. For example, as illustrated in FIG. 23B, a transistor with a back gate may be used as the transistor M1 and a transistor without a back gate may be used as each of the transistor M2 and the transistor M3.

In addition, the gate and the back gate are formed using conductors and thus also have a function of preventing an electric field generated outside the transistor from affecting the semiconductor in which a channel is formed (particularly, a function of blocking static electricity). That is, a variation in the electrical characteristics of the transistor due to the influence of an external electric field such as static electricity can be inhibited. Moreover, providing the back gate can reduce the amount of change in threshold voltage of the transistor before and after the bias-temperature stress test (also referred to as a BT test).

For example, the use of a transistor with a back gate as the transistor M1 can reduce the influence of an external electric field, allowing the off state to be maintained stably. Thus, data written to the node ND can be retained stably. Providing the back gate can stabilize the operation of the memory cells 10 and can improve the reliability of the memory device including the memory cells 10.

Likewise, the use of a transistor with a back gate as the transistor M3 can reduce the influence of an external electric field, allowing the off state to be maintained stably. Thus, leakage current between the wiring RBL and the wiring PL can be reduced, resulting in a reduction in the power consumption of the memory device including the memory cells 10.

Note that in the case where the potential of the back gate of the transistor M2 is set to a ground potential, the one electrode of the capacitor C may have a function of the back gate of the transistor M2. In this case, the one electrode of the capacitor C is preferably provided to overlap with the other electrode of the capacitor C and a region of the transistor M2 where a channel is formed. Specifically, the structure of the semiconductor device illustrated in FIG. 5A is preferably employed for the memory cell 10.

Similarly, in the case where the potential of the back gate of each of the transistor M1 to the transistor M3 is set to a ground potential, the one electrode of the capacitor C may have a function of the back gate of each of the transistor M1 to the transistor M3. In this case, the one electrode of the capacitor C is preferably provided to overlap with the other electrode of the capacitor C and a region of each of the transistor M1 to the transistor M3 where a channel is formed. Specifically, the structure of the semiconductor device illustrated in FIG. 5B is preferably employed for the memory cell 10.

As a semiconductor layer in which the channel of each of the transistor M1, the transistor M2, and the transistor M3 is formed, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, an oxide semiconductor, or a nitride semiconductor may be used.

Note that each of the transistor M1, the transistor M2, and the transistor M3 is preferably a transistor using an oxide semiconductor, which is a kind of metal oxide, in a semiconductor layer in which a channel is formed (also referred to as an “OS transistor”). An oxide semiconductor has a band gap of 2 eV or more and thus has an extremely low off-state current. Thus, the power consumption of the memory cells 10 can be reduced. Accordingly, the power consumption of the memory device 100 including the memory cells 10 can be reduced.

A memory cell including an OS transistor can be referred to as an “OS memory”. The memory device 100 including the memory cell can also be referred to as an “OS memory”.

The OS transistor operates stably even in a high-temperature environment and has a small variation in electrical characteristics. For example, the off-state current hardly increases even in the high-temperature environment. Specifically, the off-state current hardly increases even at an environmental temperature higher than or equal to room temperature and lower than or equal to 200° C. Furthermore, the on-state current is unlikely to decrease even in the high-temperature environment. Thus, the OS memory can operate stably and have high reliability even in the high-temperature environment.

Furthermore, an OS transistor is highly resistant to radiation. Thus, the OS memory can provide a highly reliable memory device with a low frequency of occurrence of soft errors even in an environment where radiation can enter. Note that a soft error is a defect in which part of data stored in a memory cell is unintentionally inverted.

For example, the OS memory can be suitably used in outer space. Specifically, the OS memory can be used for memory devices provided in a space shuttle, an artificial satellite, a space probe, and the like. Examples of radiation include X-rays and a neutron beam. Outer space refers to, for example, space at an altitude greater than or equal to 100 km, and outer space described in this specification may include one or more of thermosphere, mesosphere, and stratosphere.

Alternatively, for example, the OS memory can be used in memory devices provided in working robots in a nuclear power plant and a treatment plant or a disposal plant for radioactive wastes. In particular, the OS memory can be favorably used in the memory devices provided in remote control robots that are controlled remotely in demolishment of a reactor facility, taking out of a nuclear fuel or a fuel debris, a field investigation or the like on a space with a large amount of radioactive substance, and the like.

Alternatively, for example, OS transistors can be favorably used as transistors included in semiconductor devices provided in electronic devices used for medical care with radial rays. Examples of the electronic device include an X-ray sensing panel in X-ray photography.

### <Operation Example of Memory Cell 10>

Data writing and reading operation examples of the memory cell 10 will be described. In this embodiment, normally-off n-channel transistors are used as the transistor M1 to the transistor M3.

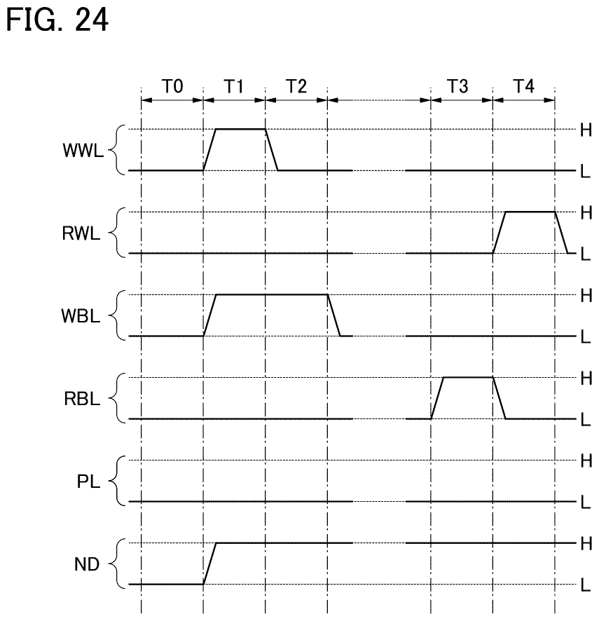

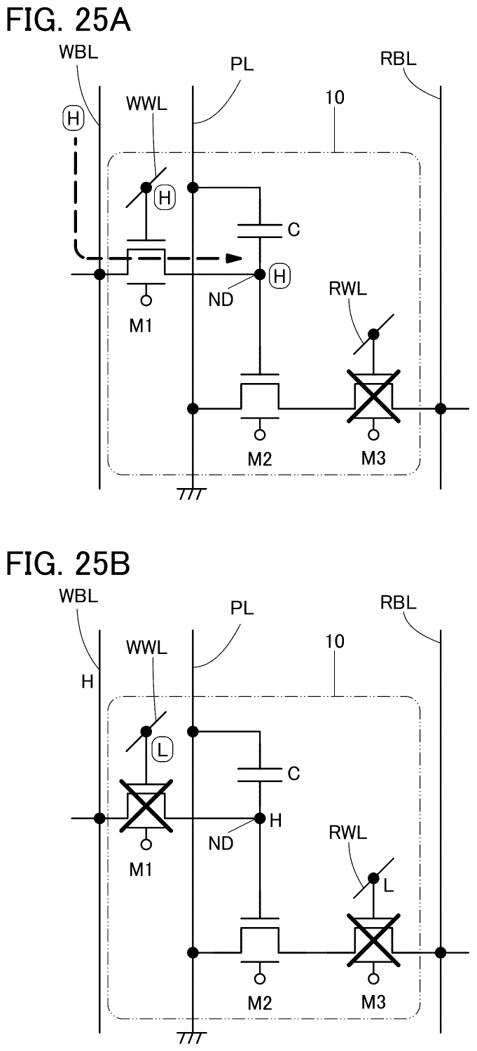

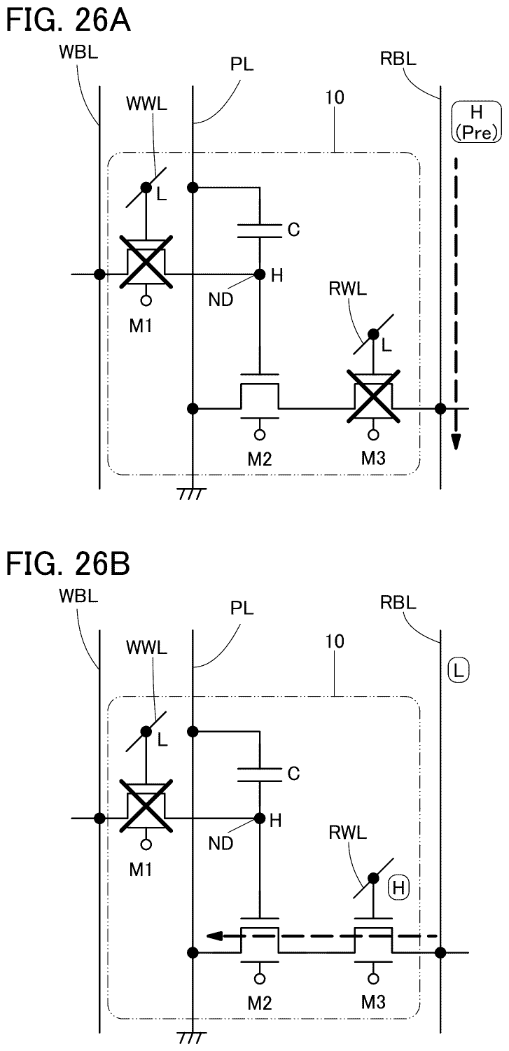

FIG. 24 is a timing chart for describing an operation example of the memory cell 10. FIG. 25A to FIG. 26B are circuit diagrams for describing the operation example of the memory cell 10.

In the following drawings and the like, for showing the potentials of a wiring and an electrode, “H” representing a potential H or “L” representing a potential L is sometimes written near the wiring and the electrode. In addition, enclosed “H” or “L” is sometimes written near a wiring or an electrode whose potential changes. Moreover, in the case where a transistor is in an off state, a symbol “X” is sometimes written on the transistor.

When the potential H is supplied to a gate of an n-channel transistor, the transistor is turned on. When the potential L is supplied to a gate of an n-channel transistor, the transistor is turned off. Thus, the potential H is a potential higher than the potential L. The potential H may be a potential equal to the high power supply potential VDD. The potential L is a potential lower than the potential H. The potential L may be a potential equal to the ground potential GND. In this embodiment, the potential L is a potential equal to the ground potential GND.

First, in Period TO, the potentials of the wiring WWL, the wiring RWL, the wiring WBL, the wiring RBL, the wiring PL, and the node ND are the potential L (FIG. 24). In addition, the ground potential GND is supplied to the back gates of the transistor M1, the transistor M2, and the transistor M3.

### [Data Writing Operation]

In Period T1, the potential H is supplied to the wiring WWL and the wiring WBL. Accordingly, the transistor M1 is turned on and the potential H is written to the node ND as data indicating “1” (FIG. 24 and FIG. 25A).

When the potential of the node ND becomes the potential H, the transistor M2 is turned on. Since the potential of the wiring RWL is the potential L, the transistor M3 is in the off state. The transistor M3 in the off state can prevent a short circuit between the wiring RBL and the wiring PL.

### [Retention Operation]

In Period T2, the potential L is supplied to the wiring WWL. Accordingly, the transistor M1 is turned off and the node ND is brought into a floating state. Thus, data (potential H) written to the node ND is retained (FIG. 24 and FIG. 25B). Note that after Period T2, the potential of the wiring WBL becomes the potential L.

As described above, the OS transistor is a transistor having an extremely low off-state current. The use of the OS transistor as the transistor M1 enables data written to the node ND to be retained for a long period. Therefore, it becomes unnecessary to refresh the potential of the node ND and the power consumption of the memory cell 10 can be reduced. Thus, the power consumption of the memory device 100 can be reduced.

When the OS transistor is used as one or both of the transistor M2 and the transistor M3, leakage current flowing between the wiring RBL and the wiring PL in the writing operation and the retention operation can be extremely low.

Moreover, the OS transistor has a higher source-drain withstand voltage than a transistor in which silicon is used in a semiconductor layer where a channel is formed (also referred to as a Si transistor). When the OS transistor is used as the transistor M1, a higher potential can be supplied to the node ND. This increases the range of a potential retained at the node ND. An increase in the range of the potential retained at the node ND makes it easy to retain multilevel data or to retain analog data.

### [Reading Operation]

In Period T3, the potential His precharged (Pre) to the wiring RBL. That is, the potential of the wiring RBL is set to the potential H and then the wiring RBL is brought into a floating state (FIG. 24 and FIG. 26A).

Next, in Period T4, the potential H is supplied to the wiring RWL, so that the transistor M3 is turned on. At this time, in the case where the potential of the node ND is the potential H, the transistor M2 is in an on state; thus, electrical continuity is established between the wiring RBL and the wiring PL through the transistor M2 and the transistor M3. When electrical continuity is established between the wiring RBL and the wiring PL, the potential of the wiring RBL, which is in a floating state, changes from the potential H to the potential L (FIG. 24 and FIG. 26B).

Note that the transistor M2 is in an off state in the case where the potential L is written to the node ND as data indicating “0”. Thus, electrical continuity is not established between the wiring RBL and the wiring PL even when the transistor M3 is turned on, and the potential of the wiring RBL remains the potential H.

By detecting a change in the potential of the wiring RBL at the time of supplying the potential H to the wiring RWL in this manner, data written to the memory cell 10 can be read.

The memory cell 10 using the OS transistor employs a method in which electric charge is written to the node ND through the OS transistor; hence, a high voltage, which is required for a conventional flash memory, is unnecessary and a high-speed writing operation is possible. Furthermore, unlike in a flash memory, the number of times of data writing and reading in the memory cell 10 using the OS transistor is substantially unlimited because charge injection and extraction into/from a floating gate or a charge-trap layer are not performed. Unlike in a flash memory, unstableness due to an increase of electron trap centers is not observed in the memory cell 10 using the OS transistor even when a rewriting operation is repeated. The memory cell 10 using the OS transistor is less likely to degrade than a conventional flash memory and can have high reliability.

Unlike a magnetic memory, a resistive random access memory, or the like, the memory cell 10 using the OS transistor has no change in the structure at the atomic level. Thus, the memory cell 10 using the OS transistor has higher rewrite endurance than a magnetic memory and a resistive random access memory.

### <Structure Example of Sense Amplifier 46>

Next, a structure example of the sense amplifier 46 will be described. Specifically, a structure example of a write read circuit that includes the sense amplifier 46 and performs writing or reading of a data signal will be described.

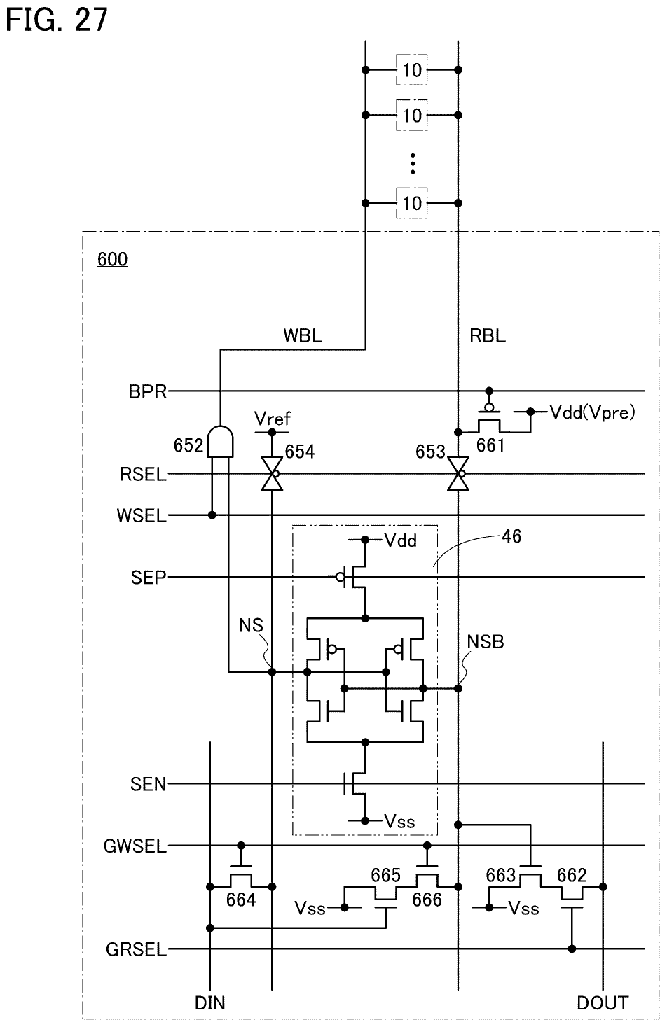

FIG. 27 is a circuit diagram illustrating a structure example of a circuit 600 that includes the sense amplifier 46 and performs writing or reading of a data signal. The circuit 600 is provided for every wiring WBL and every wiring RBL.

The circuit 600 includes a transistor 661 to a transistor 666, the sense amplifier 46, an AND circuit 652, an analog switch 653, and an analog switch 654.

The circuit 600 operates in accordance with a signal SEN, a signal SEP, a signal BPR, a signal RSEL, a signal WSEL, a signal GRSEL, and a signal GWSEL.

Data DIN input to the circuit 600 is written to the memory cell 10 through the wiring WBL electrically connected to a node NS through the AND circuit 652. Data DOUT written to the memory cell 10 is transmitted to the wiring RBL electrically connected to a node NSB through the analog switch 653 and output from the circuit 600 as the data DOUT.

Note that the data DIN and the data DOUT are internal signals and respectively correspond to the signal WDA and the signal RDA.

The transistor 661 is included in a precharge circuit. The wiring RBL is precharged to a precharge potential Vpre by the transistor 661. Note that in this embodiment, the case where a potential Vdd (high level) is used as the precharge potential Vpre will be described (denoted by Vdd (Vpre) in FIG. 27). The signal BPR is a precharge signal, and the conduction state of the transistor 661 is controlled by the signal BPR.

In a reading operation, the sense amplifier 46 determines whether data input to the wiring RBL is at a high level or a low level. In a writing operation, the sense amplifier 46 functions as a latch circuit that temporarily retains the data DIN input to the circuit 600.

The sense amplifier 46 illustrated in FIG. 27 is a latch sense amplifier. The sense amplifier 46 includes two inverter circuits, and an input node of one of the inverter circuits is connected to an output node of the other of the inverter circuits. When the input node of the one of the inverter circuits is the node NS and the output node is the node NSB, complementary data is retained at the node NS and the node NSB.

The signal SEN and the signal SEP are each a sense amplifier enable signal for activating the sense amplifier 46, and a reference potential Vref is a read judge potential. The sense amplifier 46 determines whether the potential of the node NSB at the time of the activation is at a high level or a low level on the basis of the reference potential Vref.

The AND circuit 652 controls electrical continuity between the node NS and the wiring WBL. The analog switch 653 controls electrical continuity between the node NSB and the wiring RBL. The analog switch 654 controls electrical continuity between the node NS and a wiring supplying the reference potential Vref.

In data reading, the potential of the wiring RBL is transmitted to the node NSB by the analog switch 653. When the potential of the wiring RBL is lower than the reference potential Vref, the sense amplifier 46 determines that the wiring RBL is at a low level. The sense amplifier 46 determines that the wiring RBL is at a high level when the potential of the wiring RBL does not become lower than the reference potential Vref.

The signal WSEL is a write selection signal and controls the AND circuit 652. The signal RSEL is a read selection signal and controls the analog switch 653 and the analog switch 654.

The transistor 662 and the transistor 663 are included in an output MUX (multiplexer) circuit. The signal GRSEL is a global read selection signal and controls the output MUX circuit. The output MUX circuit has a function of selecting the wiring RBL from which data is to be read.

The output MUX circuit has a function of outputting the data DOUT read from the sense amplifier 46.

The transistor 664 to the transistor 666 are included in a write driver circuit. The signal GWSEL is a global write selection signal and controls the write driver circuit. The write driver circuit has a function of writing the data DIN to the sense amplifier 46.

The write driver circuit has a function of selecting a column to which the data DIN is to be written. The write driver circuit writes data in byte units, half-word units, or word units in response to the signal GWSEL.

In a gain-cell memory cell, at least two transistors are required for one memory cell, which makes it difficult to increase the number of memory cells that can be placed per unit area. However, when an OS transistor is used as a transistor included in the memory cell 10, the plurality of memory cell arrays 15 can be stacked. That is, the amount of data that can be stored per unit area can be increased. A gain-cell memory cell can operate as a memory by amplifying accumulated electric charge by the closest transistor even when the capacitance of accumulated electric charge is small. When an OS transistor with an extremely low off-state current is used as a transistor included in the memory cell 10, the capacitance of the capacitor can be made small. Furthermore, one or both of the gate capacitance of a transistor and the parasitic capacitance of a wiring can be used as the capacitor, so that the capacitor can be omitted. That is, the area of the memory cell 10 can be made small.

Since a change in electrical characteristics of an OS transistor due to radiation irradiation is small, i.e., an OS transistor is highly resistant to radiation as described above, an OS transistor can be suitably used even in an environment where radiation can enter. Thus, when an OS transistor is used as the transistor included in the memory cell 10, the memory cell 10 highly resistant to radiation can be provided.

Presumably, memory errors of memory cells due to radiation irradiation occur due to failure (also referred to as a permanent error or a hard error) in transistors included in the memory cells which is caused by TID (Total Ionizing Dose). A possible factor of the failure is a shift in negative direction (normally-on characteristics) in write transistors or read transistors. Note that the “TID” sometimes refers to a total dose effect (total ionizing dose effect). The “TID” described in this specification and the like therefore can be rephrased as “total dose effect” in some cases.

To further increase the resistance of the memory cell 10 to radiation irradiation, a multi-gate transistor is preferably used as at least one of the transistor M1 to the transistor M3. Note that in this specification and the like, a multi-gate transistor refers to a transistor which includes a plurality of gates and in which the plurality of gates are electrically connected to each other. In particular, a multi-gate transistor including two gates is referred to as a double-gate transistor. A multi-gate transistor including three gates is particularly referred to as a triple-gate transistor.

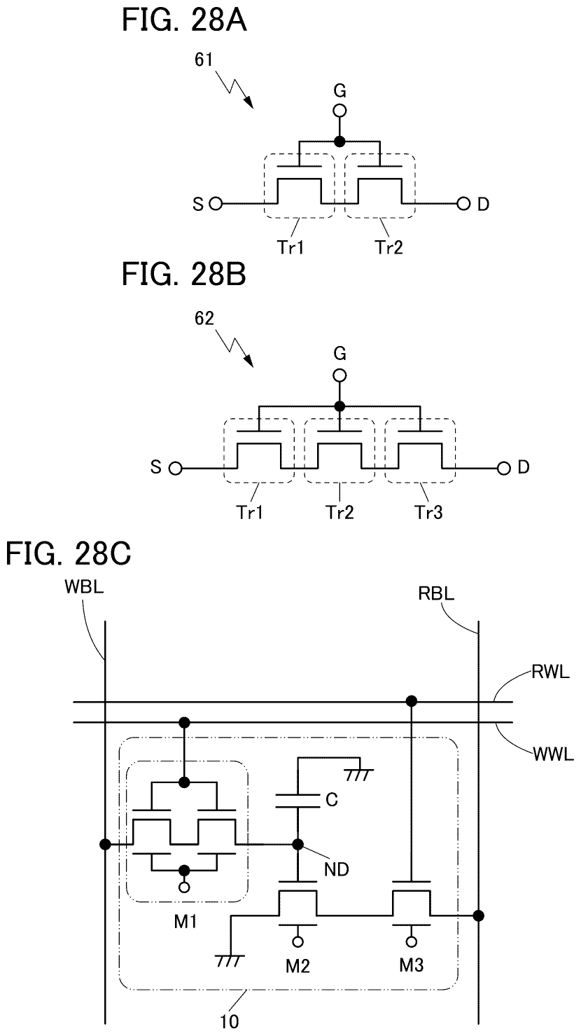

FIG. 28A illustrates a circuit symbol example of a double-gate transistor 61.

The transistor 61 has a structure in which a transistor Tr1 and a transistor Tr2 are connected in series. FIG. 28A illustrates a structure in which one of a source and a drain of the transistor Tr1 is electrically connected to a terminal S, the other of the source and the drain of the transistor Tr1 is electrically connected to one of a source and a drain of the transistor Tr2, and the other of the source and the drain of the transistor Tr2 is electrically connected to a terminal D. In FIG. 28A, gates of the transistor Tr1 and the transistor Tr2 are electrically connected to each other and electrically connected to a terminal G.

The transistor 61 illustrated in FIG. 28A has a function of switching a conduction state and a non-conduction state between the terminal S and the terminal D by changing the potential of the terminal G. Thus, the transistor 61, which is a double-gate transistor, includes the transistor Tr1 and the transistor Tr2, but the transistor 61 substantially functions as one transistor. That is, it can be said that in FIG. 28A, one of a source and a drain of the transistor 61 is electrically connected to the terminal S, the other of the source and the drain of the transistor 61 is electrically connected to the terminal D, and a gate of the transistor 61 is electrically connected to the terminal G.

Even entry of radiation into the transistor 61 makes one of the transistor Tr1 and the transistor Tr2 cause a shift in negative direction and have normally-on characteristics, the electrical continuity between the terminal S and the terminal D can be established or broken. Thus, the transistor 61 can be more highly resistant to radiation irradiation.

The transistor Tr1 and the transistor Tr2 each preferably include a separate semiconductor layer though the semiconductor layer may be shared. In other words, the semiconductor layer of the transistor Tr1 and the semiconductor layer of the transistor Tr2 are preferably separated from each other. The simultaneous failure of the transistor Tr1 and the transistor Tr2 can be made to occur less frequently, as compared with the case where the semiconductor layer is shared by the transistor Tr1 and the transistor Tr2.

FIG. 28B illustrates a circuit symbol example of a triple-gate transistor 62.

The transistor 62 has a structure in which the transistor Tr1, the transistor Tr2, and the transistor Tr3 are connected in series. FIG. 28B illustrates a structure in which the one of the source and the drain of the transistor Tr1 is electrically connected to the terminal S, the other of the source and the drain of the transistor Tr1 is electrically connected to the one of the source and the drain of the transistor Tr2, the other of the source and the drain of the transistor Tr2 is electrically connected to one of a source and a drain of the transistor Tr3, and the other of the source and the drain of the transistor Tr3 is electrically connected to the terminal D. In FIG. 28B, gates of the transistor Tr1, the transistor Tr2, and the transistor Tr3 are electrically connected to each other and electrically connected to the terminal G.

The transistor 62 illustrated in FIG. 28B has a function of switching a conduction state and a non-conduction state between the terminal S and the terminal D by changing the potential of the terminal G. Thus, the transistor 62, which is a triple-gate transistor, includes the transistor Tr1, the transistor Tr2, and the transistor Tr3, but the transistor 62 substantially functions as one transistor. In other words, it can be said that in FIG. 28B, one of a source and a drain of the transistor 62 is electrically connected to the terminal S, the other of the source and the drain is electrically connected to the terminal D, and a gate is electrically connected to the terminal G.

The memory cell 10 can be further resistant to radiation irradiation when a triple-gate transistor is used as at least one of the transistor M1 to the transistor M3, as in the case where a double-gate transistor is used as at least one of the transistor M1 to the transistor M3.

FIG. 28C illustrates a structure example of the memory cell 10 in the case where a double-gate transistor is used as the transistor M1. Note that the transistor M1 in FIG. 28C includes the back gate. A terminal electrically connected to back gates of the transistor Tr1 and the transistor Tr2 included in the transistor M1 can be the same node. Alternatively, a terminal electrically connected to the back gate of the transistor Tr1 and a terminal electrically connected to the back gate of the transistor Tr2 may be separated from each other.

When the transistor 61 is used as the transistor M1 as illustrated in FIG. 28C, data written to the node ND can be stably retained. Note that as the transistor M1, a triple-gate transistor or a multi-gate transistor including four or more gates may be used.

Although FIG. 28C illustrates a structure in which the transistor 61 is used as the transistor M1, a multi-gate transistor is preferably used as at least one of the transistor M1 to the transistor M3. For example, when a multi-gate transistor is used as the transistor M2, an increase in read current can be inhibited and a failure in reading of the data written to the node ND at the time of reading can be prevented. For example, when a multi-gate transistor is used as the transistor M3, a memory cell different from the selected memory cell can be inhibited from being selected.

In view of the above, in order to increase the resistance of the memory cell 10 to radiation irradiation, the semiconductor layer of the transistor M2 and the semiconductor layer of the transistor M3 are preferably separated from each other. On the other hand, sharing the semiconductor layer the transistor M2 and the transistor M3 can increase the integration of the memory cell 10. Hence, the structure of the semiconductor layers of the transistor M2 and the transistor M3 is preferably selected as appropriate depending on the application of the memory cell 10.

This embodiment can be combined with the other embodiments as appropriate.

### Embodiment 3

In this embodiment, an example of a chip on which the memory device of one embodiment of the present invention is mounted will be described with reference to drawings.

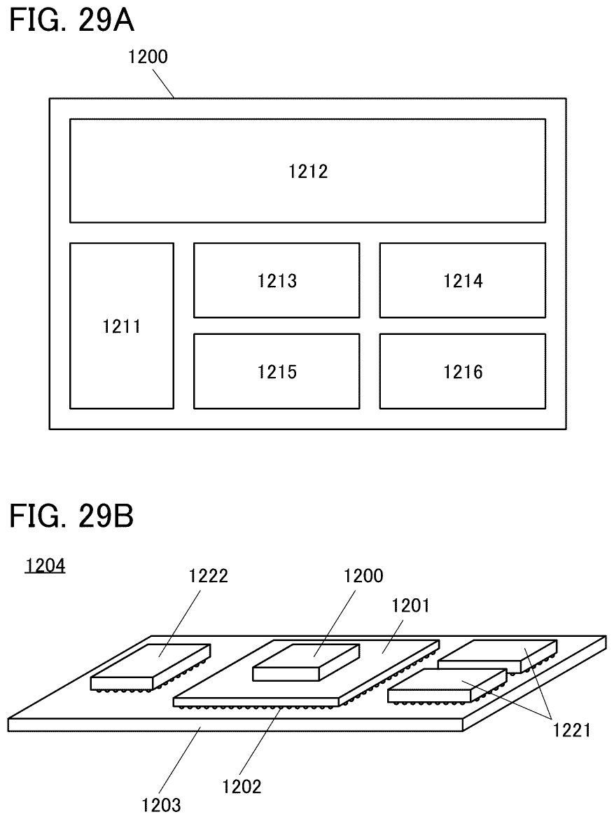

A plurality of circuits (systems) are mounted on a chip 1200 illustrated in FIG. 29A and FIG. 29B. A technique for integrating a plurality of circuits (systems) into one chip is referred to as system on chip (SoC) in some cases.

As illustrated in FIG. 29A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 29B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Memory devices such as DRAMs 1221 and a flash memory 1222 may be provided over the motherboard 1203. For example, the NOSRAM described in the above embodiment can be used as the DRAM 1221. This can make the DRAM 1221 have low power consumption, operate at high speed, and have a large capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The NOSRAM described above can be used as the memory. Moreover, the GPU 1212 is suitable for parallel computation of a large amount of data and thus can be used for image processing or a product-sum operation. When an image processing circuit or a product-sum operation circuit using an OS transistor is provided in the GPU 1212, image processing or a product-sum operation can be performed with low power consumption.

In addition, since the CPU 1211 and the GPU 1212 are provided on the same chip, a wiring between the CPU 1211 and the GPU 1212 can be shortened, and data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at a high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with the other embodiments as appropriate.

### Embodiment 4

In this embodiment, examples of an electronic component incorporating the memory device of one embodiment of the present invention will be described.

### [Electronic Component]

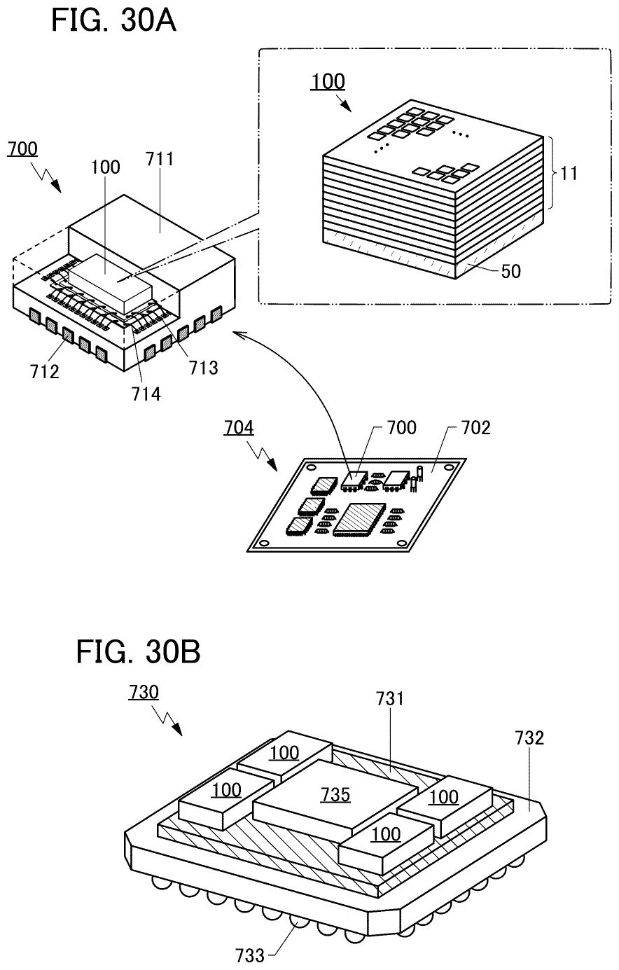

FIG. 30A is a perspective view of an electronic component 700 and a substrate (circuit board 704) on which the electronic component 700 is mounted. The electronic component 700 illustrated in FIG. 30A includes the memory device 100 that is the memory device of one embodiment of the present invention in a mold 711. FIG. 30A omits part of the electronic component to illustrate the inside of the electronic component 700. The electronic component 700 includes a land 712 outside the mold 711. The land 712 is electrically connected to an electrode pad 713, and the electrode pad 713 is electrically connected to the memory device 100 through a wire 714. The electronic component 700 is mounted on a printed circuit board 702, for example. A plurality of such electronic components are combined and electrically connected to each other on the printed circuit board 702, so that the circuit board 704 is completed.

As described in the above embodiment, the memory device 100 includes the driver circuit layer 50 and the memory layers 11 (each including the memory cell array 15).

FIG. 30B is a perspective view of an electronic component 730. The electronic component 730 is an example of a SiP (System in package) or an MCM (Multi Chip Module). In the electronic component 730, an interposer 731 is provided over a package substrate 732 (printed circuit board), and a semiconductor device 735 and a plurality of the memory devices 100 are provided over the interposer 731.

The electronic component 730 using the memory devices 100 as high bandwidth memory (HBM) is illustrated as an example. An integrated circuit (a semiconductor device) such as a CPU, a GPU, or an FPGA (Field Programmable Gate Array) can be used as the semiconductor device 735.

As the package substrate 732, for example, a ceramic substrate, a plastic substrate, or a glass epoxy substrate can be used. As the interposer 731, for example, a silicon interposer or a resin interposer can be used.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided over the interposer 731 to an electrode provided over the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In a silicon interposer, a TSV (Through Silicon Via) can also be used as the through electrode.

A silicon interposer is preferably used as the interposer 731. The silicon interposer can be manufactured at lower cost than an integrated circuit because it is not necessary to provide an active element. Moreover, since wirings of a silicon interposer can be formed through a semiconductor process, formation of minute wirings, which is difficult for a resin interposer, is easily achieved.

In order to achieve a wide memory bandwidth, many wirings need to be connected to an HBM. Therefore, formation of minute and high-density wirings is required for an interposer on which an HBM is mounted. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity, so that a poor connection between the silicon interposer and an integrated circuit provided over the silicon interposer is less likely to occur. It is particularly preferable to use a silicon interposer for a 2.5D package (2.5-dimensional mounting) in which a plurality of integrated circuits are arranged side by side over the interposer.

A heat sink (radiator plate) may be provided to overlap with the electronic component 730. In the case of providing a heat sink, the heights of integrated circuits provided over the interposer 731 are preferably the same. In the electronic component 730 described in this embodiment, the heights of the memory devices 100 and the semiconductor device 735 are preferably the same, for example.

An electrode 733 may be provided on the bottom portion of the package substrate 732 to mount the electronic component 730 on another substrate. FIG. 30B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of a mounting method include SPGA (Staggered Pin Grid Array), LGA (Land Grid Array), QFP (Quad Flat Package), QFJ (Quad Flat J-leaded package), and QFN (Quad Flat Non-leaded package).

This embodiment can be combined with the other embodiments as appropriate.

### Embodiment 5

In this embodiment, application examples of the memory device of one embodiment of the present invention will be described.

The memory device of one embodiment of the present invention can be used as memory devices of a variety of electronic devices (e.g., information terminals, computers, smartphones, e-book readers, digital still cameras, video cameras, video recording/reproducing devices, navigation systems, and game machines). The memory device can also be used for image sensors, IoT (Internet of Things), healthcare-related devices, and the like. Note that here, the computers refer not only to tablet computers, laptop computers, and desktop computers, but also to large computers such as server systems.

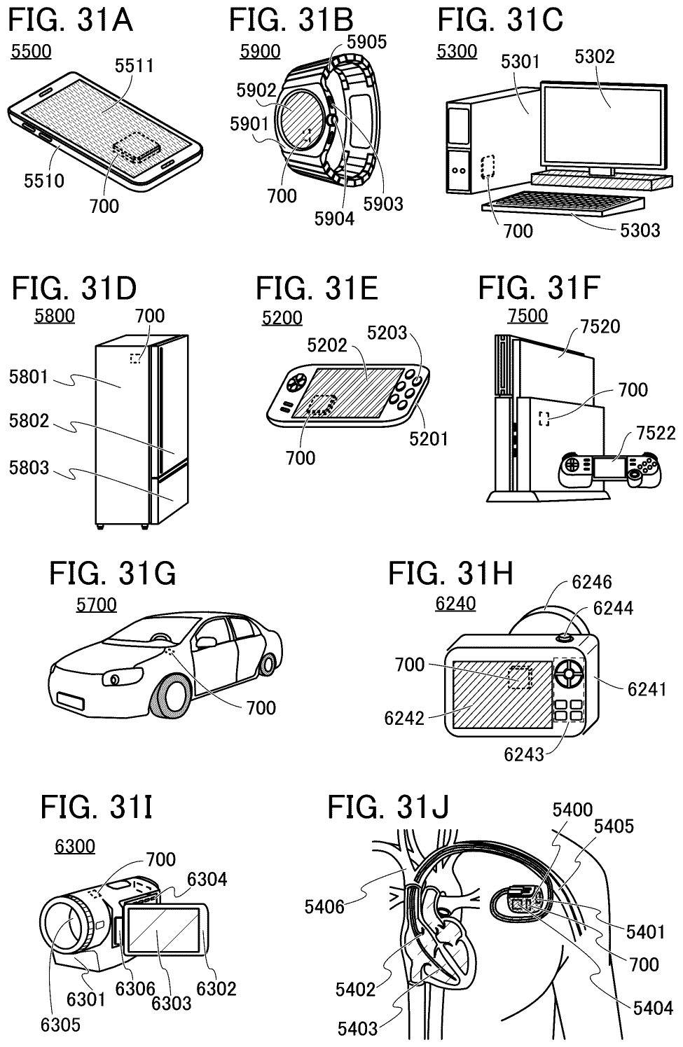

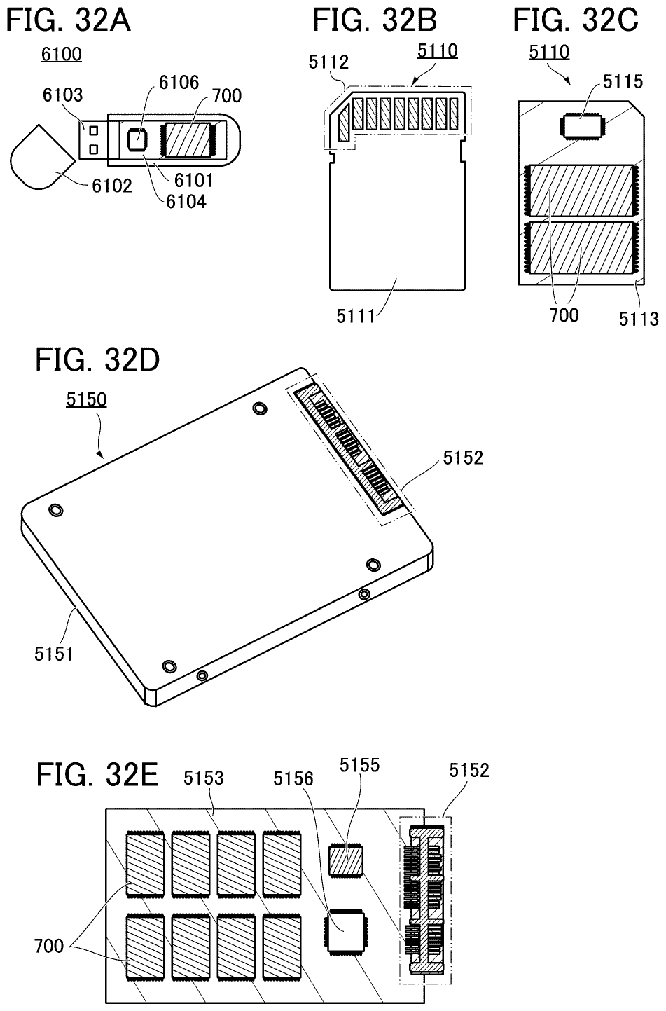

Examples of an electronic device including the memory device of one embodiment of the present invention will be described. Note that FIG. 31A to FIG. 31J and FIG. 32A to FIG. 32E each illustrate a state where the electronic component 700 or the electronic component 730 that includes the memory device described in the above embodiments is included in an electronic device.

### [Mobile Phone]

An information terminal 5500 illustrated in FIG. 31A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

By using the memory device of one embodiment of the present invention, the information terminal 5500 can retain a temporary file generated at the time of executing an application (e.g., a web browser's cache).

### [Wearable Terminal]

FIG. 31B illustrates an information terminal 5900 as an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by using the memory device of one embodiment of the present invention.

### [Information Terminal]

FIG. 31C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application by using the memory device of one embodiment of the present invention.

FIG. 31A to FIG. 31C illustrate the smartphone, the wearable terminal, and the desktop information terminal as electronic devices, and examples of other information terminals include a PDA (Personal Digital Assistant), a laptop information terminal, and a workstation.

### [Household Appliance]

FIG. 31D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The memory device of one embodiment of the present invention can be used in the electric refrigerator-freezer 5800. The electric refrigerator-freezer 5800 can transmit and receive information on food stored in the electric refrigerator-freezer 5800 and food expiration dates, for example, to and from an information terminal via the Internet. In the electric refrigerator-freezer 5800, the memory device of one embodiment of the present invention can retain a temporary file generated at the time of transmitting the information.

FIG. 31D illustrates the electric refrigerator-freezer as a household appliance, and examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### [Game Machine]

FIG. 31E illustrates a portable game machine 5200 as an example of a game machine. The portable game machine 5200 includes a housing 5201, a display portion 5202, a button 5203, and the like.

FIG. 31F illustrates a stationary game machine 7500 as an example of a game machine. The stationary game machine 7500 can be especially referred to as a home-use stationary game machine. The stationary game machine 7500 includes a main body 7520 and a controller 7522. Note that the controller 7522 can be connected to the main body 7520 with or without a wire. Although not illustrated in FIG. 31F, the controller 7522 can include a display portion that displays a game image, and an input interface besides the button, such as a touch panel, a stick, a rotating knob, and a sliding knob. The shape of the controller 7522 is not limited to that illustrated in FIG. 31F, and the shape of the controller 7522 may be changed in various ways in accordance with the genres of games. For example, for a shooting game such as an FPS (First Person Shooter) game, a gun-shaped controller having a trigger button can be used. For another example, for a music game, a controller having a shape of a musical instrument, audio equipment, or the like can be used. Furthermore, the stationary game machine may include one or more of a camera, a depth sensor, and a microphone so that the game player can play a game using a gesture or a voice instead of a controller.

Videos displayed on the game machine can be output with a display device such as a television device, a personal computer display, a game display, or a head-mounted display.

By using the memory device of one embodiment of the present invention in the portable game machine 5200 or the stationary game machine 7500, power consumption can be reduced. Moreover, heat generation from a circuit can be reduced owing to low power consumption; thus, the influence of heat generation on the circuit itself, a peripheral circuit, and a module can be reduced.

Moreover, by using the memory device of one embodiment of the present invention, the portable game machine 5200 or the stationary game machine 7500 can retain a temporary file or the like necessary for an arithmetic operation that occurs during game play.

FIG. 31E and FIG. 31F illustrate the portable game machine and the home-use stationary game machine as examples of game machines, and examples of other game machines include an arcade game machine installed in an entertainment facility (e.g., a game center and an amusement park) and a throwing machine for batting practice, installed in sports facilities.

### [Moving Vehicle]

The memory device of one embodiment of the present invention can be used in an automobile, which is a moving vehicle, and the periphery of a driver's seat in the automobile.

FIG. 31G illustrates an automobile 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the automobile 5700. In addition, a memory device showing the above information may be provided around the driver's seat.

In particular, the display device can compensate for the view obstructed by a pillar, blind areas for the driver's seat, and the like by displaying a video from an imaging device (not illustrated) provided for the automobile 5700, which can improve safety. That is, displaying an image taken by the imaging device provided on the exterior of the automobile 5700 can compensate for blind areas and improve safety.

The memory device of one embodiment of the present invention can temporarily retain information; thus, the memory device can be used to retain temporary information necessary in a system conducting automatic driving, navigation, risk prediction, or the like for the automobile 5700, for example. Moreover, the memory device of one embodiment of the present invention may be configured to retain a video of a driving recorder provided in the automobile 5700.

Although the automobile is described above as an example of a moving vehicle, the moving vehicle is not limited to the automobile. Examples of the moving vehicle include a train, a monorail train, a ship, and a flying object (a helicopter, an unmanned aircraft (drone), an airplane, or a rocket).

### [Camera]

The memory device of one embodiment of the present invention can be used in a camera.

FIG. 31H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that the digital camera 6240 is configured here such that the lens 6246 is detachable from the housing 6241 for replacement; alternatively, the lens 6246 may be integrated with the housing 6241. Moreover, the digital camera 6240 may be configured to be additionally equipped with a stroboscope, a viewfinder, or the like.

By using the memory device of one embodiment of the present invention, the digital camera 6240 can have low power consumption. Moreover, heat generation from a circuit can be reduced owing to low power consumption; thus, the influence of heat generation on the circuit itself, a peripheral circuit, and a module can be reduced.

### [Video Camera]

The memory device of one embodiment of the present invention can be used in a video camera.

FIG. 31I illustrates a video camera 6300 as an example of an imaging device. The video camera 6300 includes a first housing 6301, a second housing 6302, a display portion 6303, an operation switch 6304, a lens 6305, a joint 6306, and the like. The operation switch 6304 and the lens 6305 are provided in the first housing 6301, and the display portion 6303 is provided in the second housing 6302. The first housing 6301 and the second housing 6302 are connected to each other with the joint 6306, and the angle between the first housing 6301 and the second housing 6302 can be changed with the joint 6306. Videos displayed on the display portion 6303 may be switched in accordance with the angle at the joint 6306 between the first housing 6301 and the second housing 6302.

When a video taken by the video camera 6300 is recorded, the video needs to be encoded in accordance with a data recording format. With the use of the memory device of one embodiment of the present invention, the video camera 6300 can retain a temporary file generated at the time of encoding.

### [ICD]

The memory device of one embodiment of the present invention can be used in an implantable cardioverter-defibrillator (ICD).

FIG. 31J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with the end of one of the wires placed in the right ventricle and the end of the other wire placed in the right atrium.

The ICD main unit 5400 functions as a pacemaker and paces the heart when the heart rate is not within a predetermined range. When the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor, the number of times the treatment with pacing is performed, and the time taken for the treatment, for example, can be stored in the electronic component 700.

The antenna 5404 can receive electric power, and the battery 5401 is charged with the electric power. When the ICD main unit 5400 includes a plurality of batteries, the safety can be improved. Specifically, even when some of the batteries in the ICD main unit 5400 are dead, the other batteries can work properly; hence, the batteries also function as an auxiliary power source.

In addition to the antenna 5404 that can receive electric power, an antenna that can transmit a physiological signal may be included to construct, for example, a system that monitors cardiac activity by checking physiological signals such as a pulse, a respiratory rate, a heart rate, and body temperature with an external monitoring device.

### [Expansion Device for PC]

The memory device of one embodiment of the present invention can be used in a computer such as a PC (Personal Computer) and an expansion device for an information terminal.

FIG. 32A illustrates, as an example of the expansion device, a portable expansion device 6100 that is externally attached to a PC and includes a chip capable of storing information. The expansion device 6100 can store information using the chip when connected to a PC with a USB, for example. Note that FIG. 32A illustrates the portable expansion device 6100; however, the expansion device of one embodiment of the present invention is not limited thereto and may be a relatively large expansion device including a cooling fan, for example.

The expansion device 6100 includes a housing 6101, a cap 6102, a USB connector 6103, and a substrate 6104. The substrate 6104 is held in the housing 6101. The substrate 6104 is provided with a circuit for driving the memory device of one embodiment of the present invention, for example. The substrate 6104 is provided with the electronic component 700 and a controller chip 6106, for example. The USB connector 6103 functions as an interface for connection to an external device.

### [SD Card]

The memory device of one embodiment of the present invention can be used in an SD card that can be attached to an electronic device such as an information terminal or a digital camera.

FIG. 32B is a schematic external view of an SD card, and FIG. 32C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, the substrate 5113 is provided with the electronic component 700 and a controller chip 5115. Note that the circuit structures of the electronic component 700 and the controller chip 5115 are not limited to those described above, and the circuit structures may be changed as appropriate depending on circumstances. For example, a write circuit, a row driver, a read circuit, or the like provided in an electronic component may be incorporated into the controller chip 5115 instead of the electronic component 700.

When the electronic component 700 is also provided on the back surface side of the substrate 5113, the capacity of the SD card 5110 can be increased. In addition, a wireless chip with a wireless communication function may be provided on the substrate 5113. This enables wireless communication between an external device and the SD card 5110, making it possible to write and read data to/from the electronic component 700.

### [SSD]

The memory device of one embodiment of the present invention can be used in an SSD (Solid State Drive) that can be attached to an electronic device such as an information terminal.

FIG. 32D is a schematic external view of an SSD, and FIG. 32E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, the substrate 5153 is provided with the electronic component 700, a memory chip 5155, and a controller chip 5156. When the electronic component 700 is also provided on the back surface side of the substrate 5153, the capacity of the SSD 5150 can be increased. A work memory is incorporated into the memory chip 5155. For example, a DRAM chip is used as the memory chip 5155. A processor, an ECC (Error-Correcting Code) circuit, and the like are incorporated into the controller chip 5156. Note that the circuit structures of the electronic component 700, the memory chip 5155, and the controller chip 5115 are not limited to those described above, and the circuit structures may be changed as appropriate depending on circumstances. For example, a memory functioning as a work memory may also be provided in the controller chip 5156.

### [Computer]

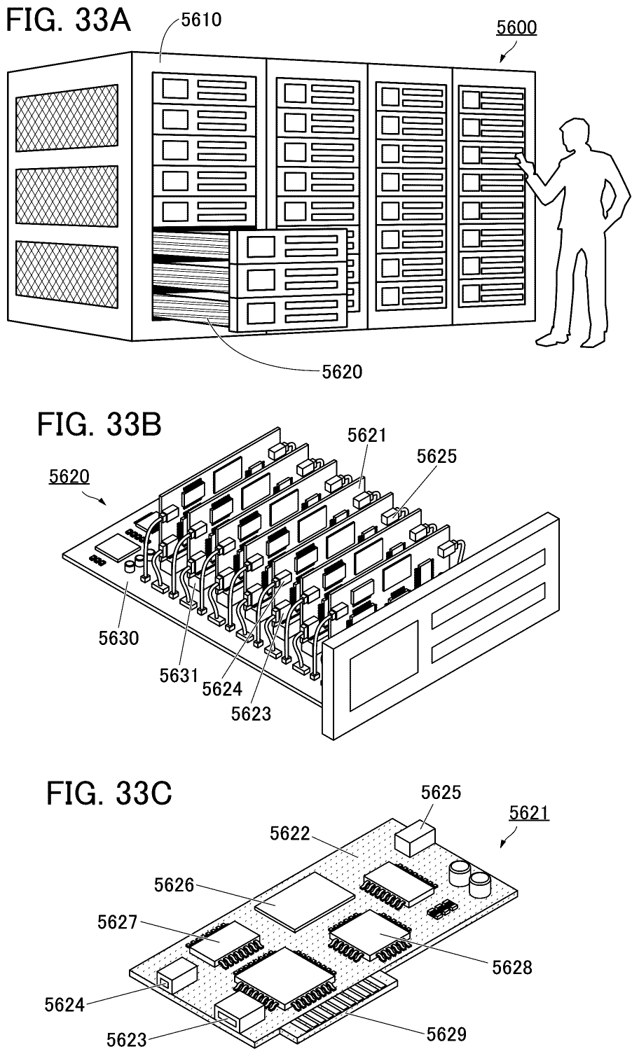

A computer 5600 illustrated in FIG. 33A is an example of a large computer. In the computer 5600, a plurality of rack mount computers 5620 are stored in a rack 5610.

The computer 5620 can have a structure in a perspective view illustrated in FIG. 33B, for example. In FIG. 33B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 33C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. FIG. 33C also illustrates semiconductor devices other than the semiconductor device 5626, the semiconductor device 5627, and the semiconductor device 5628; the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve, for example, as an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The memory device of one embodiment of the present invention is used in a variety of electronic devices and the like described above, whereby a reduction in size and a reduction in power consumption of the electronic devices can be achieved. In addition, since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention can achieve an electronic device that operates stably even in a high-temperature environment. Thus, the reliability of the electronic device can be improved.

This embodiment can be combined with the other embodiments as appropriate.

### Embodiment 6

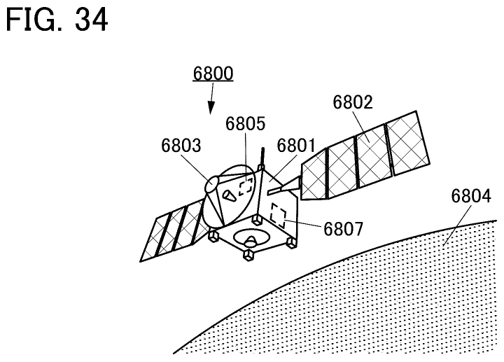

In this embodiment, specific examples of the case where the semiconductor device of one embodiment of the present invention is used in a device for space will be described with reference to FIG. 34.

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space.

FIG. 34 illustrates an artificial satellite 6800 as an example of a device for space. The artificial satellite 6800 includes a body 6801, a solar panel 6802, an antenna 6803, a secondary battery 6805, and a control device 6807. Note that in FIG. 34, a planet 6804 in outer space is illustrated as an example. Note that outer space refers to, for example, space at an altitude greater than or equal to 100 km, and outer space described in this specification may include one or more of thermosphere, mesosphere, and stratosphere.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, meson beams, and the like.

When the solar panel 6802 is irradiated with sunlight, electric power required for the operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, the present invention is not limited thereto. The semiconductor device of one embodiment of the present invention can be suitably used for a device for space such as a spacecraft, a space capsule, or a space probe, for example.

### Embodiment 7

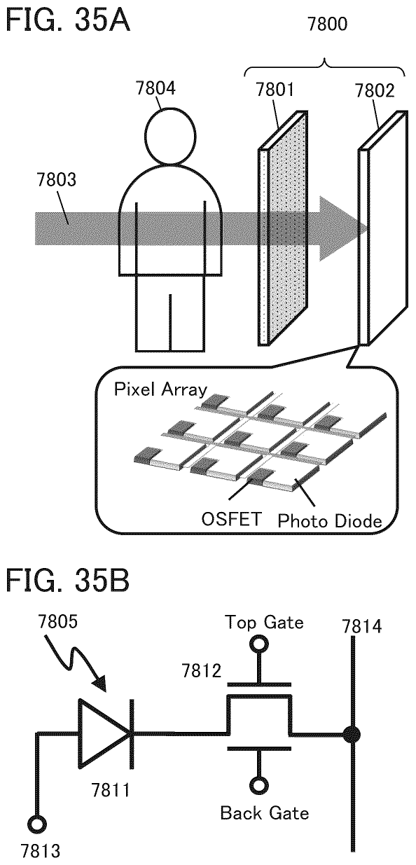

In this embodiment, a specific example of a case where the semiconductor device of one embodiment of the present invention is applied to medical equipment is described with reference to FIG. 35A and FIG. 35B.

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used for medical equipment, specifically, radiology.

FIG. 35A illustrates a state where an X-ray image of a subject 7804 is captured by an image capturing device 7800. The image capturing device 7800 includes a scintillator 7801 and an image sensor 7802. The scintillator 7801 has a function of converting radiation such as X-rays or gamma rays into visible light. The image sensor 7802 detects X-rays and thus can also be referred to as an X-ray image sensor.

An X-ray 7803 emitted from an X-ray source (not illustrated) passes through the subject 7804 such as a patient and enters the image capturing device 7800. When the X-ray 7803 enters the scintillator 7801, visible light is emitted. The visible light is received by the image sensor 7802, so that an X-ray image is captured.

The image sensor 7802 includes a pixel array, and the pixel array includes a plurality of pixels arranged in a matrix of rows and columns. Each of the plurality of pixels includes an OS transistor (OSFET) and a photodiode.

FIG. 35B is a circuit diagram of the pixel included in the image sensor 7802. As illustrated in FIG. 35B, the pixel included in the image sensor 7802 includes a photodiode 7811 and a transistor 7812. An anode of the photodiode 7811 is electrically connected to a terminal 7813, a cathode of the photodiode 7811 is electrically connected to one of a source and a drain of the transistor 7812, and the other of the source and the drain of the transistor 7812 is electrically connected to a wiring 7814. The transistor 7812 includes a gate (Top Gate) and a back gate (Back Gate).

The photodiode 7811 is an optical sensor element and performs an operation of generating current corresponding to light 7805 incident on the pixel. The transistor 7812 performs an operation of outputting, to the wiring 7814, current corresponding to the amount of the light 7805 received by the photodiode 7811. Note that the light 7805 is visible light emitted when the X-ray 7803 enters the scintillator 7801. Alternatively, the light 7805 may be the X-ray 7803.

An OS transistor has an extremely low off-state current and is highly resistant to radiation. Thus, an OS transistor can be suitably used as the transistor 7812.

### Example 1

In this example, changes in electrical characteristics of OS transistors with respect to X-ray irradiation were evaluated. Specifically, the OS transistors described in Embodiment 1 with reference to FIG. 7B were fabricated, and the OS transistors were subjected to an X-ray irradiation test. For comparison, the OS transistors were subjected to a +GBT (Gate Bias-Temperature) stress test.

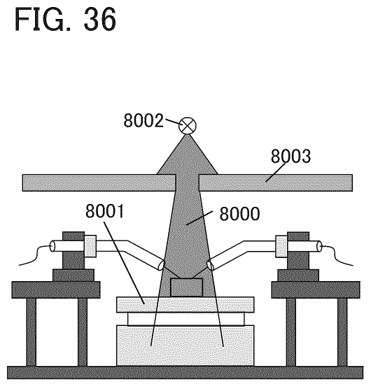

Evaluation surroundings of the X-ray irradiation test used in this example are shown in FIG. 36. An elevating table was provided in a chamber where irradiation with X-rays 8000 was performed, and probes and a stage 8001 were set over the elevating table. Note that a diaphragm plate 8003 was located between an X-ray source 8002 and the stage 8001. The diaphragm plate 8003 makes it possible to block a recoil X-ray. In addition, it is possible to reduce X-ray irradiation on coaxial arms of the probes, inhibiting irregular current from flowing in the probes. An irradiation dose rate was measured with Accu-Dose radiation measurement system 2186 by Radcal Corporation. For evaluation of the electrical characteristics of the OS transistors, the 4156C by Keysight Technologies, Inc. was used.

As an X-ray irradiation apparatus used for the X-ray irradiation test, MX-160Labo produced by mediXtec Corporation was used. The X-ray source is tungsten, the tube voltage range is higher than or equal to 30 kV and lower than or equal to 160 kV, and the tube current range is higher than or equal to 0.3 mA and lower than or equal to 3.0 mA.

Samples were subjected to the X-ray irradiation test under different conditions so that changes in electrical characteristics of the OS transistors with respect to X-ray irradiation were evaluated. As the samples, a first OS transistor group, a second OS transistor group, and a third transistor group were prepared. The first OS transistor group includes an OS transistor 901 to an OS transistor 907. The second OS transistor group includes an OS transistor 911 to an OS transistor 915, an OS transistor 916-1, an OS transistor 916-2, an OS transistor 917, an OS transistor 918-1, an OS transistor 918-2, and an OS transistor 919. The third OS transistor group includes an OS transistor 921 to an OS transistor 931. Note that the designed channel length and channel width values of each of the OS transistors included in the first OS transistor group were set to 200 nm and 60 nm, respectively. The designed channel length and channel width values of each of the OS transistors included in the second OS transistor group and the third OS transistor group were set to 60 nm and 60 nm, respectively.

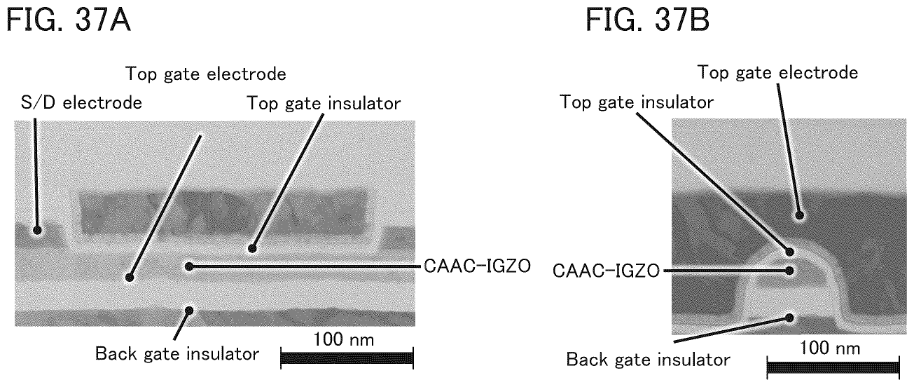

Cross-sectional STEM images of the fabricated samples were taken with “HD-2700” produced by Hitachi High-Tech Corporation. FIG. 37A shows a cross-sectional STEM image of the OS transistor 901 in the channel length direction, and FIG. 37B shows a cross-sectional STEM image of the OS transistor 901 in the channel width direction. Note that in FIG. 37A and FIG. 37B, Back gate insulatore is a back gate insulating film, CAAC-IGZO is a metal oxide, S/D electrode is a source electrode or a drain electrode, Top gate electrode is a top gate electrode, and Top gate insulator is a top gate insulating film.

The length of each component was measured on the basis of the observation result of the cross-sectional STEM image in FIG. 37A. According to results of the length measurement using FIG. 37A, the gate length of the OS transistor 901 in the channel length direction was 218 nm. The EOT of the top gate insulating film (the insulator 250) was 5.9 nm, and the EOT of the back gate insulating film (the insulator 222 and the insulator 224) was 24.6 nm.

As illustrated in FIG. 37B, the metal oxide 230 included in the OS transistor 901 is separated for each element. In addition, the upper portion and side surface of a channel formation region included in the metal oxide 230 are surrounded by the conductor 260 functioning as the top gate electrode. That is, the OS transistor 901 is a TRI-GATE type (TRI-gate type) transistor. Furthermore, the conductor 205, which functions as a back gate electrode, and the insulator 222 and the insulator 224, which function as the back gate insulating film, are provided below the channel formation region included in the metal oxide 230. Thus, it can be said that the OS transistor 901 has a transistor structure in which a Fin-type structure and SOI are combined.

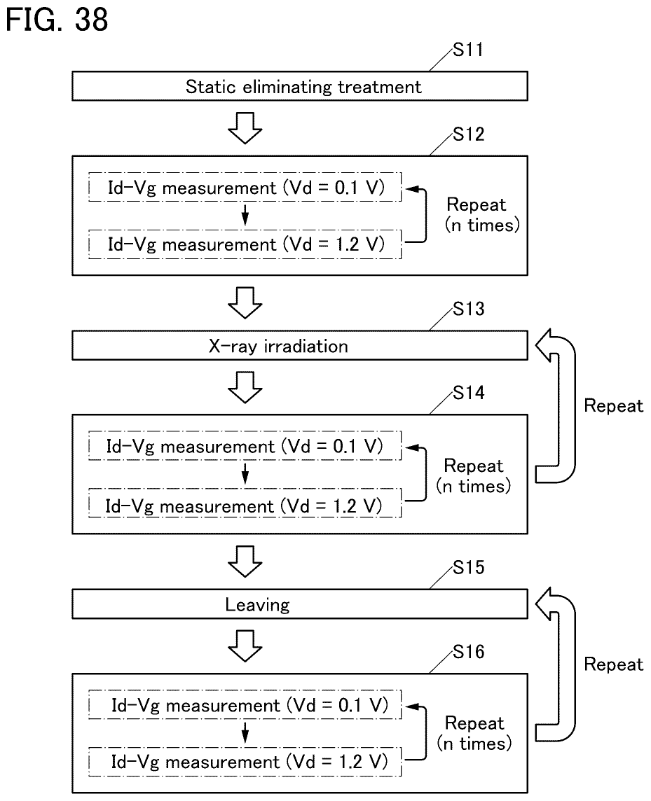

First of all, the procedure of the X-ray irradiation test is described. FIG. 38 shows a flow chart of the X-ray irradiation test.

First, the substrate was set in the X-ray irradiation apparatus and subjected to static eliminating treatment with an ionizer for five minutes (Step S11 in FIG. 38).

Next, Id-Vg measurements of the OS transistors were performed before X-ray irradiation (Step S12 in FIG. 38). As common conditions for the Id-Vg measurements of the samples, the source voltage Vs and the back gate voltage Vbg were each set to 0 V and the substrate temperature during the Id-Vg measurement was set to room temperature.

For the OS transistor 901, while the drain voltage Vd was set to 0.1 V, the drain current Id was measured with the gate voltage Vg swept from Vg_min to Vg_max. Then, while the drain voltage Vd was set to 1.2 V, the drain current Id was measured with the gate voltage Vg swept from Vg_min to Vg_max. The measurement at a drain voltage Vd of 0.1 V and the measurement at 1.2 V were repeated alternately to perform five measurements in total. Note that sweeping the gate voltage Vg from Vg_min to Vg_max is referred to as single sweep.

For the OS transistors other than the OS transistor 901, while the drain voltage Vd was set to 0.1 V, the drain current Id was measured with the gate voltage Vg swept from Vg_min to Vg_max and then swept from Vg_max to Vg_min. Then, while the drain voltage Vd was set to 1.2 V, the drain current Id was measured with the gate voltage Vg swept from Vg_min to Vg_max and then swept from Vg_max to Vg_min. The measurement at a drain voltage Vd of 0.1 V and the measurement at 1.2 V were repeated alternately to perform n sets of measurements in total (n times of measurements at a drain voltage Vd of 0.1 V and n times of measurements at 1.2 V). Note that sweeping the gate voltage Vg from Vg_min to Vg_max and then from Vg_max to Vg_min is referred to as double sweep.

Next, after probing was performed in the X-ray irradiation apparatus, the first OS transistor group and the second OS transistor group were irradiated with X-rays (Step S13 in FIG. 38). At the time of the X-ray irradiation, different voltages were applied to the terminals (source, drain, gate, and back gate) of the OS transistors. The X-ray exposure dose was set to 100 Gy, and the X-ray dose rate was set to 35.0 Gy/hr.

Next, Id-Vg measurements of the OS transistors included in the first OS transistor group and the OS transistors included in the second OS transistor group were performed (Step S14 in FIG. 38). The conditions for the Id-Vg measurements were the same as those for the Id-Vg measurements before the X-ray irradiation (Step S12 in FIG. 38).

For each of the OS transistors included in the first OS transistor group and the OS transistors included in the second OS transistor group, the X-ray irradiation (Step S13 in FIG. 38) and the Id-Vg measurement (Step S14 in FIG. 38) described above were repeated until the total X-ray exposure dose reached 3000 Gy. Note that an X-ray exposure dose of 3000 Gy is equivalent to the dose of radiation to which an object on a geostationary orbit is exposed for 30 years.

The third OS transistor group was not subjected to Step S13 and Step S14 in FIG. 38.

Next, the OS transistors were left in the X-ray irradiation apparatus at room temperature while probing was performed (Step S15 in FIG. 38). Different potentials were applied to the terminals (source, drain, gate, and back gate) of the OS transistors when they were left. Note that when the potential applied to a terminal is 0 V, the potential can be rephrased as the ground potential GND in some cases.

Next, Id-Vg measurements of the OS transistors were performed (Step S16 in FIG. 38). The conditions for the Id-Vg measurements were the same as those for the Id-Vg measurements before the X-ray irradiation (Step S12 in FIG. 38). Leaving the OS transistors left at room temperature (Step S15 in FIG. 38) and the Id-Vg measurement (Step S16 in FIG. 38) were repeated.

As described above, the third OS transistor group was not subjected to Step S13 and Step S14 in FIG. 38. This means that the third OS transistor group was subjected to a +GBT stress test in which the same voltage was continuously applied without X-ray irradiation.

The above is the description of the procedure of the X-ray irradiation test. Table 1 shows the designed values of the OS transistors, the conditions for the Id-Vg measurements, and the conditions of voltages that were applied to the terminals of the OS transistors when they were irradiated with X-rays or left at room temperature.

TABLE 1

| | Designed | | | | | | | | X-ray irradiation | | | |
|---|---|---|---|---|---|---|---|---|---|---|---|---|
| | value | Id-Vg measurement | | | | | | X-ray | or leaving | | | |
| | L | Vg_min | | Vg_max | | Sweep | n | irradiation | Vg | | Vbg | |
| 901 | 200 nm | −4 | V | +4 | V | single | 5 | Yes | 0 | V | 0 | V |
| 902 | 200 nm | 0 | V | +4 | V | double | 5 | Yes | 0 | V | 0 | V |
| 903 | 200 nm | 0 | V | +3 | V | double | 5 | Yes | 0 | V | 0 | V |
| 904 | 200 nm | −4 | V | +3 | V | double | 5 | Yes | 0 | V | 0 | V |
| 905 | 200 nm | −1 | V | +1 | V | double | 5 | Yes | 0 | V | 0 | V |
| 906 | 200 nm | −1 | V | +1 | V | double | 2 | Yes | 0 | V | 0 | V |
| 907 | 200 nm | −1 | V | +1 | V | double | 2 | Yes | −0.8 | V | −6 | V |
| 911 | 60 nm | −1 | V | +1 | V | double | 2 | Yes | 0 | V | 0 | V |
| 912 | 60 nm | −1 | V | +1 | V | double | 2 | Yes | −0.8 | V | −6 | V |
| 913 | 60 nm | −1 | V | +1 | V | double | 2 | Yes | +1 | V | 0 | V |
| 914 | 60 nm | −1 | V | +1 | V | double | 2 | Yes | +2 | V | 0 | V |
| 915 | 60 nm | −1 | V | +1 | V | double | 2 | Yes | +3 | V | 0 | V |
| 916-1 | 60 nm | −1 | V | +1 | V | double | 2 | Yes | −1 | V | 0 | V |
| 916-2 | 60 nm | −1 | V | +1 | V | double | 2 | Yes | −1 | V | 0 | V |
| 919 | 60 nm | −1 | V | +1 | V | double | 2 | Yes | −2 | V | 0 | V |
| 917 | 60 nm | −1 | V | +1 | V | double | 2 | Yes | 0 | V | +4.15 | V |
| 918-1 | 60 nm | −1 | V | +1 | V | double | 2 | Yes | 0 | V | −4.15 | V |
| 918-2 | 60 nm | −1 | V | +1 | V | double | 2 | Yes | 0 | V | −4.15 | V |
| 921 | 60 nm | −1 | V | +1 | V | double | 2 | No | +1 | V | 0 | V |
| 922 | 60 nm | −1 | V | +1 | V | double | 2 | No | +2 | V | 0 | V |
| 923 | 60 nm | −1 | V | +1 | V | double | 2 | No | +3 | V | 0 | V |
| 924 | 60 nm | −1 | V | +1 | V | double | 2 | No | +3 | V | 0 | V |
| 926 | 60 nm | −1 | V | +1 | V | double | 2 | No | 0 | V | 0 | V |
| 927 | 60 nm | −1 | V | +1 | V | double | 2 | No | −1 | V | 0 | V |
| 928 | 60 nm | −1 | V | +1 | V | double | 2 | No | −2 | V | 0 | V |
| 925 | 60 nm | −1 | V | +1 | V | double | 2 | No | 0 | V | +4.15 | V |
| 929 | 60 nm | −1 | V | +1 | V | double | 2 | No | 0 | V | +8.3 | V |
| 930 | 60 nm | −1 | V | +1 | V | double | 2 | No | 0 | V | −4.15 | V |
| 931 | 60 nm | −1 | V | +1 | V | double | 2 | No | 0 | V | −8.3 | V |

The threshold voltages (Vth) of the OS transistors were calculated from the measured Id-Vg characteristics by a constant current method. In this example, a gate voltage Vg at which a current of 1 pA flows was regarded as a threshold voltage (Vth).

First, measurement results of drain current-gate voltage characteristics of the OS transistor 903 before X-ray irradiation are described.

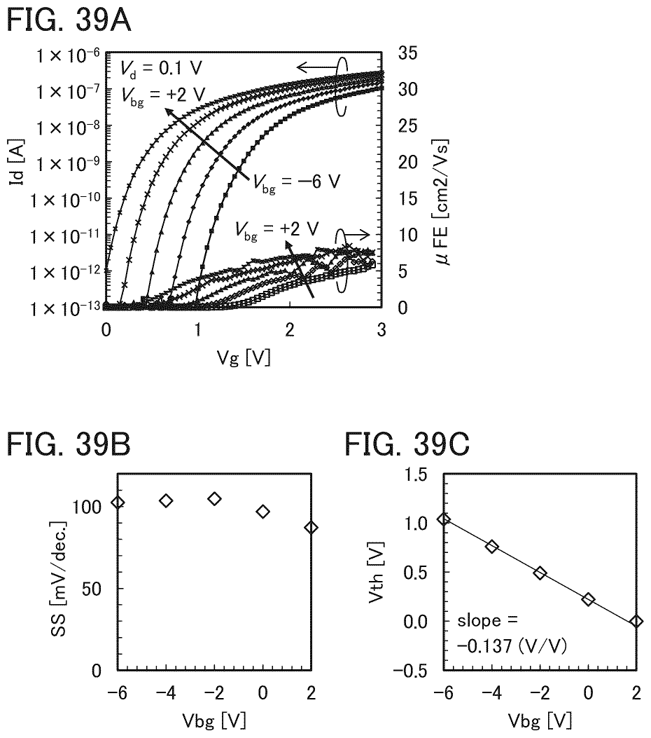

FIG. 39A shows drain current (denoted by “Id” in the graph)-gate voltage (denoted by “Vg” in the graph) characteristics of the OS transistor 903.

The Id-Vg characteristics shown in FIG. 39A are the results of measurements where the back gate voltage Vbg with respect to the source was changed from +2 V to −6 V in increments of 2 V while the drain voltage with respect to the source was 0.1 V, the source voltage was 0 V, and the temperature of the measurement environment was 27° C. In FIG. 39A, the horizontal axis represents gate voltage Vg [V], the first vertical axis (left vertical axis) represents drain current Id [A], and the second vertical axis (right vertical axis) represents the field-effect mobility μ_{FE} [cm²/Vs].

The threshold voltage (Vth) and subthreshold swing value (SS) of the OS transistor 903 were calculated from the measured Id-Vg characteristics of the OS transistor 903. Note that the threshold voltage was calculated by a constant current method. Here, the constant current method is a method in which, from the results of Id-Vg characteristics, the gate voltage in the case where a constant current (here, 1 pA) flows is regarded as the threshold voltage. In addition, the SS refers to the amount of change in gate voltage in the subthreshold region, which makes the drain current change by one digit at a constant drain voltage.

FIG. 39B shows the back gate voltage dependence of the SS, and FIG. 39C shows the back gate voltage dependence of the threshold voltage. In each of FIG. 39B and FIG. 39C, the horizontal axis represents back gate voltage Vbg [V]. The vertical axis in FIG. 39B represents SS [mV/dec.], and the vertical axis in FIG. 39C represents Vth [V].

It is verified from FIG. 39A to FIG. 39C that the Id-Vg characteristics move parallel in the horizontal axis direction at substantially equal intervals with respect to the back gate voltage Vbg. Furthermore, the outlines of the mobility curves and the SS show almost no change with respect to the back gate voltage Vbg. As shown in FIG. 39C, the proportion (slope) of the change in the threshold voltage Vth with respect to the back gate voltage Vbg is −0.137 V/V. These indicate that the threshold voltage Vth of the OS transistor can be controlled by application of the back gate voltage Vbg without a significant influence on the driving force of the device.

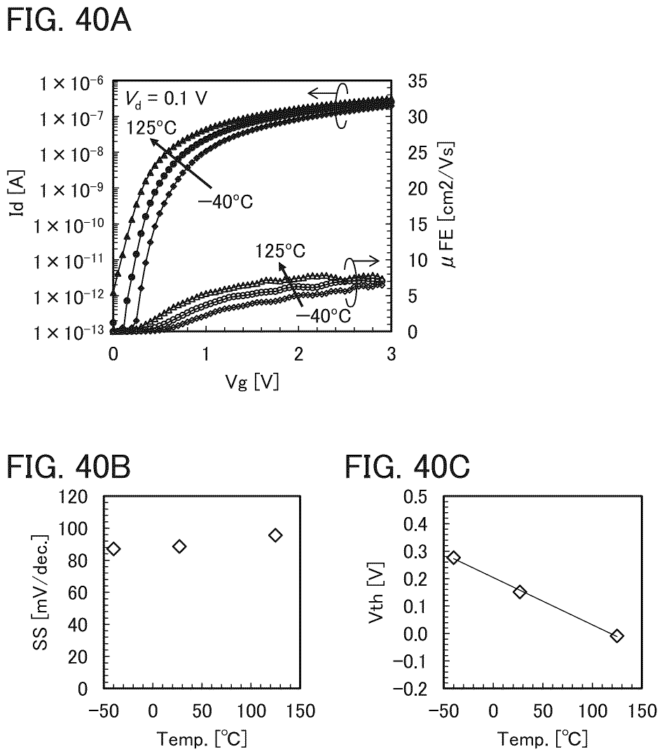

FIG. 40A shows drain current (denoted by “Id” in the diagram)-gate voltage (denoted by “Vg” in the diagram) characteristics of the OS transistor 903.

The Id-Vg characteristics shown in FIG. 40A are the results of measurements where the temperature of the measurement environment was set to 125° C., 27° C., or −40° C. while the drain voltage with respect to the source was 0.1 V and the source voltage and the back gate voltage were each 0 V. In FIG. 40A, the horizontal axis represents gate voltage Vg [V], the first vertical axis (on the left) represents drain current Id [A], and the second vertical axis (on the right) represents field-effect mobility μ_{FE} [cm²/Vs]. In FIG. 40A, black triangles represent drain current Id [A] at 125° C.; black circles, drain current Id [A] at 27° C.; black squares, drain current Id [A] at −40° C.; white triangles, field-effect mobility μ_{FE} [cm²/Vs] at 125° C.; white circles, field-effect mobility μ_{FE} [cm²/Vs] at 27° C.; and white squares, field-effect mobility μ_{FE} [cm²/Vs] at −40° C.

The threshold voltage (Vth) and subthreshold swing value (SS) of the OS transistor 903 were calculated from the measured Id-Vg characteristics of the OS transistor 903. FIG. 40B shows the temperature dependence of the SS and FIG. 40C shows the temperature dependence of the threshold voltage. In each of FIG. 40B and FIG. 40C, the horizontal axis represents temperature of the measurement environment (Temp.) [° C.]. The vertical axis in FIG. 40B represents SS [mV/dec.], and the vertical axis in FIG. 40C represents Vth [V].

As shown in FIG. 40A to FIG. 40C, a shift of Vth in the negative direction with increased temperature is observed. Furthermore, an increase in SS and an increase in field-effect mobility with increased temperature are also observed. Specifically, the amounts of changes due to the temperature change from −40° C. to 125° C. are as follows: the threshold voltage Vth is changed by −0.28 V (−1.7 mV/° C.); the field-effect mobility μ_{FE} is changed by +23% (+8.5× 10⁻³ cm²/Vs/° C.); and the SS is changed by +10% (+53 μV/dec./° C.).

The amounts of changes in Vth, SS, and μ_{FE}, however, are small, which reveals that the OS transistor is relatively stable with respect to the temperature change. In particular, the SS shows almost no change due to the temperature change.

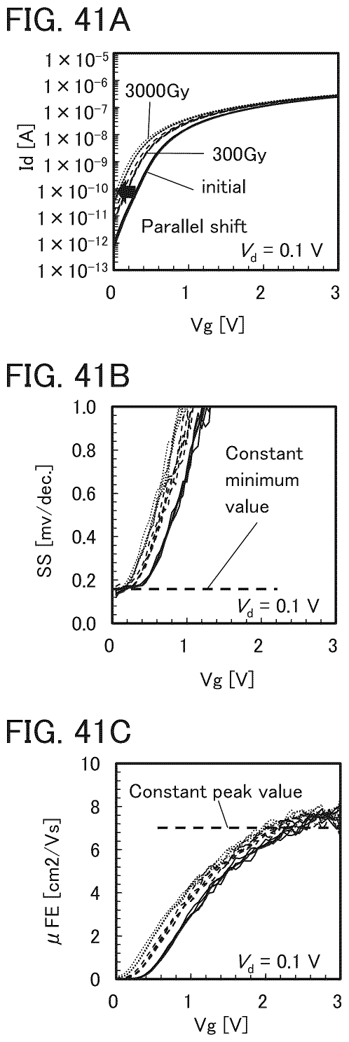

FIG. 41A shows the Id-Vg characteristics of the OS transistor 903 before X-ray irradiation, the Id-Vg characteristics at the time when the total X-ray exposure dose became 300 Gy, and the Id-Vg characteristics at the time when the total X-ray exposure dose became 3000 Gy.

The Id-Vg characteristics shown in FIG. 41A were obtained as follows: the drain voltage with respect to the source was 0.1 V, the source voltage and the back gate voltage were each 0 V, and the temperature of the measurement environment was 25° C. In FIG. 41A, the horizontal axis represents gate voltage Vg [V] and the vertical axis represents drain current Id [A].

The field-effect mobility (μ_{FE}) and subthreshold swing value (SS) of the OS transistor 903 were calculated from the measured Id-Vg characteristics of the OS transistors 903. FIG. 41B shows the total X-ray dose dependence of the SS, and FIG. 41C shows the total X-ray dose dependence of the field-effect mobility. In each of FIG. 41B and FIG. 41C, the horizontal axis represents gate voltage Vg [V]. The vertical axis in FIG. 41B represents SS [mV/dec.], and the vertical axis in FIG. 41C represents μ_{FE} [cm²/Vs].

It is verified from FIG. 41A that, with increased total X-ray dose, parallel movement of the Id-Vg characteristics in the negative direction (Parallel shift) is observed. By contrast, as shown in FIG. 41B and FIG. 41C, the minimum value (Constant minimum value) of the SS curves and the peak value (Constant peak value) of the μ_{FE} curves hardly change even with increased total X-ray dose.

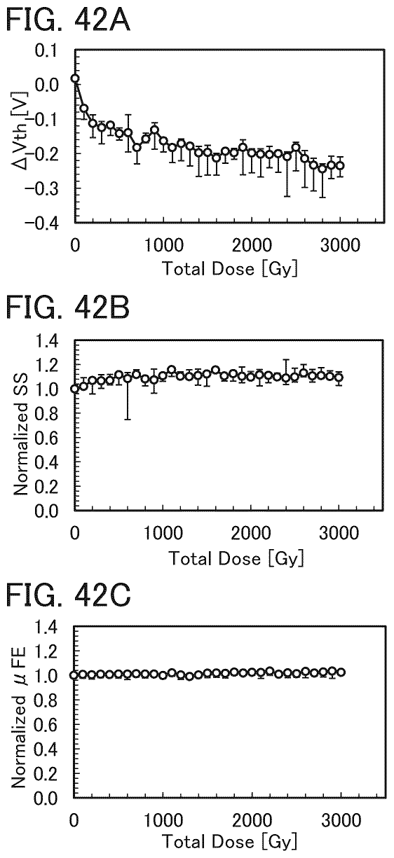

FIG. 42A to FIG. 42C show changes in the Vth, SS, and μ_{FE} of the OS transistor 903.

FIG. 42A shows a plot of the amount of change in threshold voltage (ΔVth). In FIG. 42A, the horizontal axis represents total X-ray dose (Total Dose) [Gy], and the vertical axis represents ΔVth [V]. The plot in FIG. 42A shows the median value of ΔVth obtained by five Id-Vg measurements, and error bars each show the maximum value and the minimum value.

FIG. 42B shows a plot of normalized SS. In FIG. 42B, the horizontal axis represents total X-ray dose (Total Dose) [Gy], and the vertical axis represents normalized SS (Normalized SS). The plot in FIG. 42B shows the median value of the normalized SS obtained by five Id-Vg measurements, and error bars each show the maximum value and the minimum value.

FIG. 42C shows a plot of normalized μ_{FE}. In FIG. 42C, the horizontal axis represents total X-ray dose (Total Dose) [Gy], and the vertical axis represents normalized μ_{FE} (Normalized μ_{FE}). The plot in FIG. 42C shows the median value of the normalized u FE obtained by five Id-Vg measurements and error bars each show the maximum value and the minimum value.

FIG. 42A demonstrates that the threshold voltage Vth shifts in the negative direction by TID. In addition, FIG. 42A demonstrates that a change in threshold voltage is slowing down at a total dose of 300 Gy or more. The amount of change in threshold voltage ΔVth was 300 m V when the total dose was 3000 Gy. By contrast, as shown in FIG. 42B and FIG. 42C, the subthreshold slop SS and the field-effect mobility μFE exhibited no or an extremely small change with respect to the total dose.

The above results suggest that accumulation of fixed electric charge occurs by TID but deterioration affecting the driving force of the device, such as generation of impurity states at an interface, does not occur in the OS transistor.

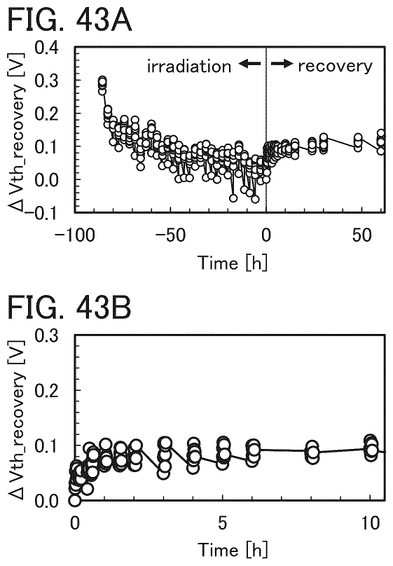

FIG. 43A shows the data at the first time to the data at the fifth time concerning a change in threshold voltage of the OS transistor 903 together.

In FIG. 43A, the horizontal axis represents time (Time) [h], and the vertical axis represents the amount of change in threshold voltage (ΔVth_recovery) [V]. In FIG. 43A, the time (Time) represents a relative time with the end of the last X-ray irradiation set to 0. The negative values mean a period in which X-ray irradiation and an Id-Vg measurement were repeated (irradiation); and the positive values mean a period in which leaving at room temperature and an Id-Vg measurement were repeated after the end of X-ray irradiation (recovery). In addition, the vertical axis is adjusted such that ΔVth in the Id-Vg measurement at the end of the last X-ray irradiation (at a point with 0 in the horizontal axis) is 0.

FIG. 43B shows the results of the period in which leaving at room temperature and an Id-Vg measurement were repeated after the end of X-ray irradiation, among the results shown in FIG. 43A.

As shown in FIG. 43A, the Vth change observed at the time of X-ray irradiation and that at the time of leaving after the X-ray irradiation occur in the opposite directions. Specifically, after TID shifts Vth in the negative direction, leaving at room temperature shifts Vth in the positive direction. That is, it is presumed that degradation due to the TID (also referred to as TID degradation) is recovered. Furthermore, FIG. 43B shows that the recovery speed is high and saturation occurs after approximately-five-hour leaving. In the end, approximately 40% of the degradation due to TID was recovered after 60-hour leaving at room temperature.

In this example, the time constant of the recovery is estimated to be smaller than 5 hours whereas the 3000 Gy X-ray irradiation took approximately 90 hours. Since the time constant of the recovery is thus small with respect to the irradiation time, the degradation in this example might be estimated to be smaller than the net TID degradation. Meanwhile, a recovery component presumably has a greater influence in the actual use environment with a much lower radiation dose rate. Hence, the OS transistor is expected to cause a negative drift with a smaller magnitude in the actual use environment than in an acceleration test result as in this example, and to be highly reliable even in a radiation environment.

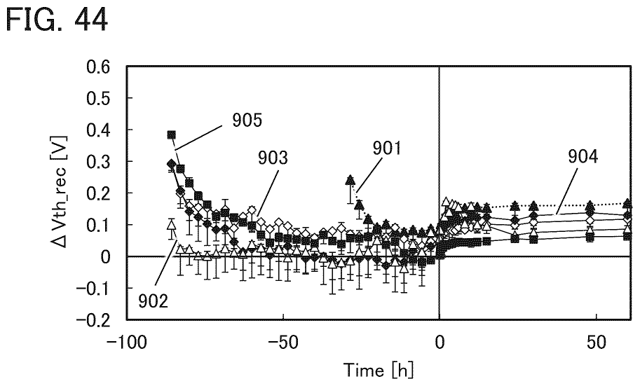

FIG. 44 shows the amounts of changes in threshold voltages of the OS transistors at a drain voltage Vd of 0.1 V. In FIG. 44, the horizontal axis represents time (Time) [h], and the vertical axis represents the amount of change in threshold voltage (ΔVth_rec) [V]. In FIG. 44, the time (Time) represents a relative time with the end of the last X-ray irradiation set to 0. The negative values mean a period in which X-ray irradiation and an Id-Vg measurement were repeated; and the positive values mean a period in which leaving at room temperature and an Id-Vg measurement were repeated after the end of X-ray irradiation. The amount of change in threshold voltage (ΔVth_rec) shown in FIG. 44 represents a relative threshold voltage with the minimum value of the threshold voltages, which was calculated from the Id-Vg characteristics measured five times at the end of the last X-ray irradiation, set to 0. Plots in FIG. 44 show the median value of the threshold voltages obtained by five Id-Vg measurements, and error bars each show the maximum value and the minimum value.

FIG. 44 shows the results of the OS transistor 901 to the OS transistor 905. Note that conditions (Vg_min, Vg_max, and a sweep method) for the Id-Vg measurements differ between the OS transistor 901 to the OS transistor 905.

As shown in FIG. 44, the Vth change observed at the time of X-ray irradiation and that at the time of leaving after the X-ray irradiation occur in the opposite directions. Specifically, according to the observation, X-ray irradiation shifts Vth in the negative direction. This is presumed to be caused by TID. Note that TID indicates degradation of a semiconductor element due to accumulation of cosmic rays or radiation. According to the observation, leaving after the X-ray irradiation shifts Vth in the positive direction. It is thus found that leaving after the X-ray irradiation recovers the degradation due to TID (the shift of Vth in the negative direction).

As can be seen from FIG. 44, the lower the upper limit (Vg_max) of the sweep range of the gate voltage is, the larger the amount of TID degradation is and the smaller the amount of recovery is. In other words, the higher Vg_max is, the larger the amount of recovery is. Thus, it is found that the absolute values (the upper limit and lower limit of the sweep range) of the gate voltage Vg are preferably small for observation of only the TID degradation as much as possible. It is found that, specifically, the gate voltage Vg is preferably set in the range of −1 V to +1 V to perform Id-Vg measurements.

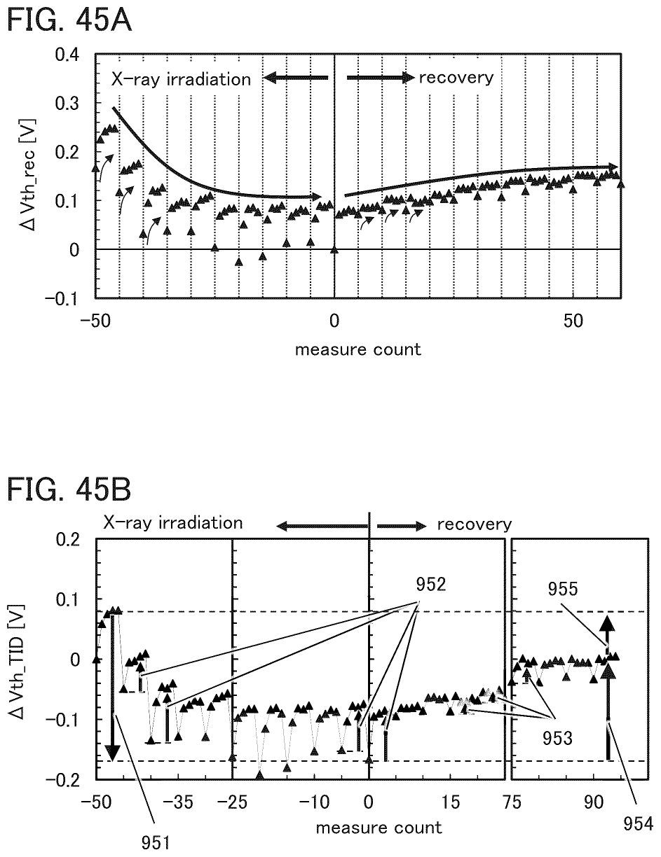

FIG. 45A is a graph where the horizontal axis of FIG. 44 is converted into the number of Id-Vg measurements. In FIG. 45A, the horizontal axis represents the number of Id-Vg measurements (measure count), and the vertical axis represents the amount of change in threshold voltage (ΔVth_rec) [V]. The number of Id-Vg measurements (measure count) represents a relative number of times with the first Id-Vg measurement after the end of X-ray irradiation (the first-time Id-Vg measurement in Step S16 in FIG. 38) set to 0. The negative values mean a period in which X-ray irradiation and an Id-Vg measurement were repeated; and the positive values mean a period in which leaving at room temperature and an Id-Vg measurement were repeated after the end of X-ray irradiation. Note that the amount of change in the threshold voltage of only the OS transistor 901 is plotted in FIG. 45A.

As shown in FIG. 45A, long-term changes in characteristics and periodic changes in characteristics are observed. As the long-term changes in characteristics, saturation of the amount of TID degradation due to an increase in the amount of X-ray irradiation and long-term recovery of TID degradation due to leaving after the X-ray irradiation are observed. As the periodic changes in characteristics, a Vth shift in the negative direction in the first Id-Vg measurement and Vth shifts in the positive direction in the second to fifth Id-Vg measurement were observed both at the time of the time of X-ray irradiation and at the time of leaving after the X-ray irradiation.

FIG. 45B is a graph in which the reference threshold voltage of the vertical axis in FIG. 45A is modified and the range represented by the horizontal axis is modified. In FIG. 45B, the horizontal axis represents the number of Id-Vg measurements (measure count), and the vertical axis represents the amount of change in threshold voltage (ΔVth_TID) [V]. The amount of change in threshold voltage (ΔVth_TID) shown in FIG. 45B represents a relative threshold voltage with the threshold voltage, which was obtained by the Id-Vg measurement at the time when the number of Id-Vg measurements (measure count) is −50, set to 0.

As shown in FIG. 45B, the change in electrical characteristics of the OS transistor with respect to X-ray irradiation (change due to TID degradation) is divided into four components. A first component is slow recovery and obtained by subtracting a change 952 from a change 954 in FIG. 45B. A second component is initial recovery and obtained by subtracting a change 953 from the change 952 in FIG. 45B. A third component is scan degradation, which is the change 953 in FIG. 45B. A fourth component is non-recoverable TID degradation, which is a change 955 or obtained by subtracting the change 954 from a change 951. In other words, the change 951 is the TID degradation; the change 952 is the sum of the initial recovery and the scan degradation; the change 953 is the scan degradation; the change 954 is the sum of the initial recovery, the slow recovery, and the scan degradation; and the change 955 is the non-recoverable TID degradation.

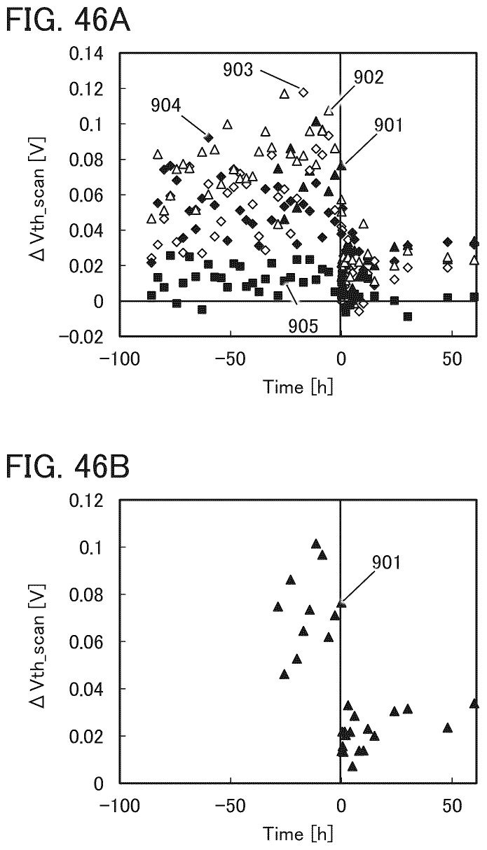

FIG. 46A and FIG. 46B each show a graph in which the vertical axis in FIG. 44 is modified to represent the amount of change in threshold voltage related to the scan degradation (ΔVth_scan). In each of FIG. 46A and FIG. 46B, the horizontal axis represents time (Time) [h] and the vertical axis represents the amount of change in threshold voltage (ΔVth_scan) [V] related to the scan degradation. The amount of change in threshold voltage (ΔVth_scan) related to the scan degradation shown in each of FIG. 46A and FIG. 46B is a value obtained by subtracting the threshold voltage obtained in the first Id-Vg measurement from median value of the threshold voltages obtained in the five Id-Vg measurements. In each of FIG. 46A and FIG. 46B, ΔVth_scan at a time less than or equal to 0 corresponds to the above-described change 952, and ΔVth_scan at a time of a positive value corresponds to the above-described change 953. Note that FIG. 46A shows the results of the OS transistor 901 to the OS transistor 905, and FIG. 46B shows the results of the OS transistor 901.

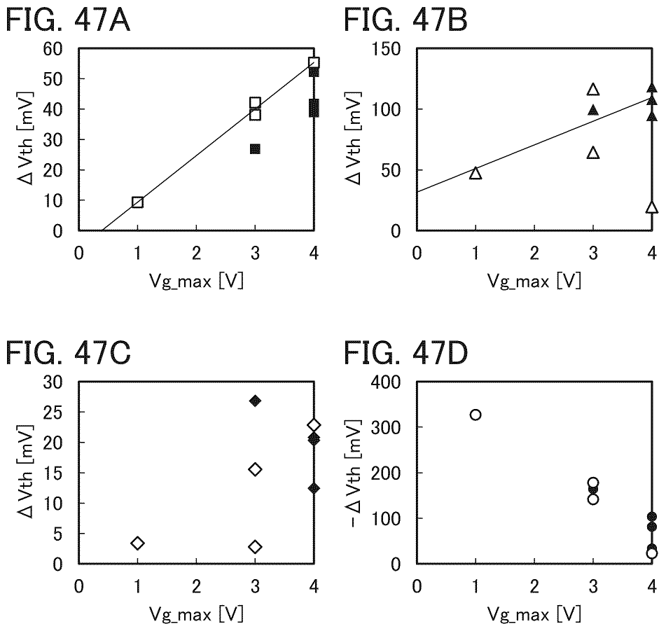

FIG. 47A to FIG. 47D show the gate voltage dependence of the components. In each of FIG. 47A to FIG. 47D, the horizontal axis represents the upper limit (Vg_max) [V] of the sweep range of the gate voltage and the vertical axis represents the amount of change in threshold voltage (ΔVth) [mV]. White marks shown in FIG. 47A to FIG. 47D represent the results obtained with the lower limit (Vg_min) of the sweep range of the gate voltage set to 0 V or −1 V, and black marks shown in FIG. 47A to FIG. 47D represent the results obtained with Vg_min set to −4 V.

FIG. 47A shows the results of the initial recovery obtained by subtracting the average value of the changes 953 from the average value of the changes 952. FIG. 47B shows the results of the slow recovery obtained by subtracting the average value of the changes 952 from the value of the change 954. FIG. 47C shows the results of the scan degradation each of which is the average value of the changes 953. FIG. 47D shows the non-recoverable TID degradation obtained by subtracting the value of the change 954 from the value of the change 951.

As observed from FIG. 47A, a linear increase tendency with respect to the positive gate voltage Vg is observed in the initial recovery. In addition, the presence of a positive gate voltage Vg at which ΔVth becomes 0 is indicated. As observed from FIG. 47B, the slow recovery tends to increase linearly with respect to the positive gate voltage Vg. In addition, the presence of a component that is recovered even without application of the positive gate voltage Vg is indicated. As shown in FIG. 47C, the scan degradation greatly varies among the samples and may have no influence on the X-ray test. As observed from FIG. 47D, the non-recoverable TID degradation tends to linearly decrease with respect to the positive gate voltage Vg. Furthermore, the dependence on the negative gate voltage Vg is not observed.

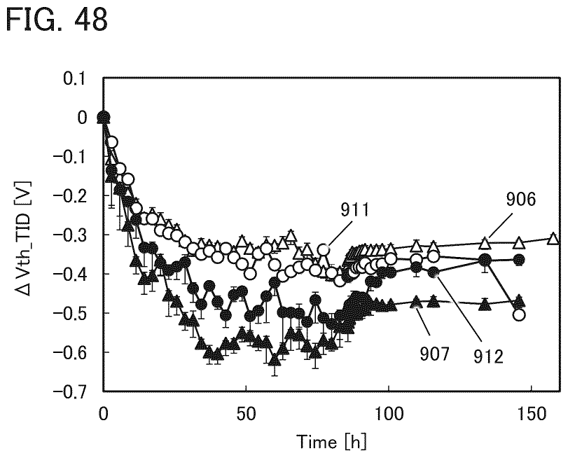

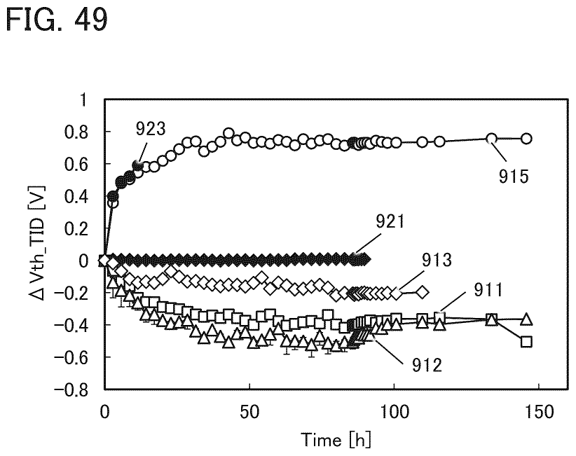

FIG. 48 and FIG. 49 each show the amount of changes in threshold voltages of the OS transistors at a drain voltage Vd of 0.1 V. In FIG. 48 and FIG. 49, the horizontal axis represents time (Time) [h], and the vertical axis represents the amount of change in the threshold voltage (ΔVth_TID) [V]. In each of FIG. 48 and FIG. 49, 0 on the horizontal axis corresponds to the time before X-ray irradiation. The amount of change in threshold voltage (ΔVth_TID) shown in each of FIG. 48 and FIG. 49 is a relative threshold voltage with an average value of the threshold voltages calculated from Id-Vg characteristics measured two times before X-ray irradiation set to 0. Plots in FIG. 48 and FIG. 49 show the average values of the threshold voltages obtained by two Id-Vg measurements, and error bars each show the maximum value and the minimum value. Note that the OS transistors except the OS transistor 901 were subjected to double sweep, so that the four threshold voltages were obtained by the two Id-Vg measurements. That is, the median values of the threshold voltages shown in FIG. 48 and FIG. 49 are each calculated from the obtained four threshold voltages.

FIG. 48 shows the results of the OS transistor 906, the OS transistor 907, the OS transistor 911, and the OS transistor 912. As shown in FIG. 48, TID degradation equally occurs under conditions where all the terminals (sources, drains, gates, and back gates) are grounded regardless of the designed values of the transistors. In addition, a tendency is observed in which the TID degradation is large under the conditions of voltage application assuming the OS transistors in an off state. The tendency for the TID degradation to be large under the conditions of voltage application assuming the OS transistors in an off state is equally observed regardless of the designed values of the transistors.

FIG. 49 shows the results of the OS transistor 911 to the OS transistor 913, the OS transistor 915, the OS transistor 921, and the OS transistor 923. As shown in FIG. 49, under the conditions where the gate voltage Vg is set to +1 V, there is no change in electrical characteristics due to voltage application (BT degradation), and TID degradation is half of that under the conditions where the gate voltage Vg is set to 0 V. Under the conditions where the gate voltage Vg is set to +3 V, there is marked BT degradation and almost no TID. Thus, the mechanism of a Vth change (degradation mechanism) due to TID is possibly caused by hole accumulation in an insulating film, which is considered with a Si transistor. The difference in behavior depending on application voltage is caused by, for example, cancelation of a Vth change due to electrons accumulated by +GBT stress, electric charge sweep due to a drift by an electric field, or recovery of TID due to interface recombination with induced electrons.

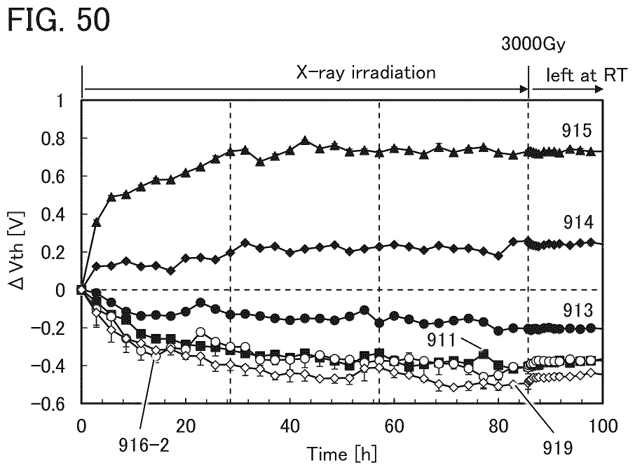

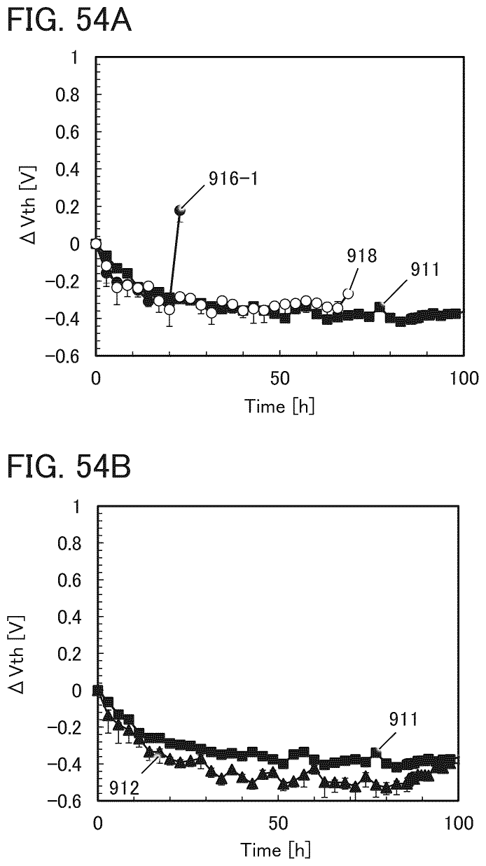

FIG. 50 to FIG. 54 show the amount of changes in threshold voltages of the OS transistors at a drain voltage Vd of 0.1 V. In FIG. 50 to FIG. 54, the horizontal axis represents time (Time) [h], and the vertical axis represents the amount of change in the threshold voltage (ΔVth) [V]. In the horizontal axis in FIG. 50 to FIG. 54, 0 on the horizontal axis corresponds to the time before X-ray irradiation. The amount of change in threshold voltage (ΔVth) shown in each of FIG. 50 to FIG. 54 is a relative value with an average value of the threshold voltages calculated from Id-Vg characteristics measured two times before X-ray irradiation set to 0. The plots in FIG. 50 to FIG. 54 indicate the median values of the threshold voltages each obtained by two Id-Vg measurements. Note that the error bars shown in FIG. 54 represent the maximum values and the minimum values of the threshold voltages. Note that the OS transistors except the OS transistor 901 were subjected to double sweep, so that the four threshold voltages were obtained by the two Id-Vg measurements. That is, the median values of the threshold voltages shown in FIG. 50 to FIG. 54 are calculated from the obtained four threshold voltages.

FIG. 50 shows the results of the OS transistor 911, the OS transistor 913 to the OS transistor 915, the OS transistor 916-2, and the OS transistor 919. As shown in FIG. 50, the TID degradation under the conditions where the gate voltage Vg is set to +2 V is between the TID degradation under the conditions where the gate voltage Vg is set to +1 V and the TID degradation under the conditions where the gate voltage Vg is set to +3 V. Under the conditions where the gate voltage Vg is set to +2 V or higher, Vth apparently shifts in the positive direction. Under the conditions where the gate voltage Vg is set to 0 V, ΔVth at a total X-ray dose of 3000 Gy is approximately −0.4 V. The higher the positive voltage applied to the gate voltage Vg is, the more ΔVth shifts in the positive direction. Furthermore, the higher the negative voltage as the gate voltage Vg is, the more ΔVth tends to shift in the negative direction.

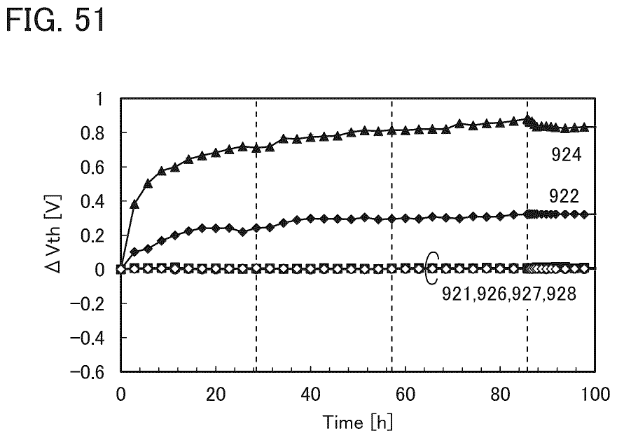

FIG. 51 shows the results of the OS transistor 921, the OS transistor 922, the OS transistor 924, and the OS transistor 926 to the OS transistor 928. As shown in FIG. 51, the BT degradation under the conditions where the gate voltage Vg is set to +2 V is the intermediate between the BT degradation under the conditions where the gate voltage Vg is set to +1 V and the BT degradation under the conditions where the gate voltage Vg is set to +3 V. Even in the case where X-ray irradiation is not performed, the higher the positive voltage applied to the gate voltage Vg is, the more ΔVth shifts in the positive direction. It is presumed from the results shown in FIG. 50 and FIG. 51 that the changes in threshold voltage are each dominantly due to electron trapping in the gate insulator. Note that ΔVth hardly changes under the conditions where the top gate voltage is set to +1 V or lower.

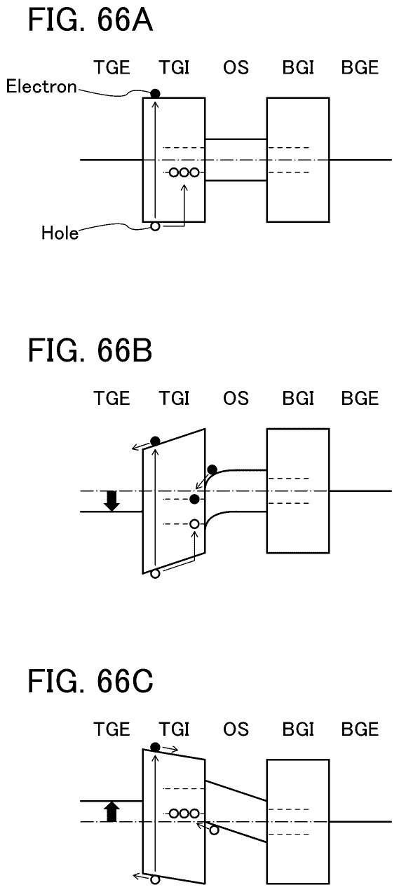

The above presumption relating to the change in threshold voltage is described with reference to energy band diagrams. FIG. 66A to FIG. 66C are each an energy band diagram of an OS transistor. The work function of each of a top gate electrode (TGE) and a back gate electrode (BGE) and the valence band and the conduction band of each of a top gate insulating film (TGI), a metal oxide (OS), and a back gate insulating film (BGI) are illustrated in FIG. 66A to FIG. 66C. In FIG. 66A to FIG. 66C, dashed-dotted lines represent Fermi levels in a state where no potential is applied to the top gate electrode and the back gate electrode, dashed lines represent the levels of trapping electrons or holes, black circles represent electrons, and white circles represents holes.

FIG. 66A is the energy band diagram where the top gate voltage is 0 V. In this case, holes are trapped by the level in the top gate insulating film.

FIG. 66B is the energy band diagram where the top gate voltage is higher than 0 V. In this case, holes are trapped by the level in the top gate insulating film. In addition, electrons are injected from the metal oxide into the level in the top gate insulating film. Note that some of the holes trapped by the level in the top gate insulating film are presumed to recombine with the electrons injected into the level in the top gate insulating film.

FIG. 66C is an energy band diagram of the case where the top gate voltage is lower than 0 V. At this time, holes are injected from the metal oxide into the level in the top gate insulating film.

Although FIG. 66B and FIG. 66C illustrate the case where the top gate voltage is applied, the same applies to the back gate insulating film of the case where the back gate voltage is applied.

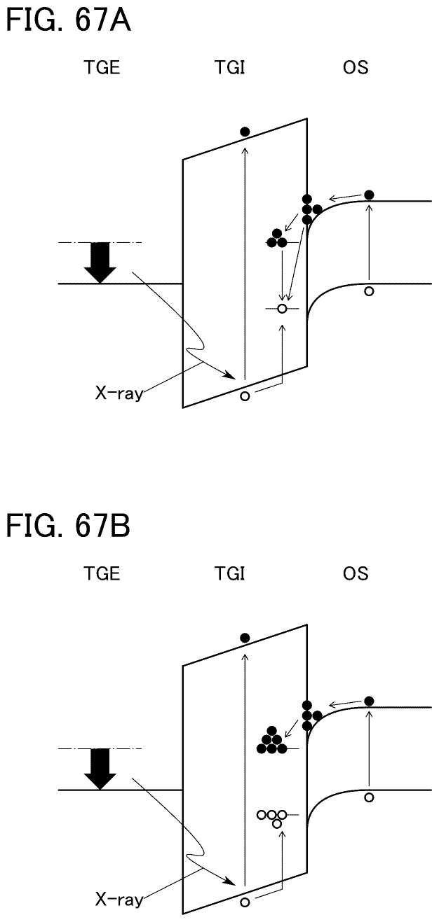

FIG. 67A and FIG. 67B are energy band diagrams of an OS transistor. FIG. 67A and FIG. 67B each illustrate the work function of the top gate electrode (TGE), the valence band and the conduction band of the top gate insulating film (TGI), and the valence band and the conduction band of the metal oxide (OS). In FIG. 67A and FIG. 67B, dashed-dotted lines represent Fermi levels in a state where no potential is applied to the top gate electrode and the back gate electrode, solid lines between the valence band and the conduction band of the top gate insulating film represent the levels of trapping electrons or holes, black circles represent electrons, and white circles represents holes. In addition, FIG. 67A and FIG. 67B are energy band diagrams where the top gate voltage is higher than 2 V.

FIG. 67A shows an example of the above presumption relating to the change in threshold voltage. In other words, the X-ray irradiation causes the level in the top gate insulating film to trap holes. However, the number of trapped holes is decreased by recombination with electrons injected from the metal oxide. Consequently, the threshold voltage shifts in the positive direction.

FIG. 67B shows an example of the above presumption relating to the change in threshold voltage. Specifically, the X-ray irradiation causes the level in the top gate insulating film to trap holes, whereby the threshold voltage shifts in the negative direction. Meanwhile, when electrons are injected from the metal oxide into the level in the top gate insulating film, the threshold voltage shifts in the positive direction. In this case, if the amount of shift of the threshold voltage in the positive direction is larger than that in the negative direction, the threshold voltage shifts in the positive direction.

Although the phenomenon of change in threshold voltage is limited to the top gate insulating film in the explanation with reference to FIG. 67A and FIG. 67B, a similar phenomenon is likely to occur also with the back gate insulating film.

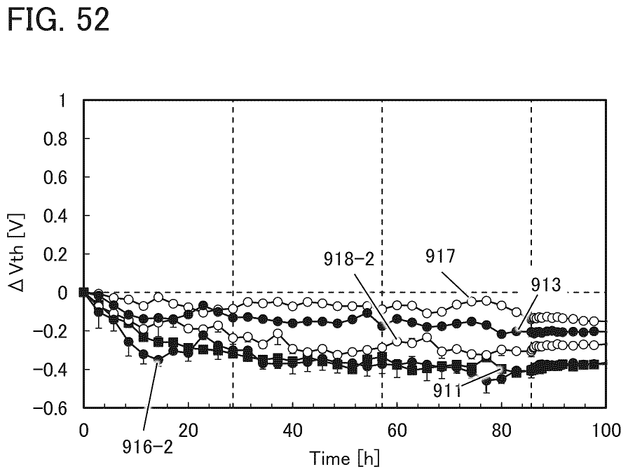

FIG. 52 shows the results of the OS transistor 911, the OS transistor 913, the OS transistor 916-2, the OS transistor 917, and the OS transistor 918-2. Note that a back gate voltage Vbg of +4.15 V corresponds to a gate voltage Vg of +1 V in consideration of the EOT. As shown in FIG. 52, the TID degradation under the conditions where the back gate voltage Vbg is set to +4.15 V is apparently smaller than the TID degradation under the conditions where the voltage Vg is set to +1 V.

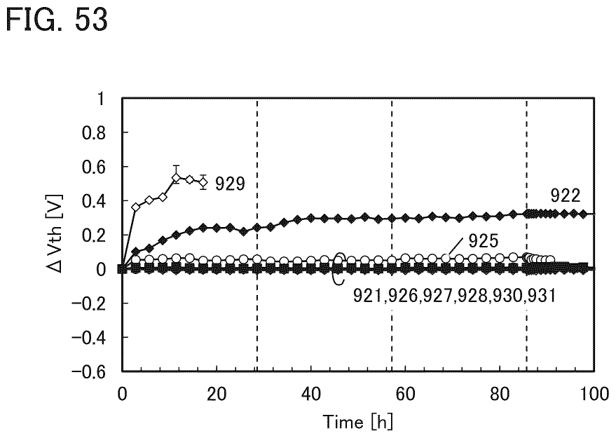

FIG. 53 shows the results of the OS transistor 921, the OS transistor 922, and the OS transistor 925 to the OS transistor 931. As shown in FIG. 53, Vth positively drifts by approximately 50 mV under the conditions where the back gate voltage Vbg is set to +4.15 V. The TID degradation under the condition where the back gate voltage Vbg is set to +8.3 V is larger than the TID degradation under the conditions where the voltage Vg is set to +2 V.

FIG. 54A shows the results of the OS transistor 911, the OS transistor 916-1, and the OS transistor 918. FIG. 54B shows the results of the OS transistor 911 and the OS transistor 912.

As can be seen from FIG. 54A, the TID degradation under the conditions where the gate voltage Vg is set to −1 V or the conditions where the back gate voltage Vbg is set to −4.15 V (corresponding to a gate voltage Vg of −1 V) is not significantly different from the TID degradation under the conditions where all the terminals (source, drain, gate, and back gate) are grounded. Meanwhile, as shown in the results in FIG. 54B, the TID degradation is large under the conditions of voltage application assuming the OS transistors in an off state, i.e., the conditions where the gate voltage Vg is set to −0.8 V and the back gate voltage Vbg is set to −6 V. The factors of the difference are, for example, the magnitude of the back gate voltage and simultaneous application of the gate voltage and the back gate voltage.

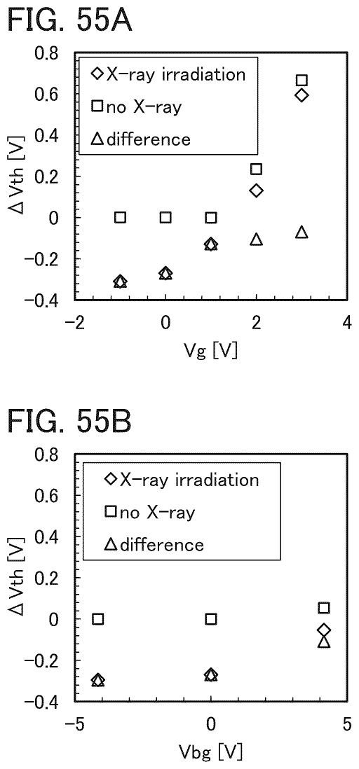

FIG. 55A shows the gate voltage Vg dependence of the threshold voltage (ΔVth), and FIG. 55B shows the back gate voltage Vbg dependence of the threshold voltage (ΔVth). In each of FIG. 55A and FIG. 55B, a plot indicated by rhombuses represents results with X-ray irradiation, a plot indicated by quadrangles represents results without X-ray irradiation, and a plot indicated by triangles represents differences therebetween. Note that the differences are calculated on the assumption that the change in characteristics due to X-ray irradiation is the sum of the TID degradation and the BT degradation and the TID degradation and the BT degradation are independent phenomena.

It is indicated that a variable component of only TID degradation including the recombination can be estimated from the results of the differences shown in FIG. 55A and FIG. 55B.

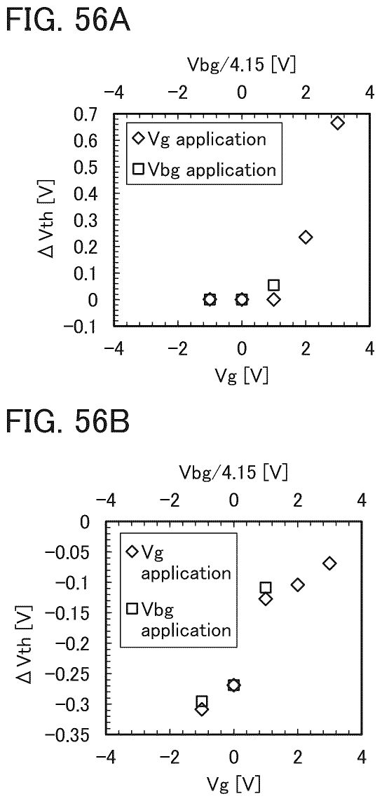

The horizontal axes in FIG. 55A and FIG. 55B are adjusted in the graphs of FIG. 56A and FIG. 56B, respectively. Specifically, the horizontal axis of each graph was adjusted in consideration of the EOT so that the electric field strengths of the gate voltage and the back gate voltage are substantially equal. In FIG. 56A and FIG. 56B, a plot indicated by rhombuses represents results with application of the gate voltage, and a plot indicated by quadrangles represents results with application of the back gate voltage. FIG. 56A shows the results without X-ray irradiation, and FIG. 56B shows the above differences.

FIG. 56A indicates that the shift in the positive direction due to +GBT stress starts to increase at a gate voltage Vg of approximately +1 V or a back gate voltage Vbg of approximately +4.15 V. In addition, it is indicated that the results with application of the gate voltage and the results with application of the back gate voltage are substantially equivalent under the conditions where the electric field strengths are substantially equal. Furthermore, FIG. 56B indicates that the variable component of only the TID degradation including the recombination significantly decreases at a boundary between the conditions where all the terminals (source, drain, gate, and back gate) are grounded and the conditions where the gate voltage Vg is set to +1 V or the back gate voltage Vbg is set to +4.15 V. It is also indicated that the results in application of the gate voltage and the results in application of the back gate voltage are substantially equivalent under the conditions where the electric field strengths are substantially equal.

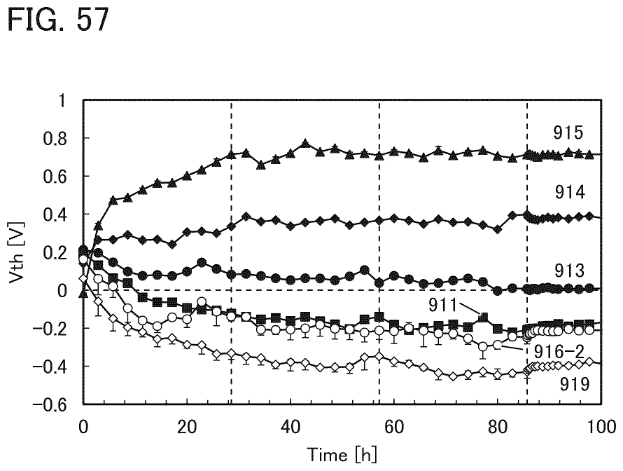

FIG. 57 shows the threshold voltages of the OS transistors at a drain voltage Vd of 0.1 V. In FIG. 57, the horizontal axis represents time (Time) [h], and the vertical axis represents threshold voltage (Vth) [V]. In the horizontal axis in FIG. 57, 0 on the horizontal axis corresponds to the time before X-ray irradiation. The plots in FIG. 57 indicate the median values of the threshold voltages each obtained by two Id-Vg measurements. Note that the error bars shown in FIG. 57 represent the maximum values and the minimum values of the threshold voltages. Note that the OS transistors except the OS transistor 901 were subjected to double sweep, so that the four threshold voltages were obtained by the two Id-Vg measurements. That is, the median value of the threshold voltages shown in FIG. 57 is calculated from the obtained four threshold voltages.

As shown in FIG. 57, variations in the threshold voltages Vth of the OS transistors before X-ray irradiation are found though the variations are not significant.

The composition, structure, method, and the like described in this example can be used in combination as appropriate with the compositions, structures, methods, and the like described in the other embodiments and the like.

### Example 2

In this example, the resistance of an OS transistor to radiation irradiation was evaluated. In addition, a memory device including an OS memory was fabricated, and its resistance to hard errors due to TID and soft errors (SEU: Single Event Upset) in irradiation with heavy-ion beams was evaluated.

### <OS Transistor>

For the structure of the OS transistor fabricated in this example, the structure of the OS transistor 911 fabricated in Example 1 can be referred to. Note that in the OS transistor, the designed channel length value was 60 nm and the designed channel width value was 60 nm. The EOT of the top gate insulating film was set to 5.0 nm and the EOT of the back gate insulating film was set to 24.6 nm.

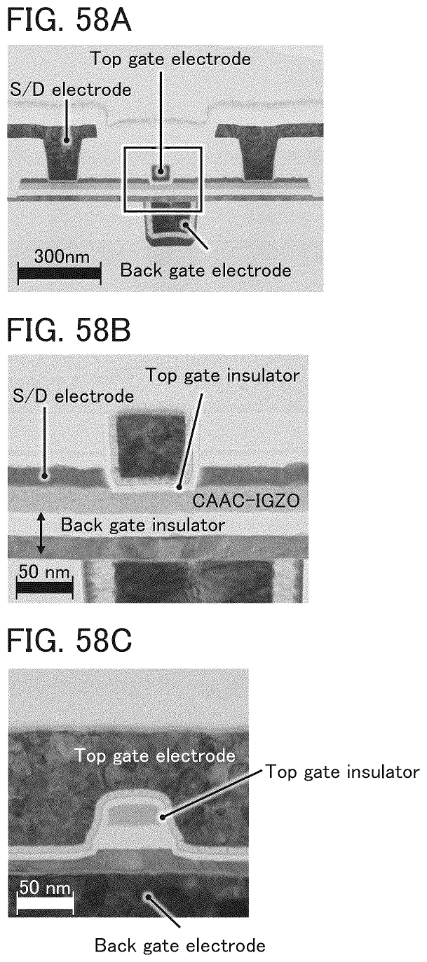

A cross-sectional STEM image of the fabricated OS transistor was taken with “HD-2700” produced by Hitachi High-Tech Corporation. FIG. 58A and FIG. 58B show cross-sectional STEM images of the OS transistor in the channel length direction, and FIG. 58C shows a cross-sectional STEM image of the OS transistor in the channel width direction. Note that FIG. 58B is an enlarged view of a region indicated by a square in FIG. 58A. The OS transistor can also be said to have a TGSA (Trench Gate Self-Aligned) structure. Note that in FIG. 58A to FIG. 58C, “Back gate electrode” is the back gate electrode, “Back gate insulatore” is the back gate insulating film, “CAAC-IGZO” is the metal oxide, “S/D electrode” is the source electrode or the drain electrode, “Top gate electrode” is the top gate electrode, and “Top gate insulator” is the top gate insulating film.

Before X-ray irradiation, drain current (Id)-gate voltage (Vg) characteristics of the fabricated OS transistor were measured.

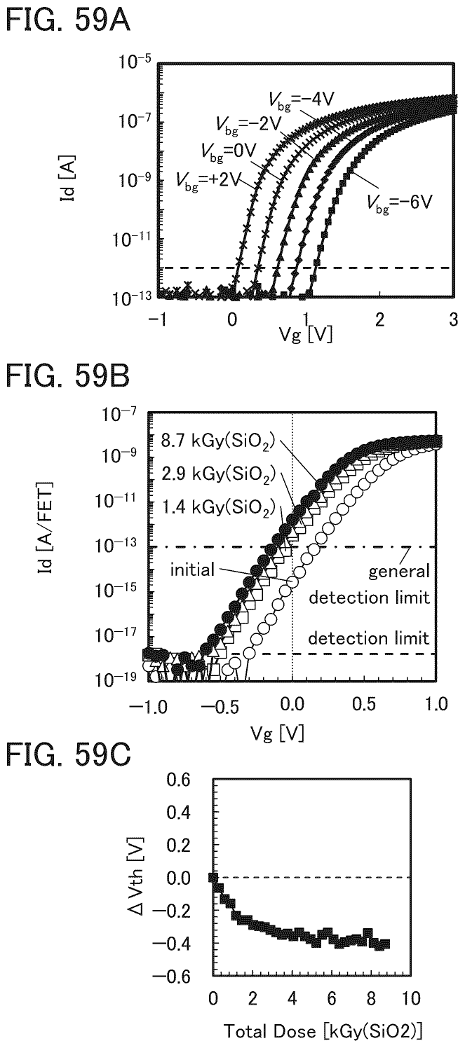

FIG. 59A shows the Id-Vg characteristics of the OS transistor before X-ray irradiation. FIG. 59A shows the Id-Vg characteristics obtained by measurements with the back gate voltage Vbg with respect to the source set to −6 V, −4 V, −2 V, 0 V, or +2 V under the conditions where the drain voltage with respect to the source was set to 0.1 V, the source voltage was set to 0 V, and the temperature of the measurement environment was set to 25° C. In FIG. 59A, the horizontal axis represents gate voltage Vg [V] and the vertical axis represents drain current Id [A].

As can be seen from FIG. 59A, the threshold voltage of the OS transistor can be linearly changed by the application of the back gate voltage Vbg.

Here, an X-ray irradiation test is described. The evaluation environment for the X-ray irradiation test employed in this example is the same as the evaluation environment described in Example 1. Note that the irradiation dose rate was measured with an ionization chamber dose meter 10×6-6 produced by Radcal Corporation. In this example, the X-ray dose rate was set to 35 Gy (air)/h. Note that the conversion coefficient of the absorption dose estimated from an X-ray spectrum and a mass-energy absorption coefficient is 1.0 Gy (air)=2.9 Gy (SiO₂). That is, the absorption dose rate at 35 Gy (air)/h is estimated to be 102 Gy (SiO₂)/h. In this example, Gy (SiO₂) is used as a unit of absorption dose.

Next, a change in the off-state current of the OS transistor due to X-ray irradiation was evaluated. Note that since the off-state current of the OS transistor falls below the lower measurement limit of a general measuring instrument, a TEG (Test Element Group) in which 60000 OS transistors were connected in parallel was fabricated in this example. During X-ray irradiation, the terminal potentials were each set to a ground potential (Vg=Vbg=Vd=Vs=0 V) and the temperature was set to room temperature (25° C.). Note that in this example, conditions where all the terminals (source, drain, gate, and back gate) are grounded are sometimes referred to as all terminals grounded.

FIG. 59B shows the Id-Vg characteristics of the OS transistors in the fabricated TEG measured before X-ray irradiation (initial), those measured when the total X-ray irradiation dose became 1.4 kGy (SiO₂), those measured when the total X-ray irradiation dose became 2.9 kGy (SiO₂), and those measured when the total X-ray irradiation dose became 8.7 kGy (SiO₂).

FIG. 59B shows Id-Vg characteristics obtained by measurement with the drain voltage with respect to the source set to 0.1 V, the source voltage and the back gate voltage set to 0 V, and the temperature of the measurement environment set to 25° C. In FIG. 59B, the horizontal axis represents gate voltage Vg [V], and the vertical axis represents drain current Id [A/FET] per OS transistor. A dashed-dotted line in FIG. 59B represents the lower measurement limit (general detection limit) in the case of measuring a transistor, where the number of parallel connections is one, using a general measurement instrument. A dotted line in FIG. 59B represents the value (detection limit) obtained when the lower measurement limit in the case of measuring the TEG where the number of parallel connections is 60000 is converted into the lower measurement limit per transistor.

As shown in FIG. 59B, the off-state current of the OS transistors after the 8.7 kGy (SiO₂) irradiation, which corresponds to the dosage on a geostationary orbit for 30 years, is lower than or equal to the lower measurement limit (1.7×10⁻¹⁸ A/FET), which reveals that the OS transistors maintain low-leakage characteristics. In addition, the SS and the field-effect mobility hardly changed under the influence of TID. This indicates that the threshold voltage having shifted in the negative direction by TID can be easily corrected by application of the back gate voltage Vbg.

FIG. 59C shows a change in the threshold voltage Vth of the OS transistor due to X-ray irradiation. In FIG. 59C, the vertical axis represents amount of change in threshold voltage (ΔVth) [V] and the horizontal axis represents total X-ray dose (Total Dose) [kGy (SiO₂)]. In this example, the gate voltage Vg at which a current of 1 pA flows is regarded as the threshold voltage Vth.

As shown in FIG. 59C, the threshold voltage Vth after the 8.7 kGy (SiO₂) irradiation shifts in the negative direction from the threshold voltage Vth before the X-ray irradiation by approximately 0.4 V with the all terminals grounded.

### <OS Memory>

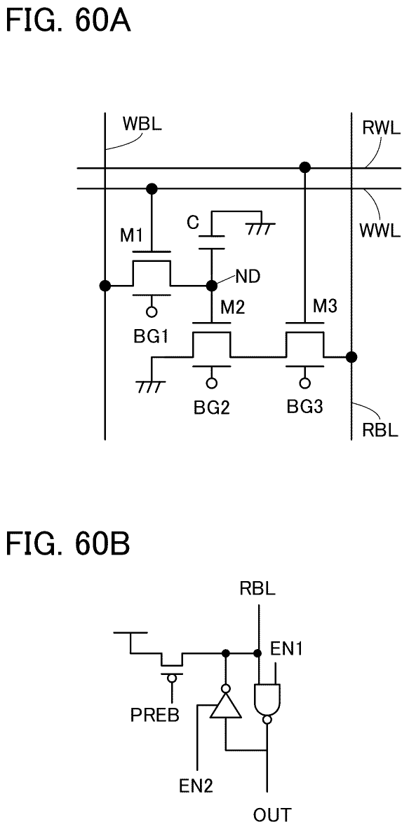

In this example, a chip including a memory device was fabricated. The memory device includes four memory cell arrays. Each memory cell array includes memory cells arranged in a matrix. FIG. 60A shows a circuit structure of the memory cell, FIG. 60B shows a circuit diagram of a reading circuit, and Table 2 shows the specifications.

TABLE 2

| Feature | Value | |
|---|---|---|
| Process technology | OS: 60 nm | |
| Cell configuration | 3T + 1C | |
| Power supply voltage | 2.5 V/−0.8 V | |
| Memory capacity | 228 | KB |
| cell capacitance | 0.67 | fF |

The memory cell includes the transistor M1 to the transistor M3 and a capacitor C. In other words, the memory cell has a 3Tr1C type (3T+1C) structure, and data is held in the capacitor C by accumulation of electric charge. Note that the transistor M1 to the transistor M3 are OS transistors. Thus, the memory cell can be regarded as an OS memory. Note that the memory cell array fabricated in this example is referred to as an OS memory array in some cases.

As described above, in the case where OS transistors are used as the transistor M1 to the transistor M3, the threshold voltage of each of the transistor M1 to the transistor M3 can be controlled independently by application of the back gate voltage. A terminal connected to the back gate of the transistor M1 is denoted by a terminal BG1, a terminal connected to the back gate of the transistor M2 is denoted by a terminal BG2, and a terminal connected to the back gate of the transistor M3 is denoted by a terminal BG3. Note that the description in Embodiment 2 can be referred to for the connection relationship between components included in the memory cell, the wirings connected to the memory cell, and the like in FIG. 60A.

The memory capacity of each memory cell array is 57 KB. That is, the memory capacity of the memory device included in the chip is 228 KB.

The memory cell array is controlled by a CMOS circuit (a Si CMOS circuit) composed of a Si transistor provided below a layer including an OS transistor.

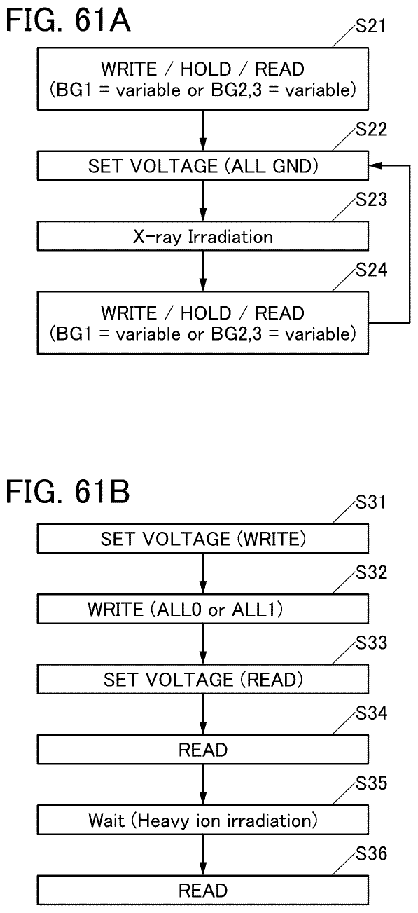

FIG. 61A shows a flowchart showing a method of a TID resistance test for the OS memory.

First, the terminal BG1 or the terminals BG2 and BG3 were changed to perform a holding test (BG1=variable or BG2,3=variable in Step S21 in FIG. 61A) for one minute. In the holding test, a writing operation (WRITE), a holding operation (HOLD), and a reading operation (READ) were performed in this order. Note that potentials applied to the terminal BG1 to the terminal BG3 were constant during one holding test (from the writing operation to the reading operation) and the potential of the wiring WWL during the holding operation was set to −0.8 V.

Next, all terminals grounded were set (SET VOLTAGE (ALL GND) in Step S22 in FIG. 61A). Next, the memory device was irradiated with a certain amount of X rays (X-ray Irradiation in Step S23 in FIG. 61A).

After the X-ray irradiation, the terminal BG1 or the terminals BG2 and BG3 described above were changed to perform a holding test for one minute (Step S24 in FIG. 61A). Note that Step S22 to Step S24 were performed repeatedly until the amount of X-rays with which the memory device was irradiated reached the set value. The above is the description of the method of the TID resistance test for the OS memory.

Next, FIG. 61B shows a flowchart showing a method of an SEU resistance test for the OS memory.

First, a voltage for performing writing was set (SET VOLTAGE (WRITE) in Step S31 in FIG. 61B). Next, the writing operation was performed (WRITE in Step S32 in FIG. 61B). In Step S32, data “0” or data “1” was written to all the memory cells (ALL0 or ALL1).

Next, a voltage for performing reading was set (SET VOLTAGE (READ) in Step S33 in FIG. 61B). Next, the reading operation was performed (READ in Step S34 in FIG. 61B).

Next, the holding operation was performed. In the holding operation, WWL=−1.3 V, BG1=−6 V, and BG2=BG3=0 V. Note that the other terminal potentials were set to GND. In the holding operation, irradiation with heavy-ion beams was performed (Wait (Heavy ion irradiation) in Step S35 in FIG. 61B).

Next, the reading operation was performed (READ, Step S36 in FIG. 61B). The above is the description of the method of the SEU resistance test for the OS memory.

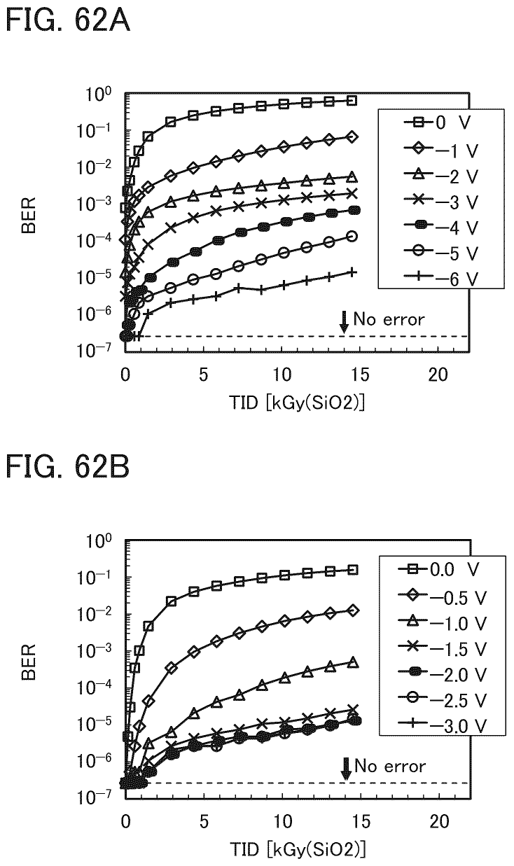

FIG. 62A and FIG. 62B show results of the TID resistance test. FIG. 62A and FIG. 62B reveal the TID dependence of a bit error rate (BER) after the writing operation and the one-minute holding operation sequentially performed immediately after X-ray irradiation. In each of FIG. 62A and FIG. 62B, the vertical axis represents bit error rate (BER) and the horizontal axis represents cumulative X-ray dose (TID) [kGy (SiO₂)]. FIG. 62A shows the results with the terminal BG2 and the terminal BG3 each set at −3.0 V and the terminal BG1 set at −6 V, −5 V, −4 V, −3 V, −2 V, −1 V, or 0 V. Meanwhile, FIG. 62B shows the results with the terminal BG1 set at −6 V and the terminal BG2 and the terminal BG3 each set at −3.0 V, −2.5 V, −2.0 V, −1.5 V, −1.0 V, −0.5 V, or 0.0 V.

As can be seen from FIG. 62A and FIG. 62B, in the case where the potential applied to the back gate is 0 V, the proportion of the memory cells performing a normal operation tends to decrease (the BER tends to increase) with an increase in TID. This is presumed to be derived from a shift of the threshold voltage in the negative direction due to X-ray irradiation.

It is also found that, the lower the potential applied to the back gate is, the more a decrease in normal rate (an increase in the BER) due to an increase in TID tends to be inhibited. This indicates that applying a negative potential to the back gate corrects the varied threshold voltage Vth, thereby inhibiting a decrease in normal rate (an increase in the BER).

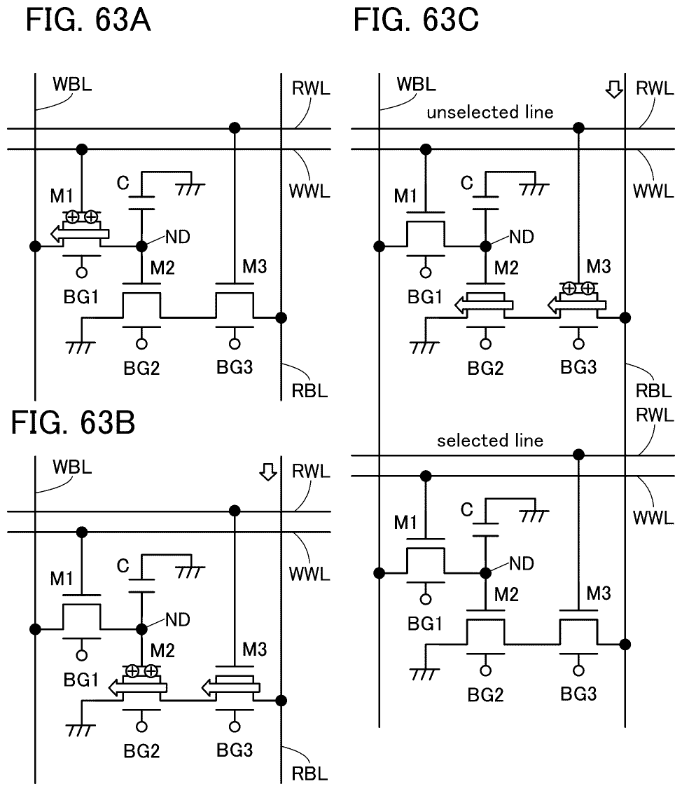

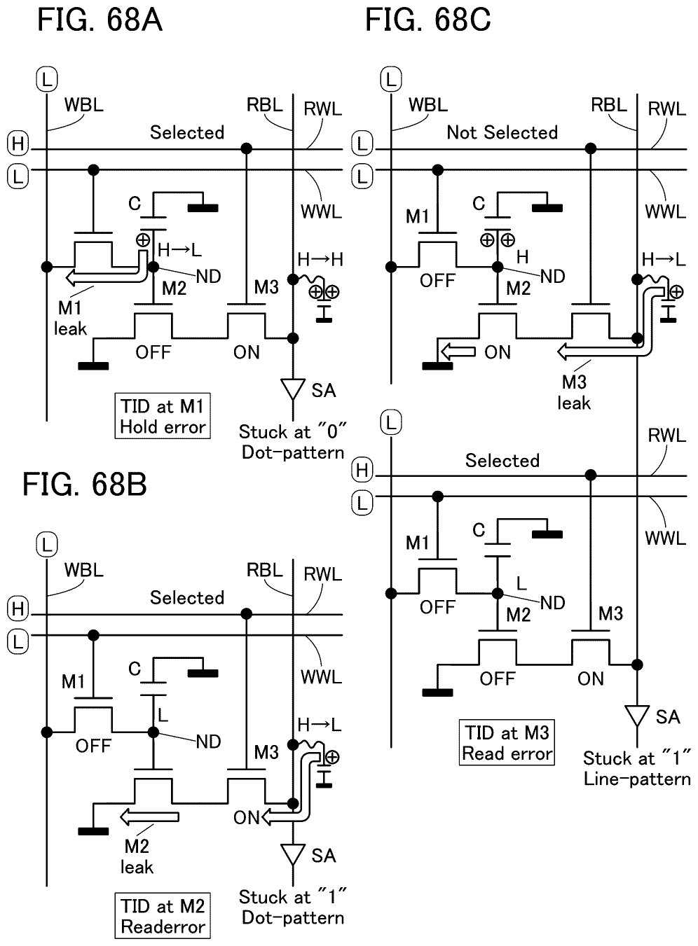

Here, error modes occurring in the OS memory and the cause for each of them are described with reference to FIG. 63A to FIG. 63C and FIG. 68A to FIG. 68C. Note that the OS memory in which an error occurs is referred to as an error cell in some cases. FIG. 63A and FIG. 68A are diagrams illustrating an error mode due to the influence of the TID on the transistor M1, FIG. 63B and FIG. 68B are diagrams illustrating an error mode due to the influence of the TID on the transistor M2, and FIG. 63C and FIG. 68C are diagrams illustrating an error mode due to the influence of the TID on the transistor M3. Note that in FIG. 68A to FIG. 68C, SA represents a sense amplifier. In addition, ON in the vicinity of a transistor indicates that the transistor is in an on state, and OFF in the vicinity of a transistor indicates that the transistor is in an off state. Furthermore, H in the vicinity of a wiring indicates that the potential H is supplied to the wiring, and L in the vicinity of a wiring indicates that the potential L is supplied to the wiring. Moreover, H in the vicinity of the node ND indicates that the potential of the node ND is the potential H, and L in the vicinity of the node ND indicates that the potential of the node ND is the potential L. Furthermore, + represents positive charge. Note that in FIG. 68A and FIG. 68B, the wiring RWL is a selection line (Selected).

It is presumed that, in the case where the threshold voltage of the transistor M1 is beyond the allowable specification values owing to the shift of the threshold voltage in the negative direction due to X-ray irradiation, current leaks from the node ND to the wiring WBL, as illustrated in FIG. 63A, thereby causing a hold error. Specifically, it is presumed that in the case where the threshold voltage of the transistor M1 is beyond the allowable specification values owing to the shift of the threshold voltage in the negative direction due to X-ray irradiation, leakage current in the transistor M1 increases (M1 leak), whereby the potential H written to the node ND is rewritten to the potential L while being held, as illustrated in FIG. 68A. Note that a 0 stuck-at fault is given as an example of a failure due to the hold error of the transistor M1 (TID at M1 Hold error). The 0 stuck-at fault occurs in an error cell (Stuck at “0” Dot-pattern).

It is presumed that, in the case where the threshold voltage of the transistor M2 is beyond the allowable specification values owing to the shift of the threshold voltage in the negative direction due to the X-ray irradiation, current flows between the source and the drain of the transistor M2 in the reading operation regardless of data held in the node ND, as illustrated in FIG. 63B, thereby causing a read error. In other words, it is presumed that, in the case where the threshold voltage of the transistor M2 is beyond the allowable specification values owing to the shift of the threshold voltage in the negative direction due to the X-ray irradiation, a state is created in which the potential His always written to the node ND in a pseudo manner as illustrated in FIG. 68B. Note that a 1 stuck-at fault is given as an example of a failure due to the read error of the transistor M2 (TID at M2 Read error). The 1 stuck-at fault occurs in an error cell (Stuck at “1” Dot-pattern).

It is presumed that, in the case where data “1” is written to the node ND of an unselected memory cell and the threshold voltage of the transistor M3 included in the unselected memory cell is beyond the allowable specification values owing to the shift of the threshold voltage in the negative direction due to the X-ray irradiation, current of the wiring RBL flows to the unselected memory cell, as illustrated in FIG. 63C and FIG. 68C, thereby causing a read error in a selected memory cell. Note that a 1 stuck-at fault is given as an example of a failure due to the read error of the transistor M3 (TID at M3 Read error). The 1 stuck-at fault occurs not only in an error cell but also in all the OS memories connected to the same wiring RBL (Stuck at “1” Line-pattern). Note that in FIG. 63C and FIG. 68C, the upper wiring RWL is an unselected line (Not Selected) and the lower wiring RWL is a selected line (Selected).

The initial threshold voltages of the OS transistors included in the memory cell may vary to some extent. Furthermore, X-ray irradiation causes the threshold voltages of the OS transistors included in the memory cell to shift in the negative direction. Presumably, as a result of the variation in the initial threshold voltages and the shift in the negative direction due to X-ray irradiation, the threshold voltage of a specific OS transistor falls out of the allowable range of threshold voltage, which results in the above-described error modes.

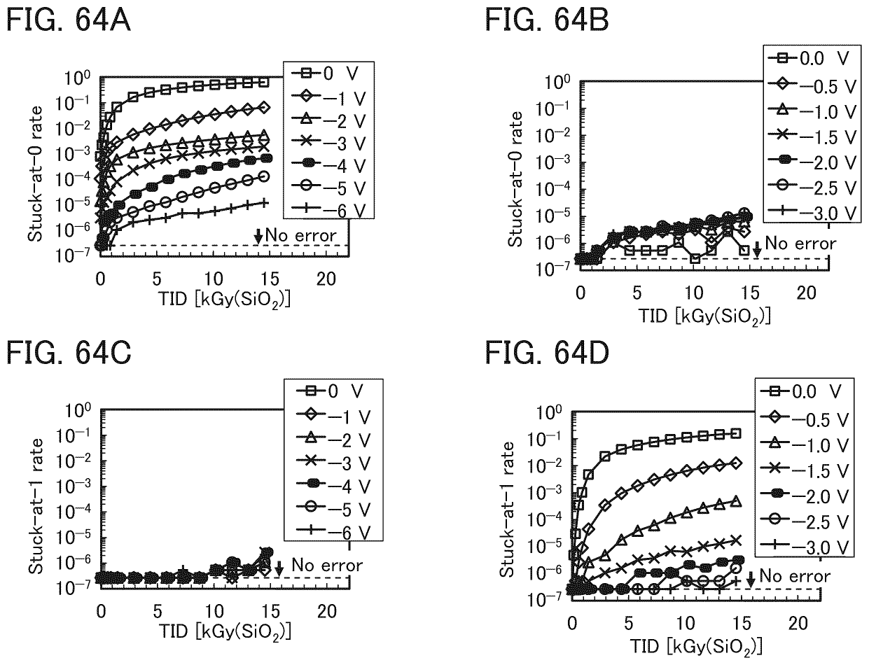

The results in FIG. 62A and FIG. 62B are separately shown for each error mode in FIG. 64A to FIG. 64D. In FIG. 64A to FIG. 64D, the horizontal axis represents the cumulative X-ray dose (TID). The vertical axis in each of FIG. 64A and FIG. 64B represents a 0 stuck-at fault rate (Stuck-at-0 rate), and the vertical axis in each of FIG. 64C and FIG. 64D represents a 1 stuck-at fault rate (Stuck-at-1 rate).

FIG. 64A and FIG. 64C each show the results with the terminal BG2 and the terminal BG3 each set at −3.0 V and the terminal BG1 set at −6 V, −5 V, −4 V, −3 V, −2 V, −1 V, or 0 V. Meanwhile, FIG. 64A and FIG. 64C each show the results with the terminal BG1 set at −6 V and the terminal BG2 and the terminal BG3 each set at −3.0 V, −2.5 V, −2.0 V, −1.5 V, −1.0 V, −0.5 V, or 0.0 V.

FIG. 64A reveals that the 0 stuck-at fault rate tends to decrease with decreasing potential of the terminal BG1. FIG. 64B reveals that the 0 stuck-at fault rate is less dependent on the potentials of the terminal BG2 and the terminal BG3 than on the terminal BG1. These show that the terminal BG1 contributes to inhibition of the 0 stuck-at fault due to the hold error of the transistor M1.

FIG. 64D reveals that the 1 stuck-at fault rate tends to decrease with decreasing the potentials of the terminal BG2 and the terminal BG3. FIG. 64C reveals that the 1 stuck-at fault rate is less dependent on the potentials of the terminal BG1 than on the terminal BG2 and the terminal BG3. These show that the terminal BG2 and the terminal BG3 contribute to inhibition of the 1 stuck-at fault due to the read errors of the transistor M2 and the transistor M3.

From the above, it is found that the correction of the threshold voltage Vth by the application of the back gate voltage, which is described with reference to FIG. 59A, is effective in inhibiting the malfunctions of the OS memory which are caused by radiation.

Next, a test of the resistance of the OS memory to soft errors using heavy-ion beams is described. The test was performed at TIARA, which is the facility for ion irradiation. As the heavy-ion beams, six kinds of ion species from the AVF cyclotron were used. Note that the description with reference to FIG. 61B can be referred to for the SEU resistance test method.

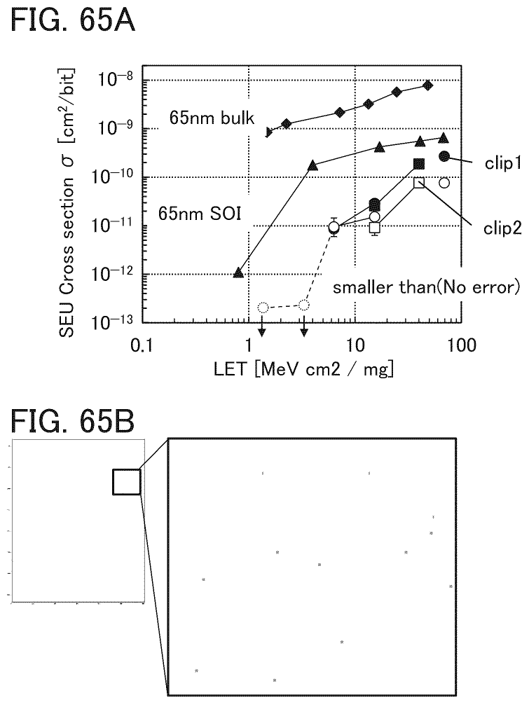

FIG. 65A shows LET (Linear Energy Transfer) dependence of the cross section σ (error probability) of a reaction to soft errors. In FIG. 65A, the vertical axis represents the cross section (SEU Cross section) σ [cm²/bit] of a reaction to soft errors and the horizontal axis represents LET [MeV cm²/mg].

A plot indicated by circles in FIG. 65A represents results for one of the OS memory arrays (clip1) and a plot indicated by squares in FIG. 65A represents results for another one of the OS memory arrays (clip2). The results of ALL1 in the OS memory array are filled, and the results of ALL0 in the OS memory array are open. Note that FIG. 65A also shows, for comparison, results of the SEU resistance test on SRAMs, which have been reported. A plot indicated by rhombuses in FIG. 65A represents results for an SRAM (65 nm bulk) fabricated by a 65-nm process using a bulk silicon wafer, and a plot indicated by triangles in FIG. 65A represents results for an SRAM (65 nm SOI) fabricated by a 65-nm process using an SOI wafer.

As shown in FIG. 65A, for both of ALL0/ALL1, the threshold value of LET with which a soft error occurs is higher in the OS memory than in a general SRAM of the same generation. With a low-energy ion beam with LET lower than or equal to 3.3 MeV cm²/mg, in particular, a soft error did not occur in the OS memory for both write patterns of ALL0 and ALL1. With the same LET (energy of the ion beam), the cross section σ of the reaction of the OS memory was less than that of a general SRAM of the same generation by approximately one digit. Accordingly, it can be said that the resistance of the OS memory to soft errors is high.

An error map of SEU in the OS memory array is shown in FIG. 65B. FIG. 65B is the error map in the SEU resistance test with LET of 69.2 MeV cm²/mg when the write pattern is set to ALL1. The error map of SEU in the OS memory array is shown on the left side of FIG. 65B, and an enlarged view of a region indicated by a square in the error map is shown on the right side of FIG. 65B.

As shown in FIG. 65B, no characteristic pattern is found in the error map and also no group of continuous error bits in adjacent bits is observed.

In the case of the OS memory, the cross section of the reaction to ALL1 with a high LET is larger than that to ALL0. An error in rewriting “1” to “0” is presumed to be because electric charge generated in the channel formation region of the transistor M1 flows into the capacitor, as in the defect mechanism of a general DRAM. Meanwhile, an error in rewriting “0” to “1” is presumed to be detected not as a hard error but as Upset because the transistor M2 and the transistor M3 cause local shifts in the negative direction due to a micro-dose effect but the shifts are recovered quickly, from the findings of a TID test.

The composition, structure, method, and the like described in this example can be used in combination as appropriate with the compositions, structures, methods, and the like described in the other embodiments and the like.

### REFERENCE NUMERALS

10: memory cell, 11: n memory layers, 15: memory cell array, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: driver circuit layer, 61: transistor, 62: transistor, 100: memory device, 101: capacitor, 181: insulator, 183: insulator, 185: insulator, 201a: transistor, 201b: transistor, 201: transistor, 202a: transistor, 202b: transistor, 202: transistor, 203a: transistor, 203b: transistor, 203: transistor, 205a: conductor, 205b: conductor, 205c: conductor, 205: conductor, 207a: opening, 207b: opening, 207c: opening, 209a: conductor, 209b: conductor, 209: conductor, 210: insulator, 212: insulator, 214: insulator, 215: insulator, 216_n: insulator, 216a: insulator, 216b: insulator, 216: insulator, 222: insulator, 224a: insulator, 224b: insulator, 224f: insulating film, 224: insulator, 230a: metal oxide, 230b: metal oxide, 230f: metal oxide film, 230: metal oxide, 231a: conductor, 231a_1: conductor, 231a_2: conductor, 231a_3: conductor, 231a_n: conductor, 231b: conductor, 231b_1: conductor, 231b_2: conductor, 231b_3: conductor, 231b_n: conductor, 231c: conductor, 231d: conductor, 231: conductor, 232a: insulator, 232b: insulator, 232c: insulator, 232d: insulator, 232f: insulating film, 232: insulator, 235a: conductor, 235b: conductor, 235c: conductor, 237a: region, 238a: region, 239a: region, 240a: connection electrode, 240b: connection electrode, 240: connection electrode, 242a: conductor, 242b: conductor, 242c: conductor, 242d: conductor, 242e: conductor, 242F: conductive layer, 242f: conductive film, 242Fa: conductive layer, 242Fb: conductive layer, 242: conductor, 250a: insulator, 250b: insulator, 250c: insulator, 250d: insulator, 250f: insulating film, 250: insulator, 258a: opening, 258b: opening, 258c: opening, 260a: conductor, 260b: conductor, 260: conductor, 271a: insulator, 271b: insulator, 271c: insulator, 271d: insulator, 271e: insulator, 271F: insulating layer, 271f: insulating film, 271Fa: insulating layer, 271Fb: insulating layer, 271: insulator, 275: insulator, 280: insulator, 282: insulator, 283: insulator, 285: insulator, 287: insulator, 288a: opening, 288b: opening, 288c: opening, 288d: opening, 291: hard mask, 292: resist mask, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 600: circuit, 652: AND circuit, 653: analog switch, 654: analog switch, 661: transistor, 662: transistor, 663: transistor, 664: transistor, 666: transistor, 700: electronic component, 702: printed circuit board, 704: circuit board, 711: mold, 712: land, 713: electrode pad, 714: wire, 730: electronic component, 731: interposer, 732: package substrate, 733: electrode, 735: semiconductor device, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5110: SD card, 5111: housing, 5112: connector, 5113: substrate, 5115: controller chip, 5150: SSD, 5151: housing, 5152: connector, 5153: substrate, 5155: memory chip, 5156: controller chip, 5200: portable game machine, 5201: housing, 5202: display portion, 5203: button, 5300: desktop information terminal, 5301: main body, 5302: display portion, 5303: keyboard, 5400: ICD main unit, 5401: battery, 5402: wire, 5403: wire, 5404: antenna, 5405: subclavian vein, 5406: superior vena cava, 5500: information terminal, 5510: housing, 5511: display portion, 5600: computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5700: automobile, 5800: electric refrigerator-freezer, 5801: housing, 5802: refrigerator door, 5803: freezer door, 5900: information terminal, 5901: housing, 5902: display portion, 5903: operation switch, 5904: operation switch, 5905: band, 6100: expansion device, 6101: housing, 6102: cap, 6103: USB connector, 6104: substrate, 6106: controller chip, 6240: digital camera, 6241: housing, 6242: display portion, 6243: operation switch, 6244: shutter button, 6246: lens, 6300: video camera, 6301: first housing, 6302: second housing, 6303: display portion, 6304: operation switch, 6305: lens, 6306: joint, 6800: artificial satellite, 6801: body, 6802: solar panel, 6803: antenna, 6804: planet, 6805: secondary battery, 6807: control device, 7500: stationary game machine, 7520: main body, 7522: controller, 7800: image capturing device, 7801: scintillator, 7802: image sensor, 7803: X-ray, 7804: subject, 7805: light, 7811: photodiode, 7812: transistor, 7813: terminal, 7814: wiring, 8000: X-ray, 8001: stage, 8002: X-ray source, 8003: diaphragm plate,

1. A semiconductor device comprising:
a metal oxide;
a first conductor and a second conductor over the metal oxide;
a first insulator over the first conductor and the second conductor;
a second insulator over the first insulator;
a third insulator that is between the first conductor and the second conductor and is over the metal oxide;
a third conductor over the third insulator;
a fourth conductor that is over the third conductor and is electrically connected to the third conductor;
a fourth insulator over the fourth conductor;
a fifth insulator provided in a first opening in the fourth insulator; and
a fifth conductor comprising a region overlapping with the fourth conductor with the fifth insulator therebetween,
wherein the third insulator and the third conductor are provided in a second opening in the first insulator and the second insulator,
wherein the metal oxide comprises a first region that overlaps with the first conductor and extends in a first direction,
wherein, in the first region, an end portion of the metal oxide is aligned with an end portion of the first conductor, and
wherein the first direction is parallel to a direction in which the fifth conductor extends.

2. The semiconductor device according to claim 1, further comprising a sixth conductor, a sixth insulator, and a seventh conductor,
wherein the metal oxide comprises a region overlapping with the sixth conductor,
wherein a third opening in the first insulator and the second insulator comprises a region overlapping with the sixth conductor,
wherein the sixth insulator is in contact with a side surface of each of the first insulator and the second insulator in the third opening,
wherein the seventh conductor is provided to fill the third opening with the sixth insulator therebetween, and
wherein the seventh conductor comprises a region in contact with part of a top surface of the sixth conductor and a region in contact with part of a side surface of the sixth conductor.

3. The semiconductor device according to claim 1, further comprising a seventh insulator and an eighth insulator,
wherein the seventh insulator is between the first conductor and the first insulator, and
wherein the eighth insulator is between the second conductor and the first insulator.

4. The semiconductor device according to claim 1,
wherein the first conductor and the second conductor each have a stacked-layer structure,
wherein the stacked-layer structure comprises a first conductive layer and a second conductive layer over the first conductive layer, and
wherein the first conductive layer comprises a region with a nitrogen concentration higher than a nitrogen concentration in the second conductive layer.

5. A semiconductor device comprising:
a first transistor; and
a capacitor, a second transistor, and a fourth insulator over the first transistor,
wherein the first transistor comprises:
a first metal oxide;
a first conductor and a second conductor over the first metal oxide;
a first insulator over the first conductor and the second conductor;
a second insulator over the first insulator;
a third insulator that is between the first conductor and the second conductor and is over the first metal oxide; and
a third conductor over the third insulator,
wherein the capacitor comprises:
a fourth conductor;
a fifth insulator over the fourth conductor; and
a fifth conductor comprising a region overlapping with the fourth conductor with the fifth insulator therebetween,
wherein the fourth conductor is electrically connected to the third conductor,
wherein the second transistor comprises:
an eighth conductor; and
a second metal oxide that is over the eighth conductor and comprises a region overlapping with the eighth conductor,
wherein the fifth insulator and the fifth conductor are provided in a first opening in the fourth insulator,
wherein the eighth conductor is provided in a second opening in the fourth insulator, and
wherein a top surface of the fifth conductor is aligned with a top surface of the eighth conductor.

6. The semiconductor device according to claim 5,
wherein the first metal oxide comprises a first region that overlaps with the first conductor and extends in a first direction,
wherein, in the first region, an end portion of the first metal oxide is aligned with an end portion of the first conductor, and
wherein the first direction is parallel to a direction in which the fifth conductor extends.

7. The semiconductor device according to claim 5, further comprising a sixth conductor, a sixth insulator, and a seventh conductor,
wherein the first metal oxide comprises a region overlapping with the sixth conductor,
wherein a third opening in the first insulator and the second insulator comprises a region overlapping with the sixth conductor,
wherein the sixth insulator is in contact with a side surface of each of the first insulator and the second insulator in the third opening,
wherein the seventh conductor is provided to fill the third opening with the sixth insulator therebetween, and
wherein the seventh conductor comprises a region in contact with part of a top surface of the sixth conductor and a region in contact with part of a side surface of the sixth conductor.

8. The semiconductor device according to claim 5, further comprising a seventh insulator and an eighth insulator,
wherein the seventh insulator is between the first conductor and the first insulator, and
wherein the eighth insulator is between the second conductor and the first insulator.

9. The semiconductor device according to claim 5,
wherein the first conductor and the second conductor each have a stacked-layer structure,
wherein the stacked-layer structure comprises a first conductive layer and a second conductive layer over the first conductive layer, and
wherein the first conductive layer comprises a region with a nitrogen concentration higher than a nitrogen concentration in the second conductive layer.
